(19) United States
(12) Patent Application Publication
(10) Pub. No.: US 2022/0181551 A1
(43) Pub. Date: Jun. 9, 2022

(54) ORGANIC ELECTROLUMINESCENCE DEVICE AND POLYCYCLIC COMPOUND FOR ORGANIC ELECTROLUMINESCENCE DEVICE

(71) Applicant: Samsung Display Co., Ltd., Yongin-si (KR)

(72) Inventors: TAEIL KIM, Hwaseong-si (KR); SUN YOUNG PAK, Suwon-si (KR); JUNHA PARK, Gwacheon-si (KR); JANG YEOL BAEK, Yongin-si (KR); KYOUNG SUNWOO, Hwaseong-si (KR); MUN-KI SIM, Seoul (KR); CHANSEOK OH, Seoul (KR); MINJUNG JUNG, Gangwon-do (KR)

(21) Appl. No.: 17/451,308

(22) Filed: Oct. 18, 2021

(30) Foreign Application Priority Data
Dec. 8, 2020 (KR) 10-2020-0170665

(51) Int. Cl. H01L 51/00; C09K 11/06; C07F 5/02

(52) U.S. Cl. CPC H01L 51/008; C09K 11/06; H01L 51/5016; C09K 2211/1007; C07F 5/027

(57) ABSTRACT

An organic electroluminescence device of one or more embodiments includes a first electrode, an organic layer on the first electrode, and a second electrode on the organic layer, wherein the first electrode and the second electrode each independently includes at least one selected from among Ag, Mg, Cu, Al, Pt, Pd, Au, Ni, Nd, Ir, Cr, Li, Ca, LiF, Mo, Ti, W, In, Sn, Zn, compounds thereof, mixtures thereof, and oxides thereof, and the organic layer includes a polycyclic compound represented by Formula 1, thereby showing high emission efficiency properties:

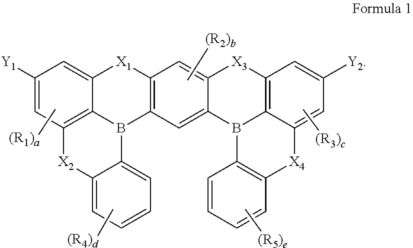

### CROSS-REFERENCE TO RELATED APPLICATION

This application claims priority to and the benefit of Korean Patent Application No. 10-2020-0170665, filed on Dec. 28, 2020, the entire content of which is hereby incorporated by reference.

### BACKGROUND

One or more embodiments of the present disclosure herein relate to an organic electroluminescence device and a polycyclic compound used therein, and for example, to a polycyclic compound used as a light-emitting material and an organic electroluminescence device including the same.

Recently, the development of an organic electroluminescence display as an image display has been researched. The organic electroluminescence display is different from a liquid crystal display and may be a self-luminescent display in which holes and electrons injected from a first electrode and a second electrode recombine in an emission layer so that a light-emitting material including an organic compound in the emission layer emits light to achieve display of images.

In the application of an organic electroluminescence device to a display, the decrease of a driving voltage, the increase of emission efficiency and/or the life (lifespan) of the organic electroluminescence device may be desired, and development on materials for an organic electroluminescence device capable of stably achieving these characteristics may be desired.

In order to accomplish an organic electroluminescence device with high efficiency, techniques on phosphorescence emission, which uses energy in a triplet state, or delayed fluorescence emission, which uses the generating phenomenon of singlet excitons by the collision of triplet excitons (triplet-triplet annihilation, TTA), are being developed, and development on a material for thermally activated delayed fluorescence (TADF) using delayed fluorescence phenomenon is being evaluated.

### SUMMARY

One or more embodiments of the present disclosure are directed toward an organic electroluminescence device and a polycyclic compound for an organic electroluminescence device, and, for example, an organic electroluminescence device with high efficiency and a polycyclic compound included in the emission layer of an organic electroluminescence device.

One or more embodiments provide an organic electroluminescence device including a first electrode, an organic layer on the first electrode, and a second electrode on the organic layer; wherein the first electrode and the second electrode may each independently include at least one selected from among Ag, Mg, Cu, Al, Pt, Pd, Au, Ni, Nd, Ir, Cr, Li, Ca, LiF, Mo, Ti, W, In, Sn, Zn, compounds thereof, mixtures thereof, and oxides thereof, and the organic layer may include a polycyclic compound represented by Formula 1 below.

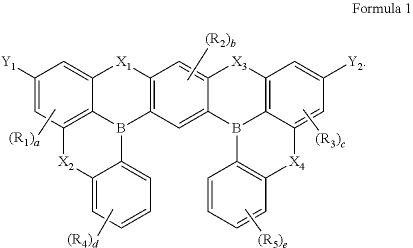

In Formula 1, X₁ to X₄ may be each independently CR₆R₇, NR₈, O, S, or Se;

R₁ to R₇ may be each independently a hydrogen atom, a deuterium atom, a halogen atom, a nitro group, a cyano group, a hydroxyl group, a substituted or unsubstituted amine group, a substituted or unsubstituted thiol group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring; R₈ may be a hydrogen atom, a deuterium atom, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring; Y₁ and Y₂ may be each independently a hydrogen atom, a deuterium atom, a halogen atom, a substituted or unsubstituted silyl group, a substituted or unsubstituted oxy group, a substituted or unsubstituted amine group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring; “a” to “c” may be each independently an integer of 0 to 2; and “d” and “e” may be each independently an integer of 0 to 4, where at least one selected from among Y₁ and Y₂ is represented by Formula 2-1 or Formula 2-2 below.

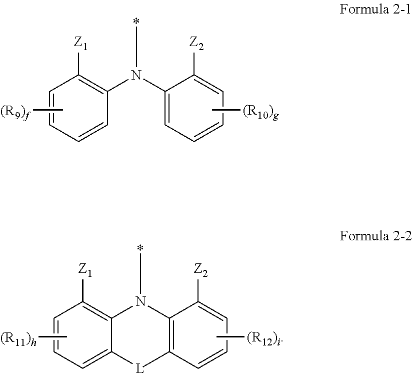

In Formula 2-1 and Formula 2-2, L may be a direct linkage, CR₁₃R₁₄, O, or S; R₉ to R₁₂ may be each independently a hydrogen atom, a deuterium atom, a halogen atom, a cyano group, a nitro group, a hydroxyl group, a substituted or unsubstituted silyl group, a substituted or unsubstituted oxy group, a substituted or unsubstituted thiol group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring; R₁₃ and R₁₄ may be each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; Z₁ and Z₂ may be each independently a substituted or unsubstituted silyl group, a substituted or unsubstituted alkyl group of 1 to 20 carbon atoms, a substituted or unsubstituted cycloalkyl group of 3 to 20 carbon atoms, a substituted or unsubstituted bicycloalkyl group of 5 to 30 carbon atoms, or a substituted or unsubstituted tricycloalkyl group of 8 to 30 carbon atoms; “f” and “g” may be each independently an integer of 0 to 4; and “h” and “i” may be each independently an integer of 0 to 3.

In one or more embodiments, the organic layer may include a hole transport region on the first electrode, an emission layer on the hole transport region, and an electron transport region on the emission layer, wherein at least one selected from among the hole transport region, the emission layer, and the electron transport region may include the polycyclic compound.

In one or more embodiments, the emission layer may include the polycyclic compound and may emit delayed fluorescence.

In one or more embodiments, the emission layer may be a delayed fluorescence emission layer including a host and a dopant, and the dopant may include the polycyclic compound represented by Formula 1.

In one or more embodiments, the electron transport region may include an electron transport layer on the emission layer, and an electron injection layer on the electron transport layer, wherein the electron transport layer or the electron injection layer may include the polycyclic compound.

In one or more embodiments, Formula 2-2 may be represented by Formula 3 below.

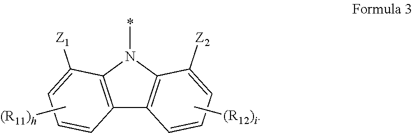

In Formula 3, Z₁, Z₂, R₁₁, R₁₂, “h”, and “i” are the same as defined in Formula 2-2.

In one or more embodiments, Formula 1 may be represented by any one selected from among Formula 4-1 to Formula 4-4 below.

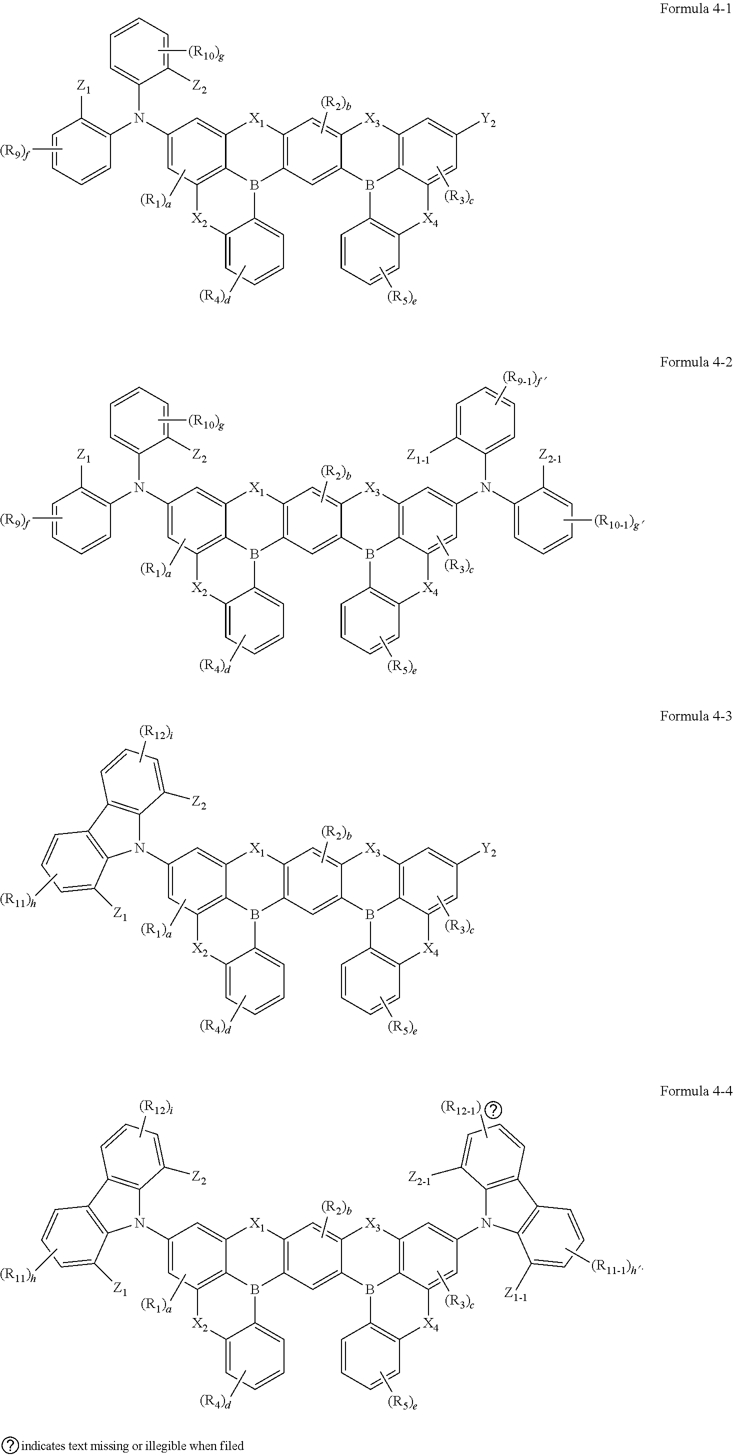

In Formula 4-1 to Formula 4-4, Z₁₋₁ and Z₂₋₁ may be each independently a substituted or unsubstituted silyl group, a substituted or unsubstituted alkyl group of 1 to 20 carbon atoms, a substituted or unsubstituted cycloalkyl group of 3 to 20 carbon atoms, a substituted or unsubstituted bicycloalkyl group of 5 to 30 carbon atoms, or a substituted or unsubstituted tricycloalkyl group of 8 to 30 carbon atoms; R₉₋₁, R₁₀₋₁, R₁₁₋₁, and R₁₂₋₁ may be each independently a hydrogen atom, a deuterium atom, a halogen atom, a cyano group, a nitro group, a hydroxyl group, a substituted or unsubstituted silyl group, a substituted or unsubstituted oxy group, a substituted or unsubstituted thiol group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring; “f′” and “g′” may be each independently an integer of 0 to 4; “h” and “i” may be each independently an integer of 0 to 3; and X₁ to X₄, R₁ to R₅, “a” to “e”, Y₂, Z₁, Z₂, R₉ to R₁₂, and “f” to “i” are the same as defined in Formula 1 and Formula 2.

In one or more embodiments, Z₁ and Z₂ may be each independently a silyl group substituted with a substituted or unsubstituted alkyl group of 1 to 10 carbon atoms, a substituted or unsubstituted alkyl group of 1 to 10 carbon atoms, a substituted or unsubstituted cycloalkyl group of 3 to 10 ring-forming carbon atoms, a substituted or unsubstituted bicycloalkyl group of 5 to 10 ring-forming carbon atoms, or a substituted or unsubstituted tricycloalkyl group of 8 to 12 ring-forming carbon atoms.

In one or more embodiments, at least one selected from among X₁ to X₄ may be NAr₁, and Ar₁ may be a substituted or unsubstituted aryl group of 6 to 30 ring-forming carbon atoms, or a substituted or unsubstituted heteroaryl group of 2 to 30 ring-forming carbon atoms.

In one or more embodiments, Formula 1 may be represented by any one selected from among Formula 5-1 to Formula 5-5 below.

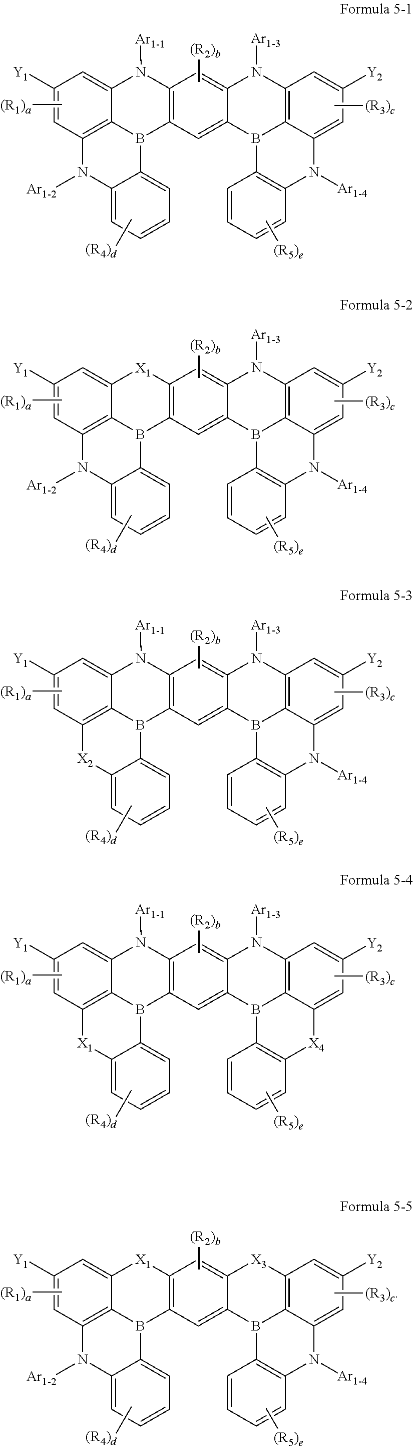

In Formula 5-1 to Formula 5-5, X₁ to X₄ may be each independently O, S, or Se; Ar₁₋₁ to Ar₁₋₄ may be each independently a substituted or unsubstituted aryl group of 6 to 30 ring-forming carbon atoms, or a substituted or unsubstituted heteroaryl group of 2 to 30 ring-forming carbon atoms; and Y₁, Y₂, R₁ to R₅, and “a” to “e” are the same as defined in Formula 1.

In one or more embodiments, Ar₁₋₁ to Ar₁₋₄ may be each independently represented by any one selected from among Formula 6-1 to Formula 6-3 below.

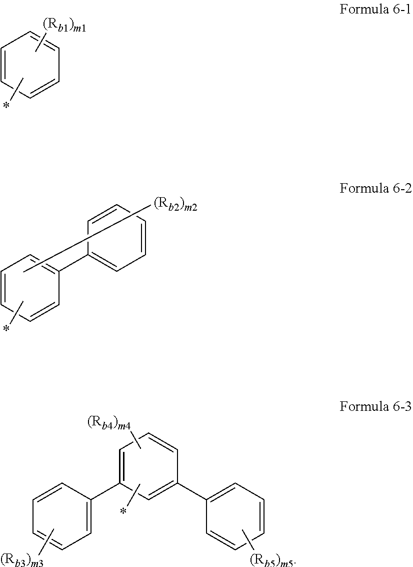

In Formula 6-1 to Formula 6-3, R_{b1} to R_{b5} may be each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring; “m1”, “m3”, and “m5” may be each independently an integer of 0 to 5; “m2” may be an integer of 0 to 9; and “m4” may be an integer of 0 to 3.

In one or more embodiments, the polycyclic compound represented by Formula 1 may be any one selected from among the compounds represented in Compound Group 1.

A polycyclic compound according to one or more embodiments is represented by Formula 1 above.

### BRIEF DESCRIPTION OF THE FIGURES

The accompanying drawings are included to provide a further understanding of present embodiments and are incorporated in and constitute a part of this specification. The drawings illustrate embodiments of the present disclosure and, together with the description, serve to explain principles of the present disclosure. In the drawings:

FIG. 1 is a plan view showing a display apparatus according to one or more embodiments;

FIG. 2 is a cross-sectional view showing a display apparatus according to one or more embodiments;

FIG. 3 is a cross-sectional view schematically showing an organic electroluminescence device according to one or more embodiments;

FIG. 4 is a cross-sectional view schematically showing an organic electroluminescence device according to one or more embodiments;

FIG. 5 is a cross-sectional view schematically showing an organic electroluminescence device according to one or more embodiments;

FIG. 6 is a cross-sectional view schematically showing an organic electroluminescence device according to one or more embodiments;

FIG. 7 is a cross-sectional view schematically showing an organic electroluminescence device according to one or more embodiments;

FIG. 8 is a cross-sectional view showing a display apparatus according to one or more embodiments; and

FIG. 9 is a cross-sectional view showing a display apparatus according to one or more embodiments.

### DETAILED DESCRIPTION

Embodiments of the present disclosure may have various modifications and may be embodied in different forms, and example embodiments will be explained in more detail with reference to the accompanying drawings. Embodiments of the present disclosure may, however, be embodied in different forms and should not be construed as limited to the embodiments set forth herein. Rather, all modifications, equivalents, and substituents which are included in the spirit and technical scope of the present disclosure should be included in present embodiments.

Like reference numerals refer to like elements throughout. In the drawings, the dimensions of structures are exaggerated for clarity of illustration. It will be understood that, although the terms first, second, etc. may be used herein to describe various elements, these elements should not be limited by these terms. These terms are only used to distinguish one element from another element. Thus, a first element could be termed a second element without departing from the teachings of the present disclosure. Similarly, a second element could be termed a first element. As used herein, the singular forms are intended to include the plural forms as well, unless the context clearly indicates otherwise.

In the description, it will be further understood that the terms “comprises” and/or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

In the description, when a layer, a film, a region, a plate, etc. is referred to as being “on” or “above” another part, it can be “directly on” the other part (without any intervening layers therebetween), or intervening layers may also be present. Similarly, when a layer, a film, a region, a plate, etc. is referred to as being “under” or “below” another part, it can be “directly under” the other part (without any intervening layers therebetween), or intervening layers may also be present. Also, when an element is referred to as being disposed (e.g., provided) “on” another element, it can be disposed (e.g., provided) under the other element.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list.

As used herein, the term “and/or” includes any and all combinations of one or more of the associated listed items.

Further, the use of “may” when describing embodiments of the present disclosure refers to “one or more embodiments of the present disclosure”.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Hereinafter, embodiments of the present disclosure will be explained referring to the drawings.

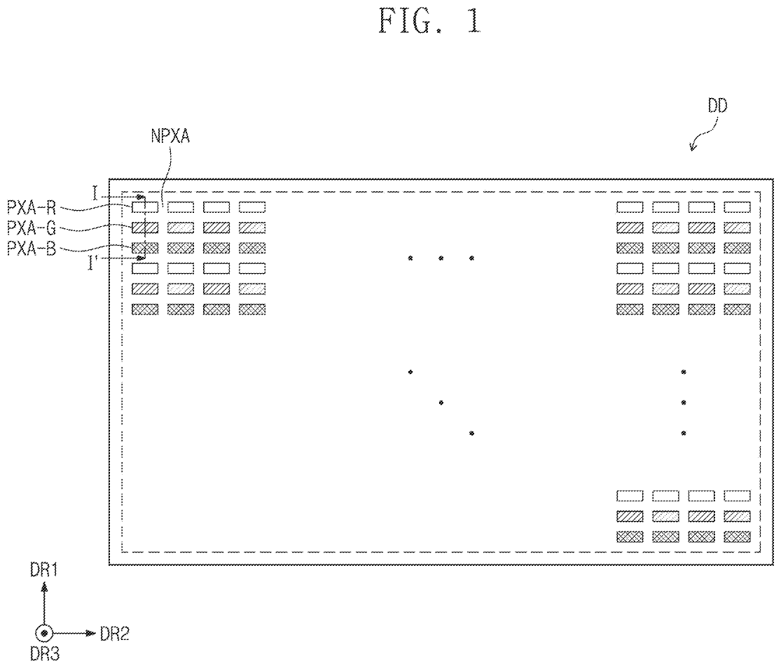

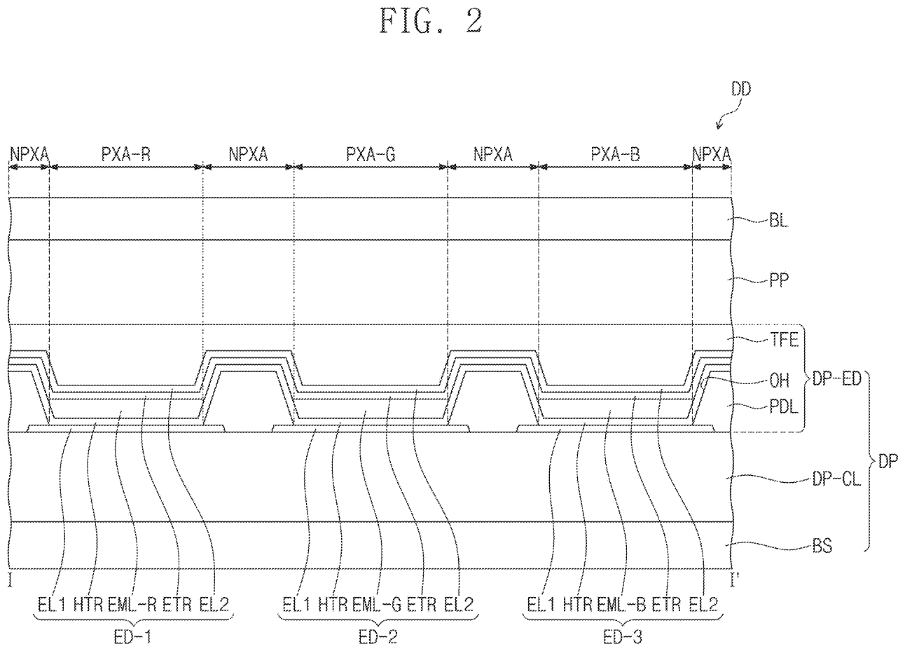

FIG. 1 is a plan view showing an embodiment of a display apparatus DD. FIG. 2 is a cross-sectional view of a display apparatus DD of one or more embodiments. FIG. 2 is a cross-sectional view showing a part corresponding to line I-I′ in FIG. 1.

The display apparatus DD may include a display panel DP and an optical layer PP on the display panel DP. The display panel DP includes organic electroluminescence devices ED-1, ED-2 and ED-3. The display apparatus DD may include multiple organic electroluminescence devices ED-1, ED-2 and ED-3. The optical layer PP may be on the display panel DP and control reflected light by external light at the display panel DP. The optical layer PP may include, for example, a polarization layer and/or a color filter layer. In one or more embodiments, the optical layer PP may be omitted in the display apparatus DD of one or more embodiments.

On the optical layer PP, a base substrate BL may be provided. The base substrate BL may be a member providing a base surface where the optical layer PP is positioned. The base substrate BL may be a glass substrate, a metal substrate, a plastic substrate, etc. However, embodiments of the present disclosure are not limited thereto, and the base substrate BL may be an inorganic layer, an organic layer or a composite material layer. The base substrate BL may be omitted in one or more embodiments.

The display apparatus DD according to one or more embodiments may further include a filling layer. The filling layer may be between a display device layer DP-ED and a base substrate BL. The filling layer may be an organic layer. The filling layer may include at least one selected from among an acrylic resin, a silicon-based resin, and an epoxy-based resin.

The display panel DP may include a base layer BS, a circuit layer DP-CL provided on the base layer BS and a display device layer DP-ED. The display device layer DP-ED may include a pixel definition layer PDL, organic electroluminescence devices ED-1, ED-2 and ED-3 in the pixel definition layer PDL, and an encapsulating layer TFE on the organic electroluminescence devices ED-1, ED-2 and ED-3.

The base layer BS may be a member providing a base surface where the display device layer DP-ED is positioned. The base layer BS may be a glass substrate, a metal substrate, a plastic substrate, etc. However, embodiments of the present disclosure are not limited thereto, and the base layer BS may be an inorganic layer, an organic layer, or a composite material layer (e.g., including an organic material and an inorganic material).

In one or more embodiments, the circuit layer DP-CL is on the base layer BS, and the circuit layer DP-CL may include multiple transistors. Each of the transistors may include a control electrode, an input electrode, and an output electrode.

For example, the circuit layer DP-CL may include switching transistors and driving transistors for driving the organic electroluminescence devices ED-1, ED-2 and ED-3 of the display device layer DP-ED.

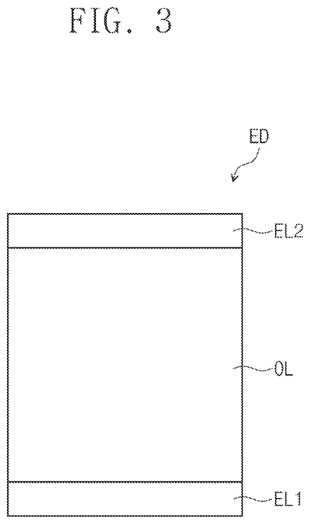

Each of the organic electroluminescence devices ED-1, ED-2 and ED-3 may have the structures of organic electroluminescence devices ED of embodiments according to FIG. 3 to FIG. 7, which will be further explained below. Each of the organic electroluminescence devices ED-1, ED-2 and ED-3 may include a first electrode EL1, a hole transport region HTR, emission layers EML-R, EML-G and EML-B, an electron transport region ETR and a second electrode EL2.

In FIG. 2, shown is an embodiment where the emission layers EML-R, EML-G and EML-B of organic electroluminescence devices ED-1, ED-2 and ED-3, which are in opening portions OH defined in a pixel definition layer PDL, are provided, and a hole transport region HTR, an electron transport region ETR and a second electrode EL2 are provided as common layers in all organic electroluminescence devices ED-1, ED-2 and ED-3. However, embodiments of the present disclosure are not limited thereto. For example, in one or more embodiments, the hole transport region HTR and the electron transport region ETR may be patterned and provided in the opening portions OH defined in the pixel definition layer PDL. For example, in one or more embodiments, the hole transport region HTR, the emission layers EML-R, EML-G and EML-B, and the electron transport region ETR of the organic electroluminescence devices ED-1, ED-2 and ED-3 may be patterned by an ink jet printing method and provided.

An encapsulating layer TFE may cover the organic electroluminescence devices ED-1, ED-2 and ED-3. The encapsulating layer TFE may encapsulate the display device layer DP-ED. The encapsulating layer TFE may be a thin film encapsulating layer. The encapsulating layer TFE may be one layer or a stacked layer of multiple layers. The encapsulating layer TFE includes at least one insulating layer. The encapsulating layer TFE according to one or more embodiments may include at least one inorganic layer (hereinafter, encapsulating inorganic layer). In one or more embodiments, the encapsulating layer TFE may include at least one organic layer (hereinafter, encapsulating organic layer), and at least one encapsulating inorganic layer.

The encapsulating inorganic layer protects the display device layer DP-ED from moisture/oxygen, and the encapsulating organic layer protects the display device layer DP-ED from foreign materials such as dust particles. The encapsulating inorganic layer may include silicon nitride, silicon oxy nitride, silicon oxide, titanium oxide, and/or aluminum oxide, without specific limitation. The encapsulating organic layer may include an acrylic compound, an epoxy-based compound, etc. The encapsulating organic layer may include a photopolymerizable organic material, without specific limitation.

The encapsulating layer TFE may be on the second electrode EL2 and may be provided while filling (e.g., to fill) the opening portion OH.

Referring to FIG. 1 and FIG. 2, the display apparatus DD may include a non-luminous area NPXA and luminous areas PXA-R, PXA-G and PXA-B. The luminous areas PXA-R, PXA-G and PXA-B may be areas emitting (e.g., configured to emit) light produced from the organic electroluminescence devices ED-1, ED-2 and ED-3, respectively. The luminous areas PXA-R, PXA-G and PXA-B may be separated from each other on a plane (e.g., in plan view).

The luminous areas PXA-R, PXA-G and PXA-B may be areas separated by the pixel definition layer PDL. The non-luminous areas NPXA may be areas between neighboring luminous areas PXA-R, PXA-G and PXA-B and may be areas corresponding to the pixel definition layer PDL. In one or more embodiments, each of the luminous areas PXA-R, PXA-G and PXA-B may correspond to each pixel. The pixel definition layer PDL may divide the organic electroluminescence devices ED-1, ED-2 and ED-3. The emission layers EML-R, EML-G and EML-B of the organic electroluminescence devices ED-1, ED-2 and ED-3 may be provided and divided in the opening portions OH defined in the pixel definition layer PDL.

The luminous areas PXA-R, PXA-G and PXA-B may be divided into multiple groups according to the color of light produced from the organic electroluminescence devices ED-1, ED-2 and ED-3. In the display apparatus DD of one or more embodiments, shown in FIG. 1 and FIG. 2, three luminous areas PXA-R, PXA-G and PXA-B emitting (e.g., configured to emit) red light, green light and blue light are illustrated as one or more embodiments. For example, the display apparatus DD of one or more embodiments may include a red luminous area PXA-R, a green luminous area PXA-G and a blue luminous area PXA-B, which are separated from each other.

In the display apparatus DD according to one or more embodiments, multiple organic electroluminescence devices ED-1, ED-2 and ED-3 may emit light having different wavelength regions. For example, in one or more embodiments, the display apparatus DD may include a first organic electroluminescence device ED-1 emitting (e.g., to emit) red light, a second organic electroluminescence device ED-2 emitting (e.g., to emit) green light, and a third organic electroluminescence device ED-3 emitting (e.g., to emit) blue light. For example, the red luminous area PXA-R, the green luminous area PXA-G, and the blue luminous area PXA-B of the display apparatus DD may correspond to the first organic electroluminescence device ED-1, the second organic electroluminescence device ED-2, and the third organic electroluminescence device ED-3, respectively.

However, one or more embodiments of the present disclosure is not limited thereto, and the first to third organic electroluminescence devices ED-1, ED-2 and ED-3 may emit light in the same wavelength region, or at least one thereof may emit light in a different wavelength region. For example, all of the first to third organic electroluminescence devices ED-1, ED-2 and ED-3 may emit blue light.

The luminous areas PXA-R, PXA-G and PXA-B in the display apparatus DD according to one or more embodiments may be arranged in a stripe shape. Referring to FIG. 1, multiple red luminous areas PXA-R may be arranged with each other along a second direction DR2, multiple green luminous areas PXA-G may be arranged with each other with each other along the second direction DR2, and multiple blue luminous areas PXA-B may be arranged with each other along the second direction DR2. A red luminous area PXA-R, a green luminous area PXA-G, and a blue luminous area PXA-B may be arranged with each other by turns (e.g., alternatingly) along a first direction DR1.

In FIG. 1 and FIG. 2, the areas of the luminous areas PXA-R, PXA-G and PXA-B are shown to be similar, but present embodiments are not limited thereto. For example, areas of the luminous areas PXA-R, PXA-G and PXA-B may be different from each other according to the wavelength region of light emitted. As used herein, the areas of the luminous areas PXA-R, PXA-G and PXA-B may mean areas on a plane defined by the first direction DR1 and the second direction DR2.

However, the arrangement of the luminous areas PXA-R, PXA-G and PXA-B is not limited to the configuration shown in FIG. 1, and the arrangement order of the red luminous areas PXA-R, the green luminous areas PXA-G and the blue luminous areas PXA-B may be provided in various suitable combinations according to the properties of display quality required (or desired) for the display apparatus DD. For example, the arrangement of the luminous areas PXA-R, PXA-G and PXA-B may be a PenTile®/PENTILE® arrangement (PENTILE® is a registered trademark owned by Samsung Display Co., Ltd.), or a diamond arrangement.

In one or more embodiments, the areas of the luminous areas PXA-R, PXA-G and PXA-B may be different from each other. For example, in one or more embodiments, the area of the green luminous area PXA-G may be smaller than the area of the blue luminous area PXA-B, but embodiments of the present disclosure are not limited thereto.

Hereinafter, FIG. 3 to FIG. 7 are cross-sectional views schematically showing organic electroluminescence devices according to embodiments. Referring to FIG. 3 to FIG. 7, in an organic electroluminescence device ED of one or more embodiments, a first electrode EL1 and a second electrode EL2 are oppositely positioned, and between the first electrode and the second electrode, an organic layer OL may be positioned.

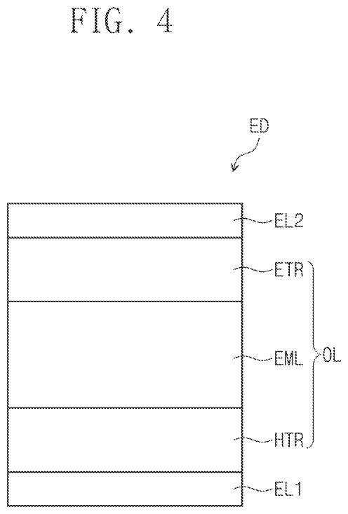

Referring to FIG. 4 to FIG. 7, the organic layer OL of one or more embodiments may include multiple functional layers. The multiple functional layers may include a hole transport region HTR, an emission layer EML and an electron transport region ETR. For example, an organic electroluminescence device ED according to one or more embodiments may include a first electrode EL1, a hole transport region HTR, an emission layer EML, an electron transport region ETR, and a second electrode EL2 stacked in this order. In one or more embodiments, the organic electroluminescence device ED according to one or more embodiments may include a capping layer CPL on the second electrode EL2.

The organic electroluminescence device ED of one or more embodiments may include a polycyclic compound of one or more embodiments, which will be explained in more detail hereinbelow, in the organic layer OL between the first electrode EL1 and the second electrode EL2. If the organic layer OL includes the emission layer EML, the emission layer EML may include the polycyclic compound of one or more embodiments. However, one or more present embodiments are not limited thereto, and the organic electroluminescence device ED of one or more embodiments may include the polycyclic compound according to one or more embodiments, which will be further explained below, in a hole transport region HTR or an electron transport region ETR, which are multiple functional layers between the first electrode EL1 and the second electrode EL2, in addition to the emission layer EML, or may include the polycyclic compound according to one or more embodiments, which will be further explained below, in a capping layer CPL on the second electrode EL2.

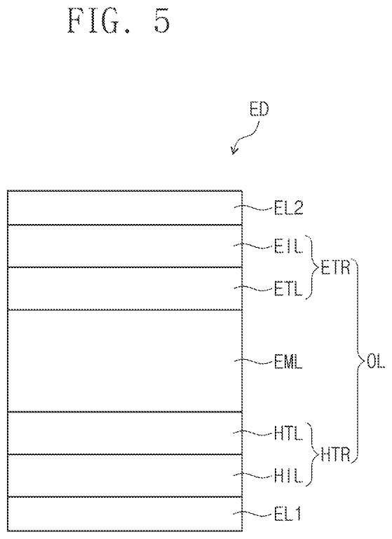

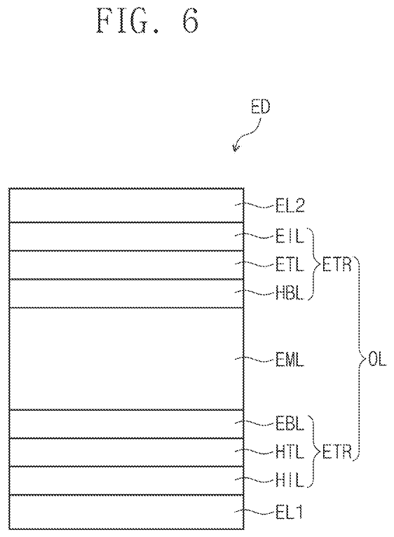

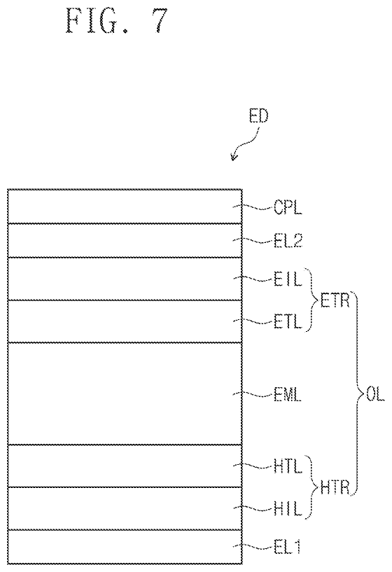

When compared with FIG. 4, FIG. 5 shows the cross-sectional view of an organic electroluminescence device ED of one or more embodiments, wherein a hole transport region HTR includes a hole injection layer HIL and a hole transport layer HTL, and an electron transport region ETR includes an electron injection layer EIL and an electron transport layer ETL. When compared with FIG. 4, FIG. 6 shows the cross-sectional view of an organic electroluminescence device ED of one or more embodiments, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. When compared with FIG. 5, FIG. 7 shows the cross-sectional view of an organic electroluminescence device ED of one or more embodiments, including a capping layer CPL on the second electrode EL2.

The first electrode EL1 may be conductive. The first electrode EL1 may be formed using a metal material, a metal alloy, or any suitable conductive compound. The first electrode EL1 may be an anode or a cathode. However, embodiments of the present disclosure are not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, Zn, compounds thereof, mixtures thereof, and oxides thereof. In one or more embodiments, the first electrode EL1 may have a single layer structure composed of compounds of one or two or more among the materials, and may have a single layer structure composed of mixtures of two or more among the materials. In one or more embodiments, the first electrode EL1 may have a multilayer structure having multiple layers composed of multiple different materials among the materials. For example, the first electrode EL1 may have a double layer structure of LiF/Ca or LiF/Al, but embodiments of the present disclosure are not limited thereto.

If the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). If the first electrode EL1 is the transflective electrode or the reflective electrode, the first electrode EL1 may be selected from among Ag, Mg, Cu, Al, Pt, Pd, Au, Ni, Nd, Ir, Cr, Li, Ca, LiF, Mo, Ti, W, compounds thereof, and mixtures thereof (for example, a mixture of Ag and Mg). In one or more embodiments, the first electrode EL1 may have a structure of multiple layers including a reflective layer or a transflective layer formed using any of the above materials, and a transmissive conductive layer formed using ITO, IZO, ZnO, and/or

ITZO. For example, the first electrode EL1 may include a three-layer structure of ITO/Ag/ITO. However, embodiments of the present disclosure are not limited thereto. The first electrode EL1 may include at least one of the above-described metal materials, combination(s) of two or more metal materials selected from the above-described metal materials, and/or oxide(s) of the above-described metal materials.

The thickness of the first electrode EL1 may be from about 700 Å (angstroms) to about 10,000 Å. For example, the thickness of the first electrode EU may be from about 1,000 Å to about 3,000 Å.

The organic layer OL is on the first electrode EL1. The organic layer OL may have a single layer formed of (e.g., consisting of) a single material, a single layer formed of multiple different materials or a multilayer structure having multiple layers formed of multiple different materials. For example, the organic layer OL may have a structure of a single layer of an emission layer EML, or a multilayer structure composed of a hole transport region HTR, an emission layer EML and an electron transport region ETR, but embodiments of the present disclosure are not limited thereto.

The organic layer OL of the organic electroluminescence device ED of one or more embodiments may include the polycyclic compound according to one or more embodiments. If the organic layer OL has a multilayer structure having multiple layers, any one layer selected from among the multiple layers may include the polycyclic compound according to one or more embodiments. For example, the organic layer OL may include a hole transport region HTR on the first electrode EL1, an emission layer on the hole transport region HTR and an electron transport region ETR on the emission layer, and the emission layer EML or the electron transport region ETR may include the polycyclic compound according to one or more embodiments.

In the description, the term “substituted or unsubstituted” corresponds to a group that is unsubstituted or that is substituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In addition, each of the exemplified substituents may be substituted or unsubstituted. For example, a biphenyl group may be interpreted as an aryl group or a phenyl group substituted with a phenyl group.

In the description, the term “forming a ring via the combination with an adjacent group” may mean forming a substituted or unsubstituted hydrocarbon ring, or a substituted or unsubstituted heterocycle via the combination with an adjacent group. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may each independently be monocycles (e.g., monocyclic) or polycycles (e.g., polycyclic). In one or more embodiments, the ring formed via the combination with an adjacent group may be combined with another ring to form a spiro structure.

In the description, the term “adjacent group” may refer to a pair of substituent groups where the first substituent is connected to an atom which is directly connected to another atom substituted with the second substituent; a pair of substituent groups connected to the same atom; or a pair of substituent groups where the first substituent is sterically positioned at the nearest position to the second substituent. For example, in 1,2-dimethylbenzene, two methyl groups may be interpreted as “adjacent groups” to each other, and in 1,1-diethylcyclopentene, two ethyl groups may be interpreted as “adjacent groups” to each other.

In the description, the halogen atom may be a fluorine atom, a chlorine atom, a bromine atom and/or an iodine atom.

In the description, the alkyl group may be a linear, branched or cyclic alkyl group. The carbon number of the alkyl group may be 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, 1-methylpentyl, 3-methylpentyl, 2-ethylpentyl, 4-methyl-2-pentyl, n-hexyl, 1-methylhexyl, 2-ethylhexyl, 2-butylhexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-heneicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the description, the cycloalkyl group may be an alkyl group of a cyclic structure. The carbon number of the cycloalkyl group may be 3 to 30, 3 to 20, or 3 to 10. Examples of the cycloalkyl group may include cyclopropyl, cyclobutyl, cyclopentyl, cyclohexyl, cycloheptyl, cyclooctyl, 1-methylcyclopropyl, 1-pentylcyclopropyl, 1,2-diethylcyclobutyl, 1-methylcyclobutyl, 1-butylcyclobutyl, 1,3-dimethylcyclobutyl, 1-methylcyclopentyl, 1-butylcyclopentyl, 1-methylcyclohexyl, 1-ethylcyclopentyl, etc., without limitation.

In the description, the bicycloalkyl group and the tricycloalkyl group represent one type (e.g., kind) of a cyclic structure. The bicycloalkyl group may be formed by two rings sharing one or more non-adjacent atoms like structures C-1 to C-4 below. The tricycloalkyl group may be formed by three rings sharing two or more non-adjacent atoms like structure C-5 below. In one or more embodiments, the bicycloalkyl group and the tricycloalkyl group may include a spiro group and a fused cyclic group. The ring-forming carbon number of the bicycloalkyl group and the tricycloalkyl group may be 5 to 30, 5 to 20, or 5 to 10. Examples of the bicycloalkyl group may include bicyclo[2.1.1]hexyl, bicyclo[2.2.1]heptyl, bicyclo[2.2.2]octyl, bicyclo[3.3.1]nonyl, bicyclo[4.2.1]nonyl, bicyclo[3.3.2]decyl, bicyclo[4.2.2]decyl, bicyclo[4.3.1]decyl, bicyclo[3.3.3]undecyl, bicyclo[4.3.2]undecyl, bicyclo[4.3.3]dodecyl, etc., but embodiments of the present disclosure are not limited thereto. Examples of the tricycloalkyl group may include an adamantyl group, but embodiments of the present disclosure are not limited thereto.

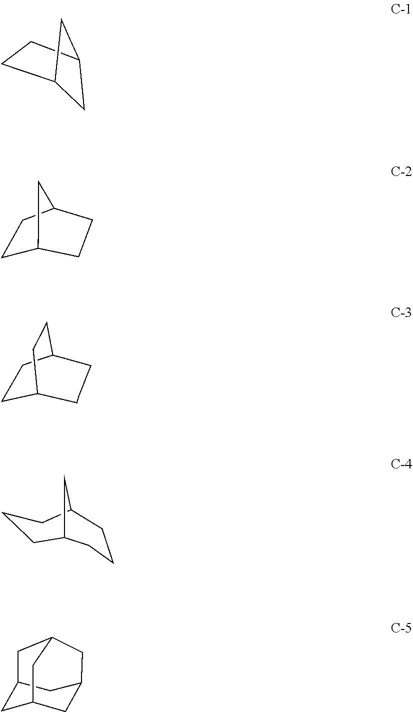 [SMILES: C1CC2CCC1C2 ; C1CC2CCC1C2 ; C1CC2CCCC(C1)CC2 ; C1CC2CCCC(C1)C2 ; C1C2CC3CC1CC(C2)C3]

In the description, the hydrocarbon ring group means an optional functional group or substituent derived from an aliphatic hydrocarbon ring and an aromatic hydrocarbon ring. The hydrocarbon ring group may be a saturated hydrocarbon ring group of 5 to 20 ring-forming carbon atoms, or an unsaturated hydrocarbon ring group of 2 to 20 ring-forming carbon atoms. The aliphatic hydrocarbon ring and the aromatic hydrocarbon ring may each independently be monocycles (e.g., monocyclic) or polycycles (e.g., polycyclic).

In the description, the aryl group means an optional functional group or substituent derived from an aromatic hydrocarbon ring. The aryl group may be a monocyclic aryl group or a polycyclic aryl group. The carbon number for forming rings in the aryl group may be 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, etc., without limitation.

In the description, the heteroaryl group may include one or more selected from among B, O, N, P, Si and S as heteroatoms. If the heteroaryl group includes two or more heteroatoms, two or more heteroatoms may be the same or different. The heteroaryl group may be a monocyclic heterocyclic group or a polycyclic heterocyclic group. The carbon number for forming rings of the heteroaryl group may be 2 to 30, 2 to 20, or 2 to 10. Examples of the heteroaryl group may include thiophene, furan, pyrrole, imidazole, triazole, pyridine, bipyridine, pyrimidine, triazine, triazole, acridine, pyridazine, pyrazine, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzoimidazole, benzothiazole, benzocarbazole, benzothiophene, dibenzothiophene, thienothiophene, benzofuran, phenanthroline, thiazole, isooxazole, oxazole, oxadiazole, thiadiazole, phenothiazine, dibenzosilole, dibenzofuran, etc., without limitation.

In the description, the explanation on the aryl group may be applied to the arylene group except that the arylene group is a divalent group. The explanation on the heteroaryl group may be applied to the heteroarylene group except that the heteroarylene group is a divalent group.

In the description, the silyl group includes an alkyl silyl group and an aryl silyl group. Examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., without limitation.

In the description, the thiol group may include an alkyl thio group and an aryl thio group. The thiol group may mean the above-defined alkyl group or aryl group combined with a sulfur atom. Examples of the thiol group include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the description, the oxy group may mean the above-defined alkyl group or aryl group which is combined with an oxygen atom. The oxy group may include an alkoxy group and an aryl oxy group. The alkoxy group may be a linear, branched or cyclic chain. The carbon number of the alkoxy group is not specifically limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc. However, embodiments of the present disclosure are not limited thereto.

In the description, the alkenyl group may be a linear chain or a branched chain. The carbon number is not specifically limited but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styrylvinyl group, etc., without limitation.

In the description, the carbon number of the amine group is not specifically limited, but may be 1 to 30. The amine group may include an alkyl amine group and an aryl amine group. Examples of the amine group include a methylamine group, a dimethylamine group, a phenylamine group, a diphenylamine group, a naphthylamine group, a 9-methyl-anthracenylamine group, a triphenylamine group, etc., without limitation.

In the description, a direct linkage may mean a chemical bond (e.g., a single bond).

Meanwhile, in the description,

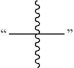

and “-*” mean positions to be connected (e.g., a binding site).

The polycyclic compound according to one or more embodiments may be represented by Formula 1 below.

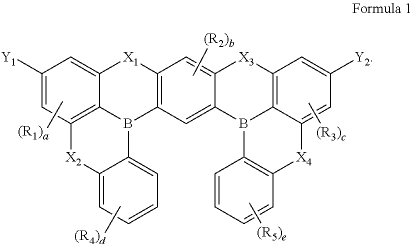

In Formula 1, X₁ to X₄ are each independently CR₆R₇, NR₈, O, S, or Se.

In Formula 1, R₁ to R₇ are each independently a hydrogen atom, a deuterium atom, a halogen atom, a nitro group, a cyano group, a hydroxyl group, a substituted or unsubstituted amine group, a substituted or unsubstituted thiol group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring.

In Formula 1, R₈ is a hydrogen atom, a deuterium atom, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring.

In Formula 1, Y₁ and Y₂ are each independently a hydrogen atom, a deuterium atom, a halogen atom, a substituted or unsubstituted silyl group, a substituted or unsubstituted oxy group, a substituted or unsubstituted amine group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring.

In Formula 1, “a” is an integer of 0 to 2. Meanwhile, if “a” is 2, multiple R₁ groups are the same or different.

In Formula 1, “b” is an integer of 0 to 2. Meanwhile, if “b” is 2, multiple R₂ groups are the same or different.

In Formula 1, “c” is an integer of 0 to 2. Meanwhile, if “c” is 2, multiple R₃ groups are the same or different.

In Formula 1, “d” is an integer of 0 to 4. Meanwhile, if “d” is 2 or more, multiple R₄ groups are the same or different.

In Formula 1, “e” is an integer of 0 to 4. Meanwhile, if “e” is 2 or more, multiple R₅ groups are the same or different.

In one or more embodiments, X₁ to X₄ may be all O, S, or Se, or all may be NR₈.

In one or more embodiments, one selected from among X₁ to X₄ may be 0, S, or Se, and remaining three may be NR₈.

In one or more embodiments, two selected from among X₁ to X₄ may be 0, S, or Se, and remaining two may be NR₈.

In one or more embodiments, three selected from among X₁ to X₄ may be 0, S, or Se, and remaining one may be NR₈.

In Formula 1, at least one selected from among Y₁ and Y₂ is represented by Formula 2-1 or Formula 2-2 below.

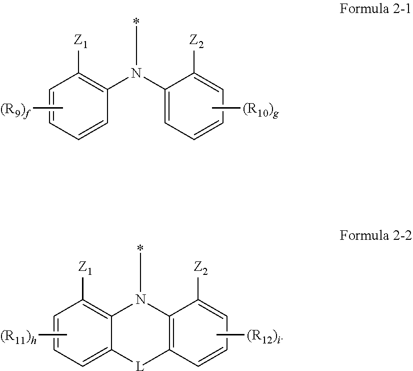

In Formula 2-1 and Formula 2-2, Z₁ and Z₂ are each independently a substituted or unsubstituted silyl group, a substituted or unsubstituted alkyl group of 1 to 20 carbon atoms, a substituted or unsubstituted cycloalkyl group of 3 to 20 carbon atoms, a substituted or unsubstituted bicycloalkyl group of 5 to 30 carbon atoms, or a substituted or unsubstituted tricycloalkyl group of 8 to 30 carbon atoms.

In Formula 2-1 and Formula 2-2, “-*” represents a position to be connected with Formula 1.

In Formula 2-1 and Formula 2-2, R₉ to R₁₂ are each independently a hydrogen atom, a deuterium atom, a halogen atom, a cyano group, a nitro group, a hydroxyl group, a substituted or unsubstituted silyl group, a substituted or unsubstituted oxy group, a substituted or unsubstituted thiol group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring.

In Formula 2-1, “f” is an integer of 0 to 4. Meanwhile, if “f” is 2 or more, multiple R₉ groups are the same or different.

In Formula 2-1, “g” is an integer of 0 to 4. Meanwhile, if “g” is 2 or more, multiple R₁₀ groups are the same or different.

In Formula 2-2, L is a direct linkage, CR₁₃R₁₄, O, or S.

In Formula 2-2, R₁₃ and R₁₄ are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula 2-2, “h” is an integer of 0 to 3. Meanwhile, if “h” is 2 or more, multiple R₁₁ groups are the same or different.

In Formula 2-2, “i” is an integer of 0 to 3. Meanwhile, if “i” is 2 or more, multiple R₁₂ groups are the same or different.

In one or more embodiments, Formula 2-2 may be represented by Formula 3 below.

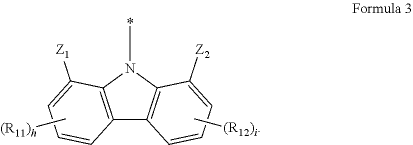

In Formula 3, Z₁, Z₂, R₁₁, R₁₂, “h”, and “i” are the same as defined in Formula 2-2.

In one or more embodiments, Z₁ and Z₂ may be each independently a silyl group substituted with a substituted or unsubstituted alkyl group of 1 to 10 carbon atoms, a substituted or unsubstituted alkyl group of 1 to 10 carbon atoms, a substituted or unsubstituted cycloalkyl group of 3 to 10 carbon atoms, a substituted or unsubstituted bicycloalkyl group of 5 to 10 carbon atoms, or a substituted or unsubstituted tricycloalkyl group of 8 to 12 carbon atoms.

In one or more embodiments, Z₁ and Z₂ may be each independently a methyl group, an ethyl group, an isopropyl group, a t-butyl group, a trimethylsilyl group, a cyclopentyl group, a cyclohexyl group, or an adamantyl group.

In one or more embodiments, Formula 1 may be represented by any one selected from among Formula 4-1 to Formula 4-4 below.

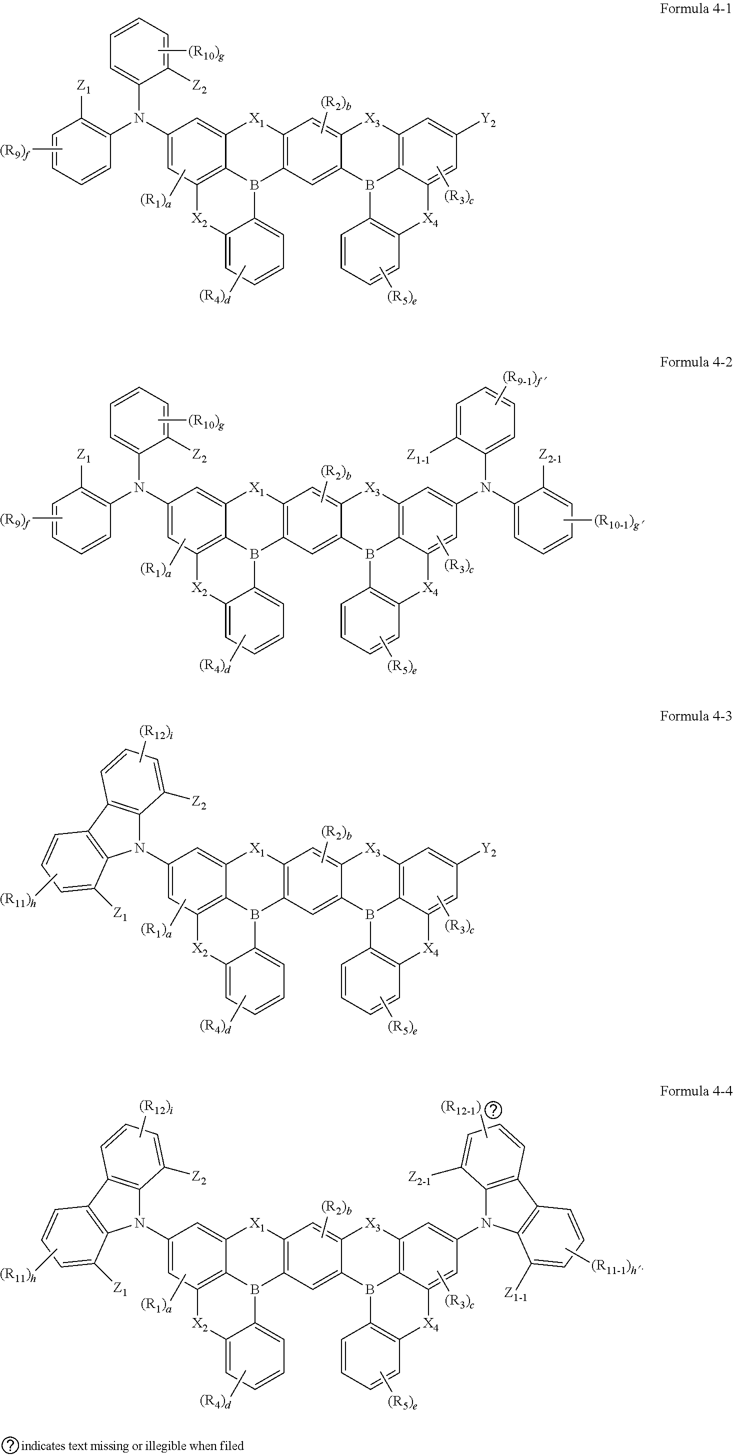

In Formula 4-2 and Formula 4-4, Z₁₋₁ and Z₂₋₁ may be each independently a substituted or unsubstituted silyl group, a substituted or unsubstituted alkyl group of 1 to 20 carbon atoms, a substituted or unsubstituted cycloalkyl group of 3 to 20 carbon atoms, a substituted or unsubstituted bicycloalkyl group of 5 to 30 carbon atoms, or a substituted or unsubstituted tricycloalkyl group of 8 to 30 carbon atoms.

In Formula 4-2 and Formula 4-4, R₉₋₁, R₁₀₋₁, R₁₁₋₁, and R₁₂₋₁ may be each independently a hydrogen atom, a deuterium atom, a halogen atom, a cyano group, a nitro group, a hydroxyl group, a substituted or unsubstituted silyl group, a substituted or unsubstituted oxy group, a substituted or unsubstituted thiol group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring.

In Formula 4-2, “f” is an integer of 0 to 4. Meanwhile, if “f” is 2 or more, multiple R₉₋₁ groups are the same or different.

In Formula 4-2, “g” is an integer of 0 to 4. Meanwhile, if “g′” is 2 or more, multiple R₁₀₋₁ groups are the same or different.

In Formula 4-4, “h” is an integer of 0 to 3. Meanwhile, if “h′” is 2 or more, multiple R₁₁₋₁ groups are the same or different.

In Formula 4-4, “i′” is an integer of 0 to 3. Meanwhile, if “i′” is 2 or more, multiple R₁₂₋₁ groups are the same or different.

In Formula 4-1 to Formula 4-4, X₁ to X₄, R₁ to R₅, “a” to “e”, Y₂, Z₁, Z₂, R₉ to R₁₂, and “f” to “i” are the same as defined in Formula 1 and Formula 2.

In one or more embodiments, at least one selected from among X₁ to X₄ may be NAr₁, and Ar₁ may be a substituted or unsubstituted aryl group of 6 to 30 ring-forming carbon atoms, or a substituted or unsubstituted heteroaryl group of 2 to 30 ring-forming carbon atoms.

In one or more embodiments, Formula 1 may be represented by any one selected from among Formula 5-1 to Formula 5-5 below.

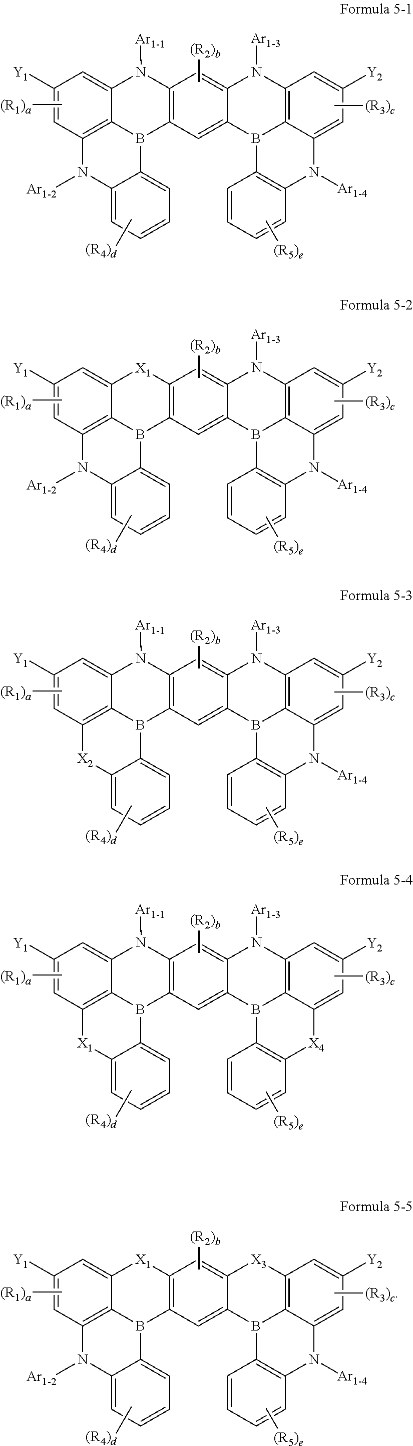

In Formula 5-1 to Formula 5-5, X₁ to X₄ may be each independently O, S, or Se.

In Formula 5-1 to Formula 5-5, Ar₁₋₁ to Ar₁₋₄ may be each independently a substituted or unsubstituted aryl group of 6 to 30 ring-forming carbon atoms, or a substituted or unsubstituted heteroaryl group of 2 to 30 ring-forming carbon atoms.

In Formula 5-1 to Formula 5-5, Y₁, Y₂, R₁ to R₅, and “a” to “e” are the same as defined in Formula 1.

In one or more embodiments, Ar₁₋₁ to Ar₁₋₄ may be each independently represented by any one selected from among Formula 6-1 to Formula 6-3 below.

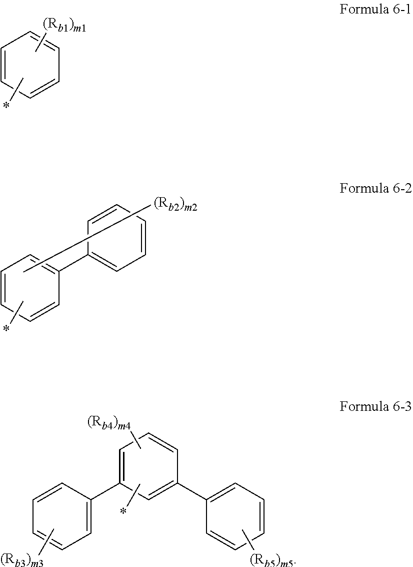

In Formula 6-1 to Formula 6-3, R_{b1} to R_{b5} may be each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring.

In Formula 6-1, “m1” is an integer of 0 to 5. Meanwhile, if “m1” is 2 or more, multiple R_{b1} groups are the same or different.

In Formula 6-2, “m2” is an integer of 0 to 9. Meanwhile, if “m2” is 2 or more, multiple R_{b2} groups are the same or different.

In Formula 6-3, “m3” is an integer of 0 to 5. Meanwhile, if “m3” is 2 or more, multiple R_{b3} groups are the same or different.

In Formula 6-3, “m4” is an integer of 0 to 3. Meanwhile, if “m4” is 2 or more, multiple R_{b4} groups are the same or different.

In Formula 6-3, “m5” is an integer of 0 to 5. Meanwhile, if “m5” is 2 or more, multiple R_{b5} groups are the same or different.

In one or more embodiments, the polycyclic compound represented by Formula 1 may be any one selected from the compounds represented in Compound Group 1 below. However, embodiments of the present disclosure are not limited thereto.

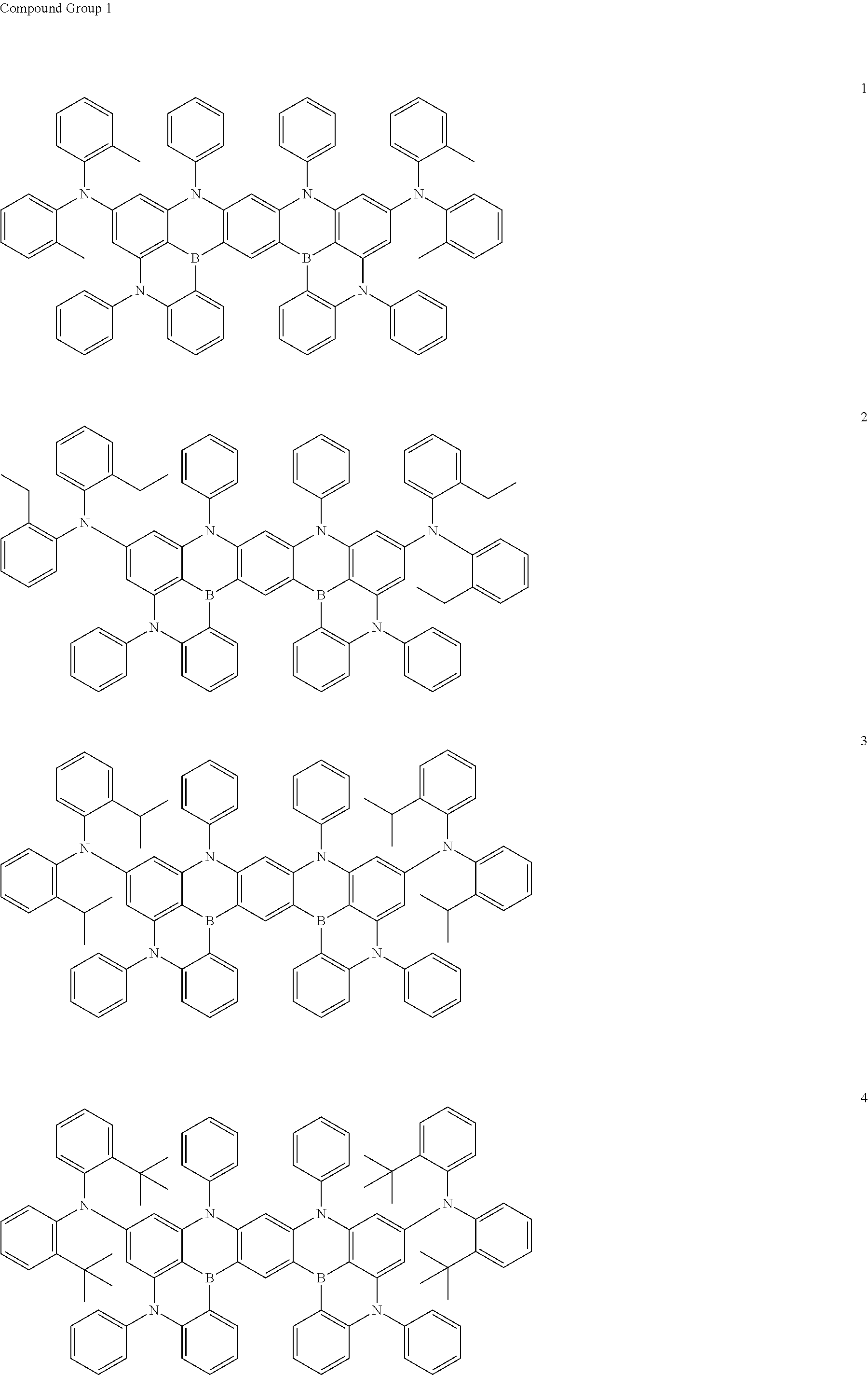

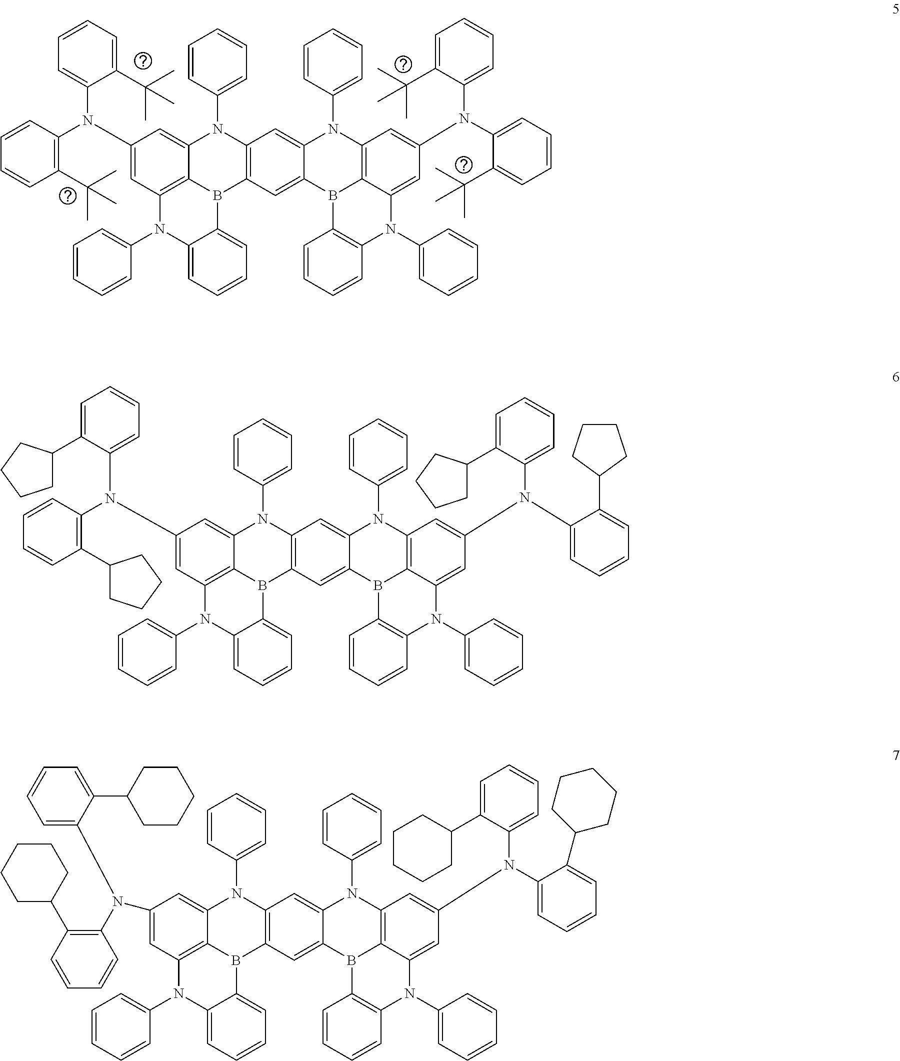

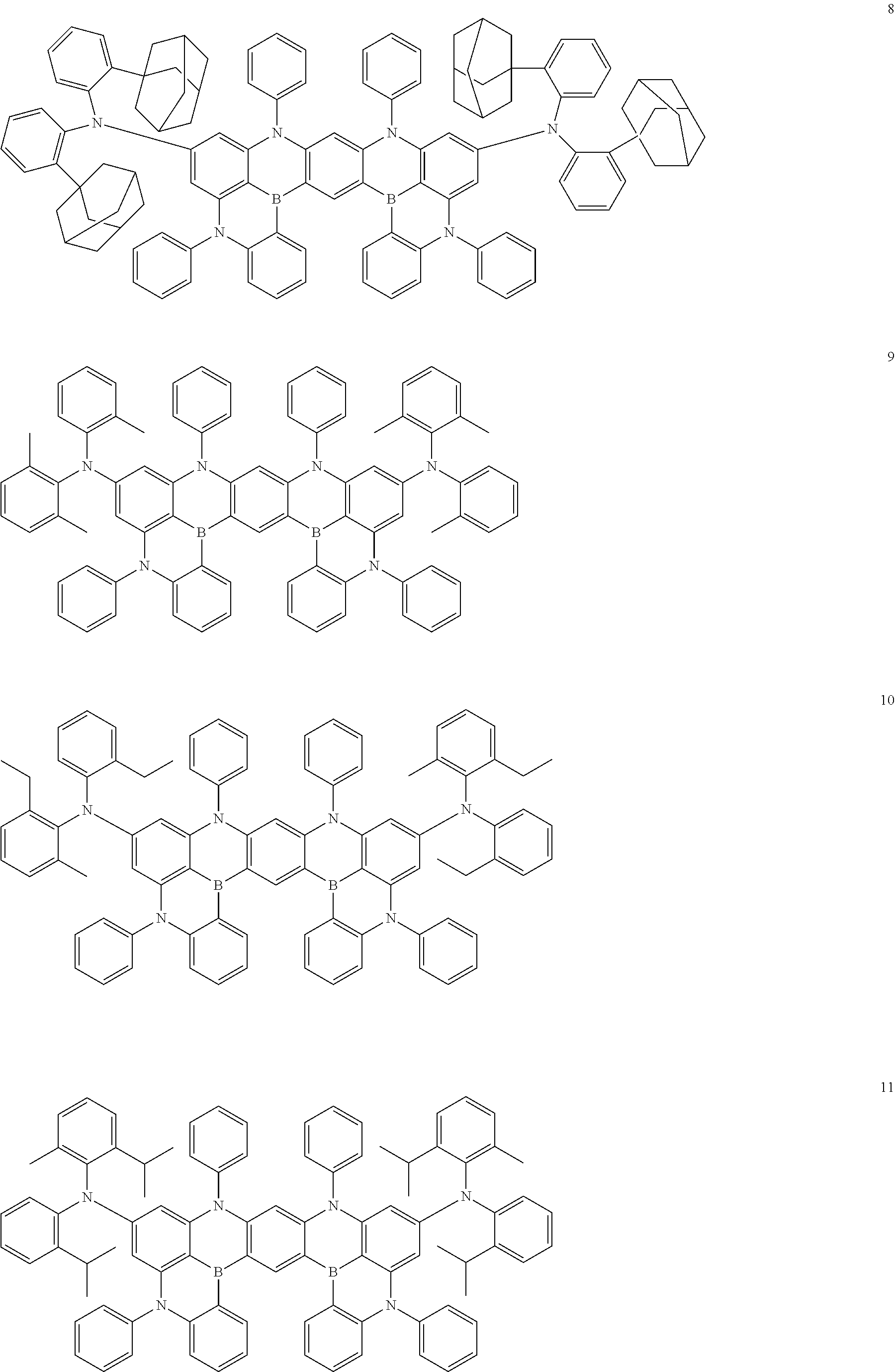

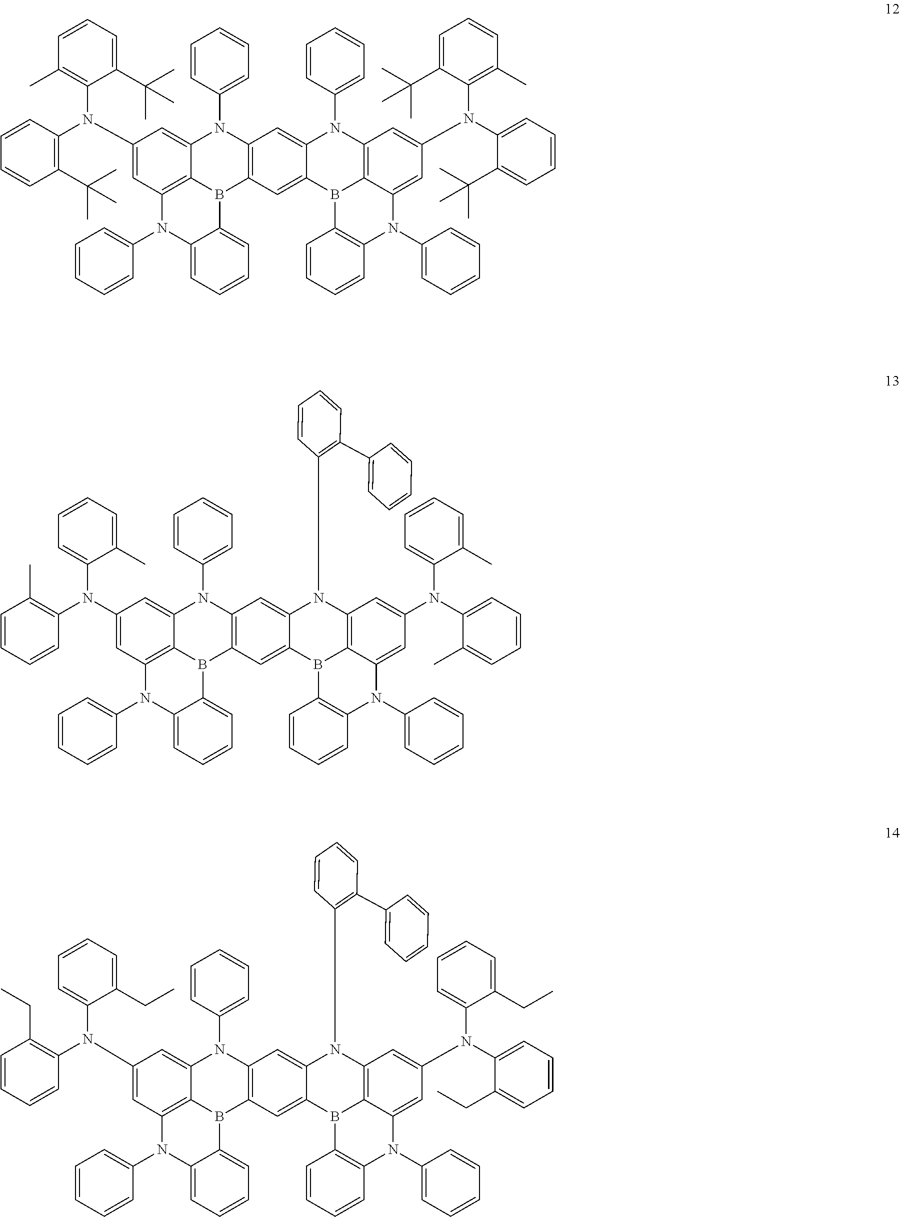 [SMILES: Cc1cccc(C(C)(C)C)c1N(c1cc2c3c(c1)N(c1ccccc1)c1cc4c(cc1B3c1ccccc1N2c1ccccc1)B1c2ccccc2N(c2ccccc2)c2cc(N(c3ccccc3C(C)(C)C)c3c(C)cccc3C(C)(C)C)cc(c21)N4c1ccccc1)c1ccccc1C(C)(C)C ; Cc1ccccc1N(c1cc2c3c(c1)N(c1ccccc1)c1cc4c(cc1B3c1ccccc1N2c1ccccc1)B1c2ccccc2N(c2ccccc2)c2cc(N(c3ccccc3C)c3ccccc3C)cc(c21)N4c1ccccc1-c1ccccc1)c1ccccc1C ; CCc1ccccc1N(c1cc2c3c(c1)N(c1ccccc1)c1cc4c(cc1B3c1ccccc1N2c1ccccc1)B1c2ccccc2N(c2ccccc2)c2cc(N(c3ccccc3CC)c3ccccc3CC)cc(c21)N4c1ccccc1-c1ccccc1)c1ccccc1CC]

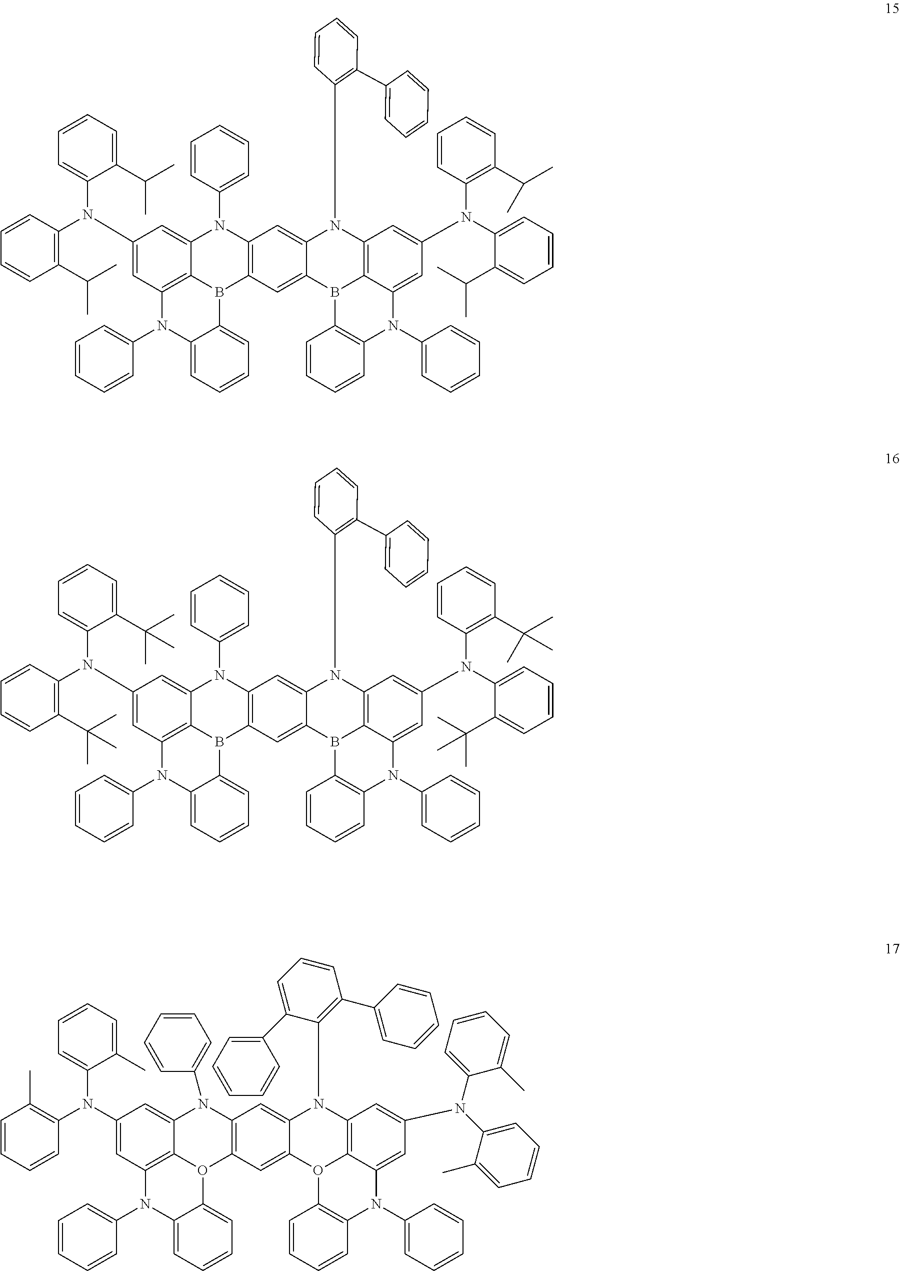

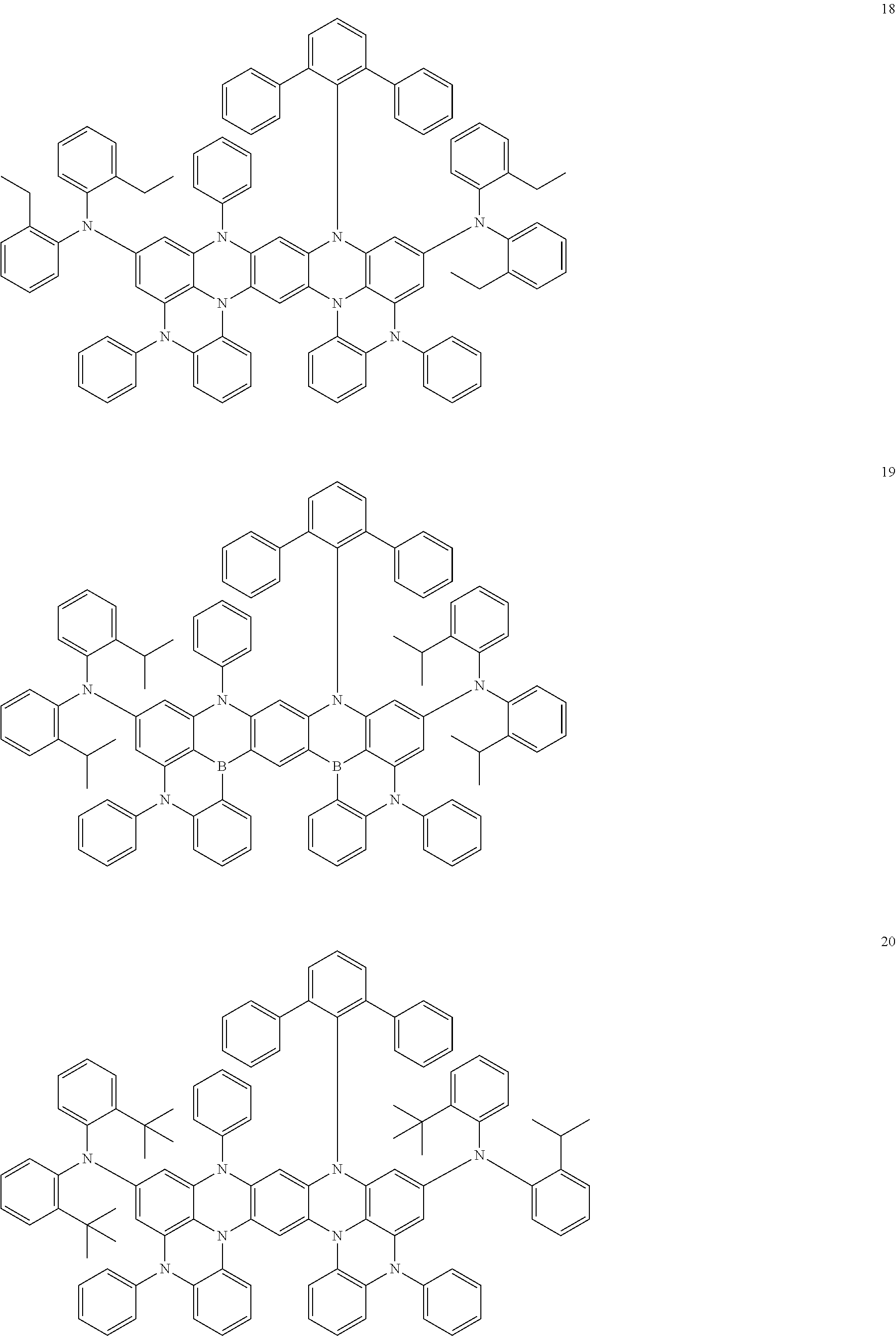

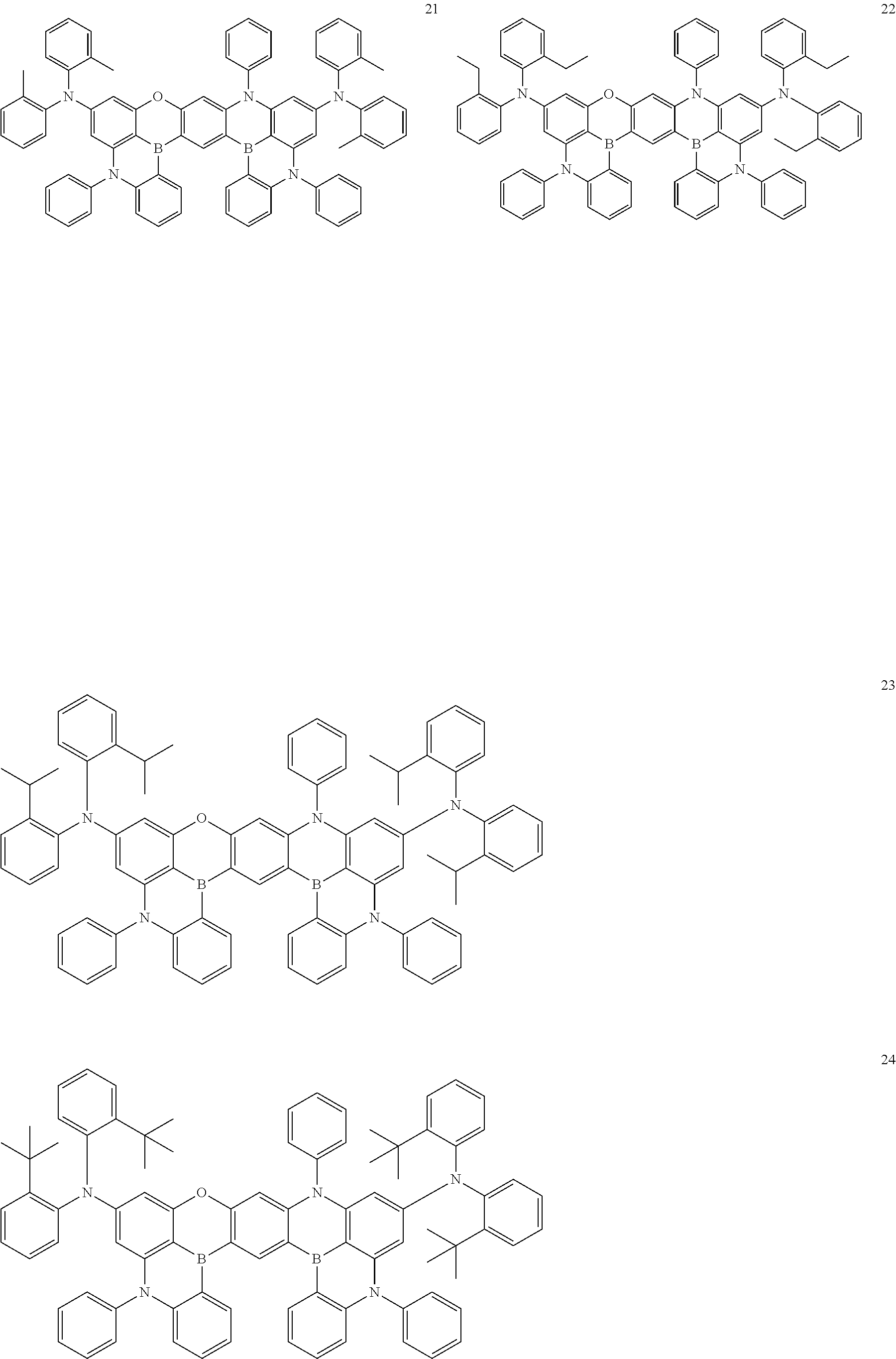

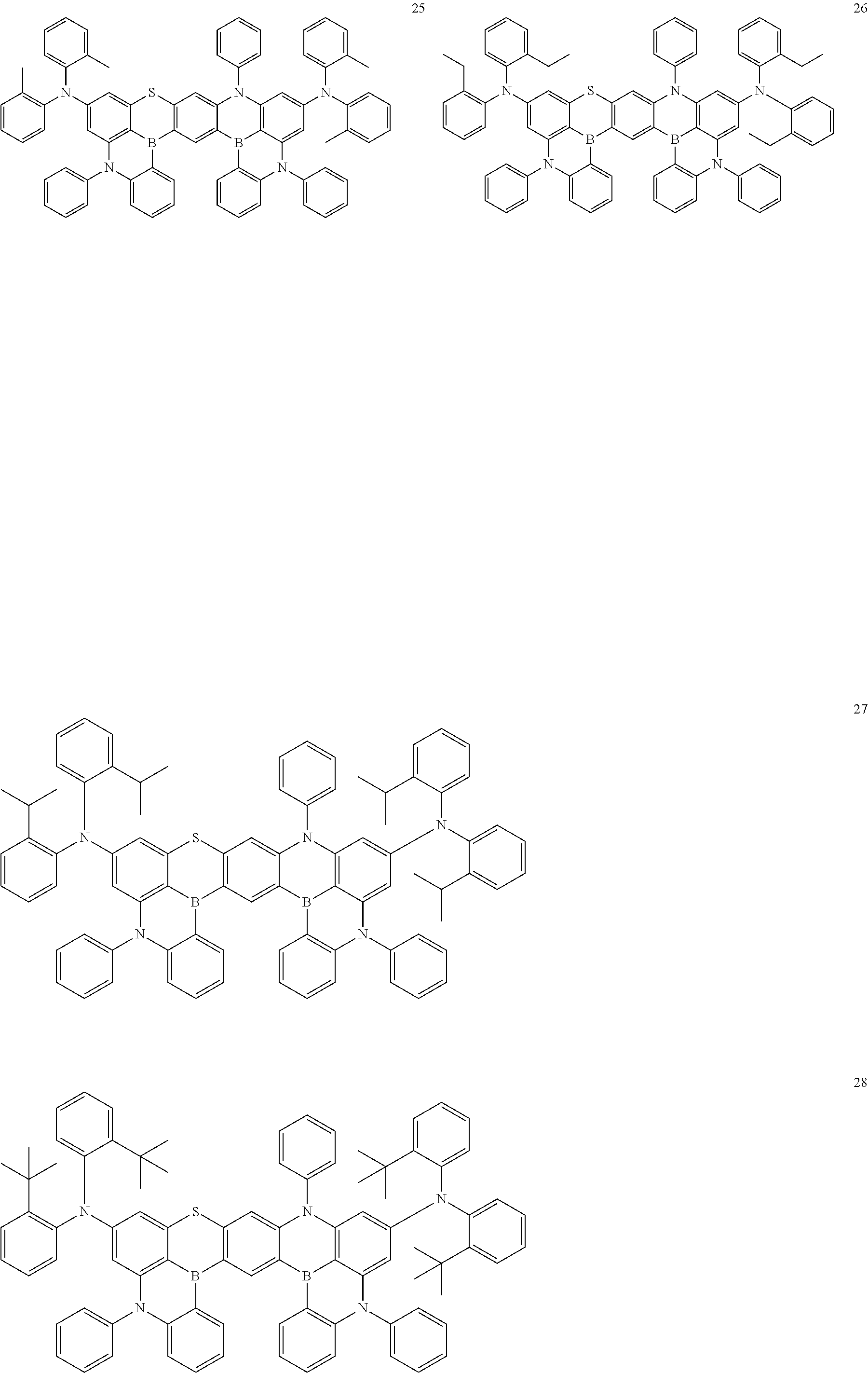

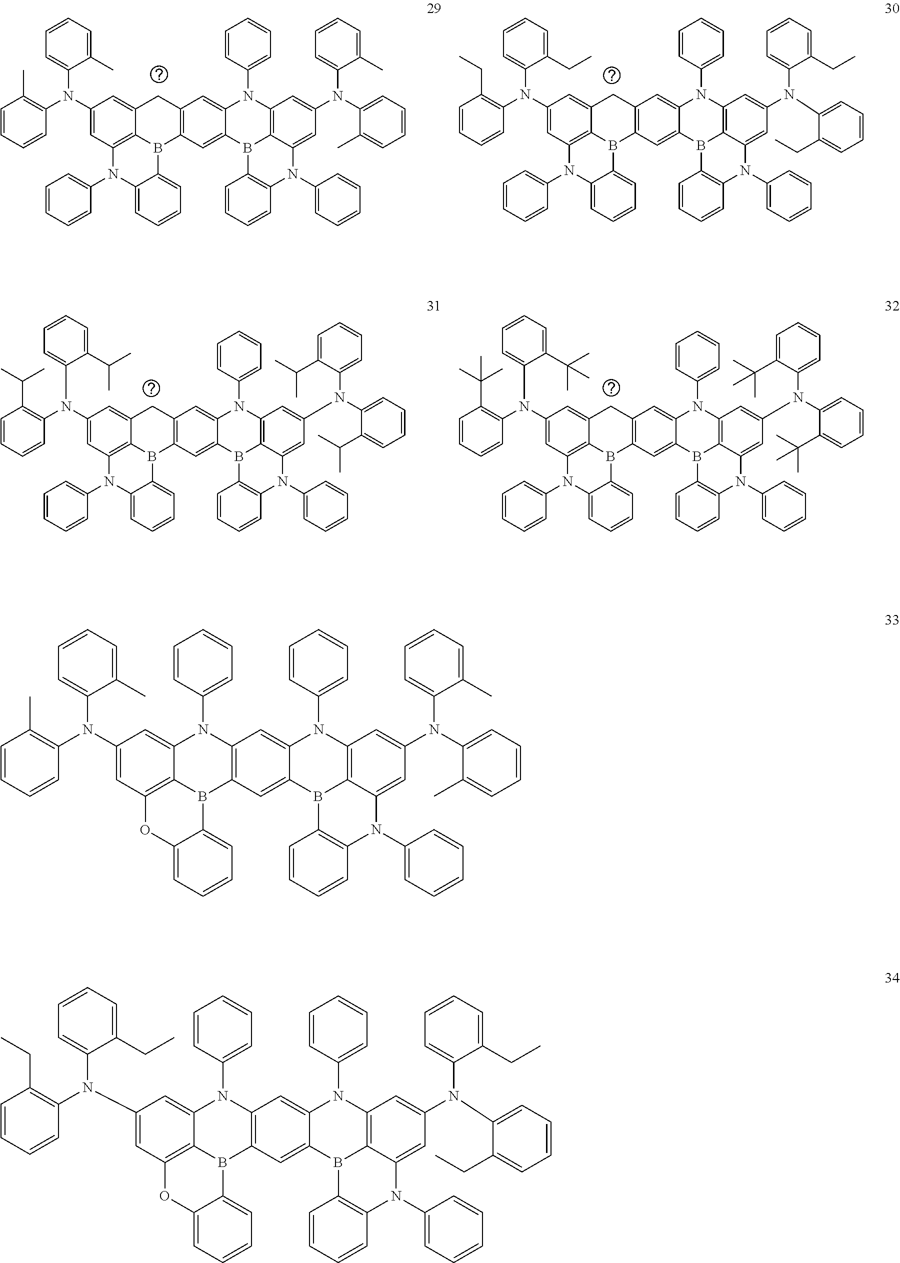

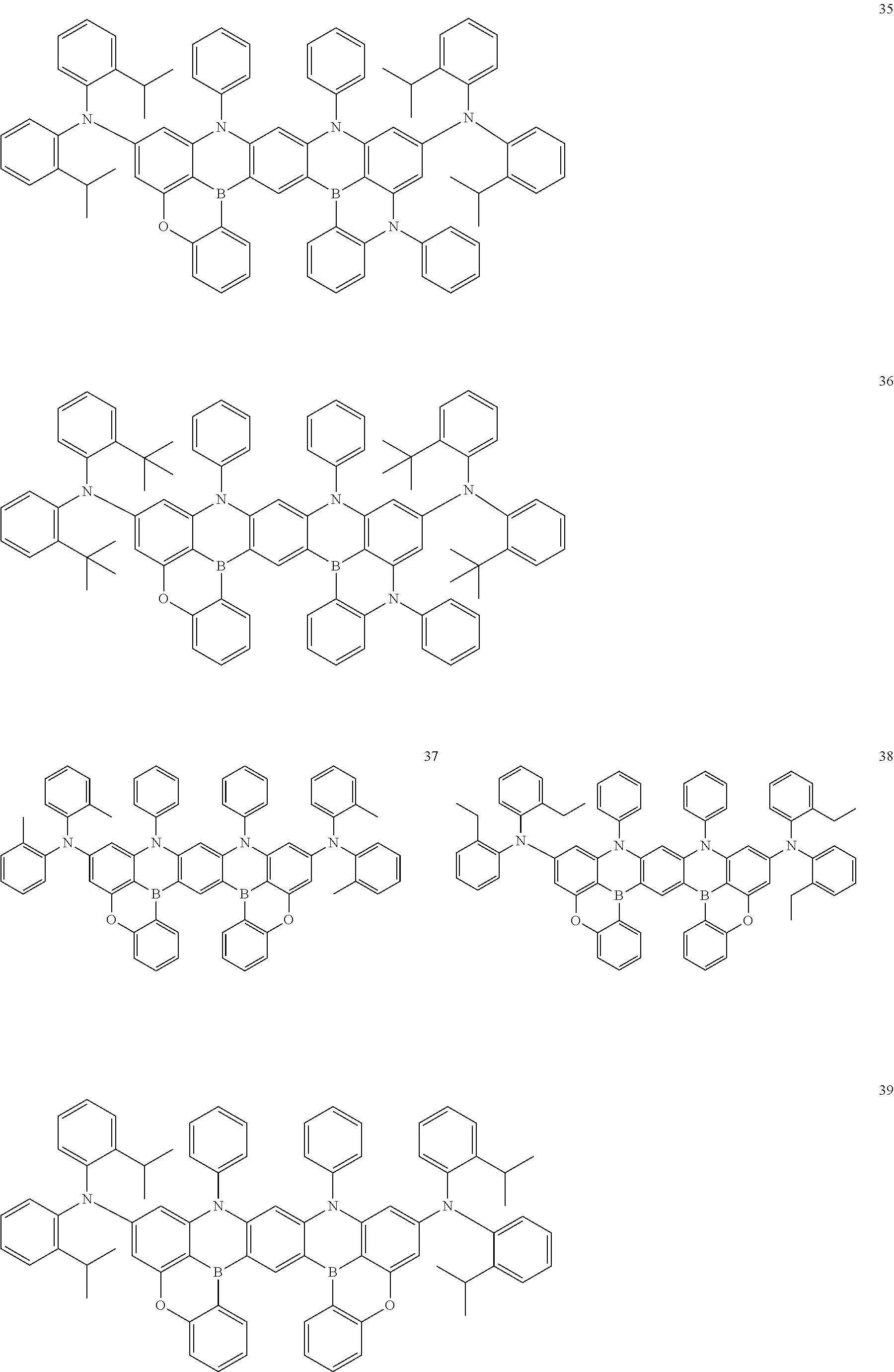

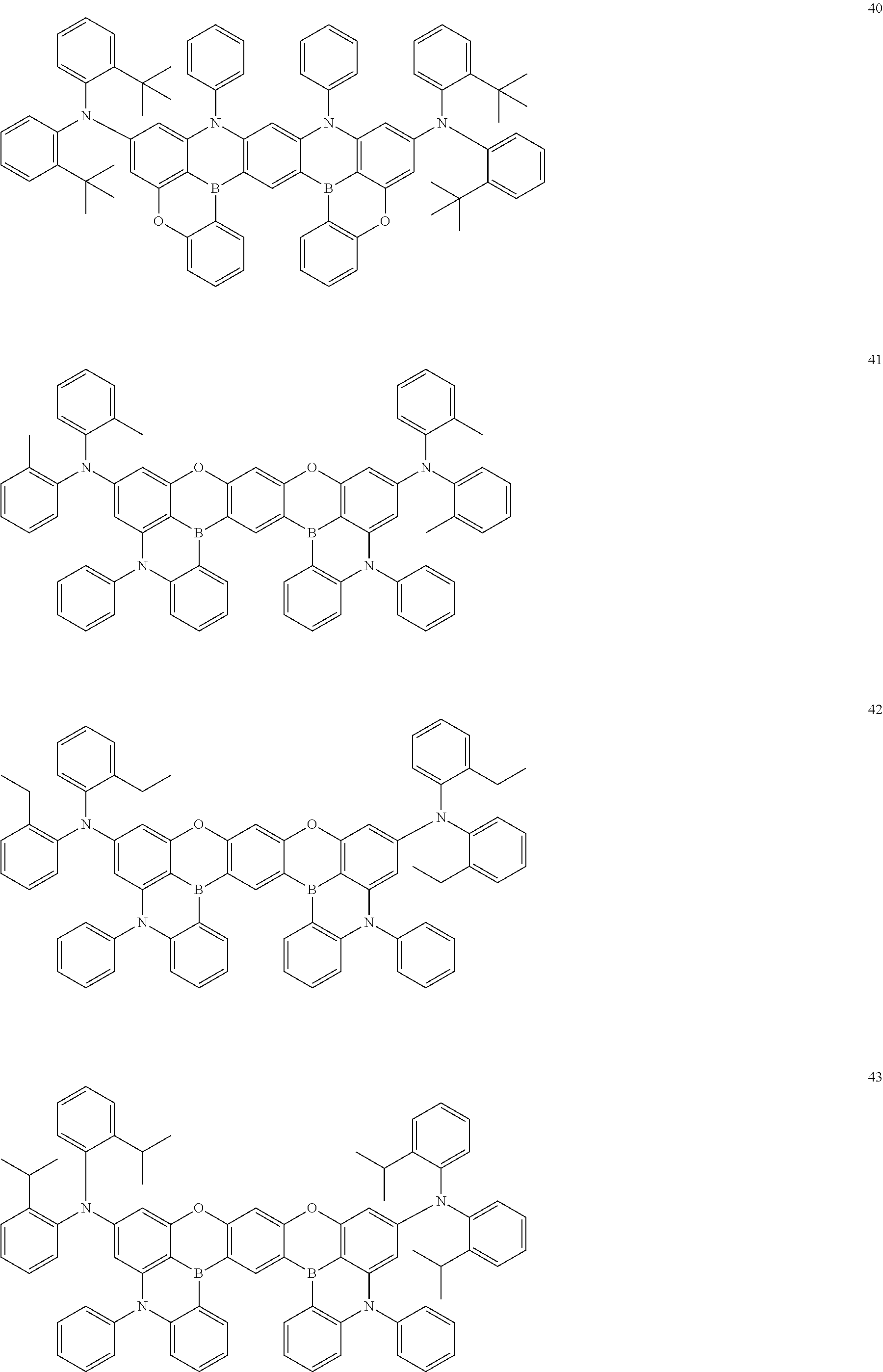

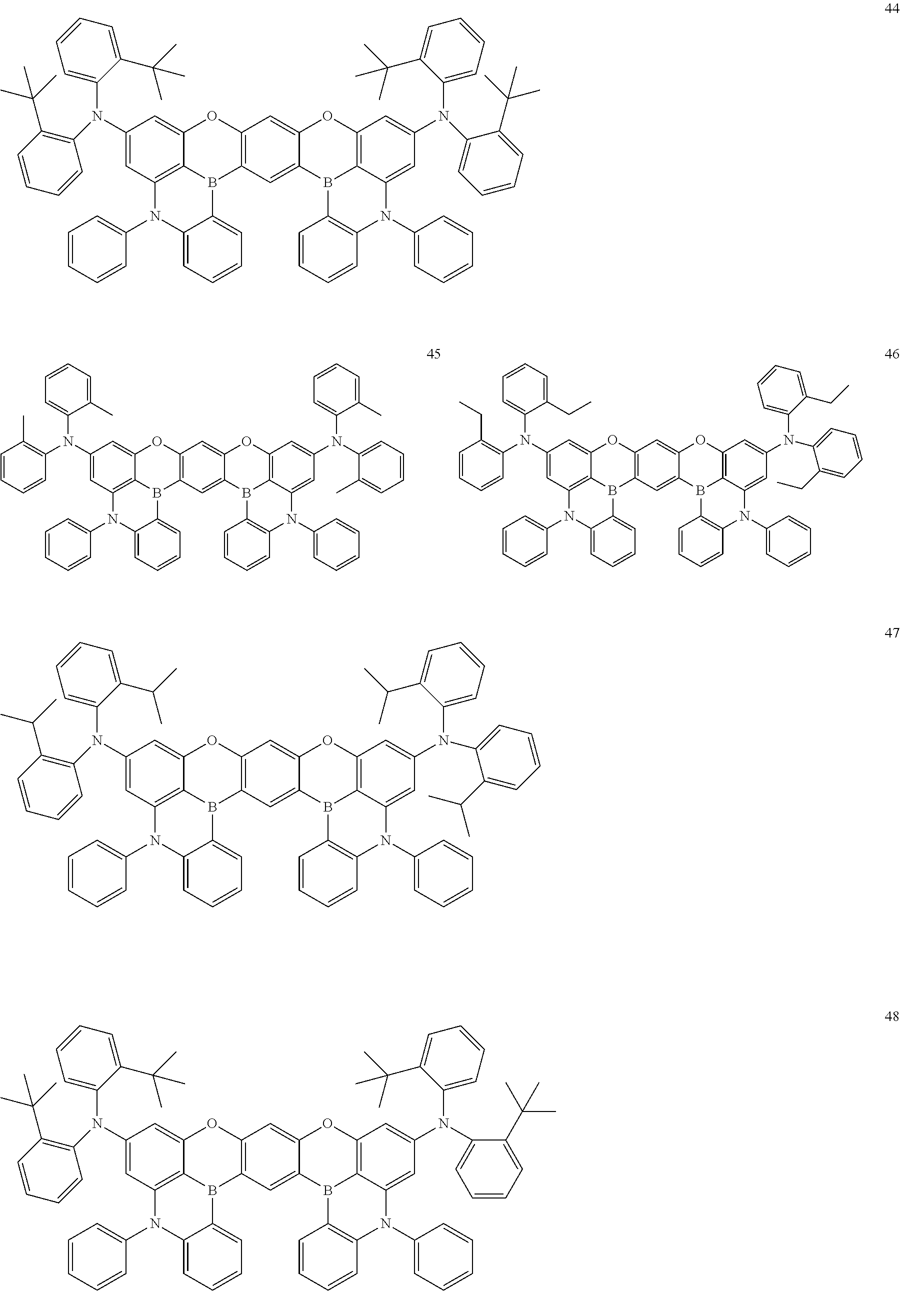

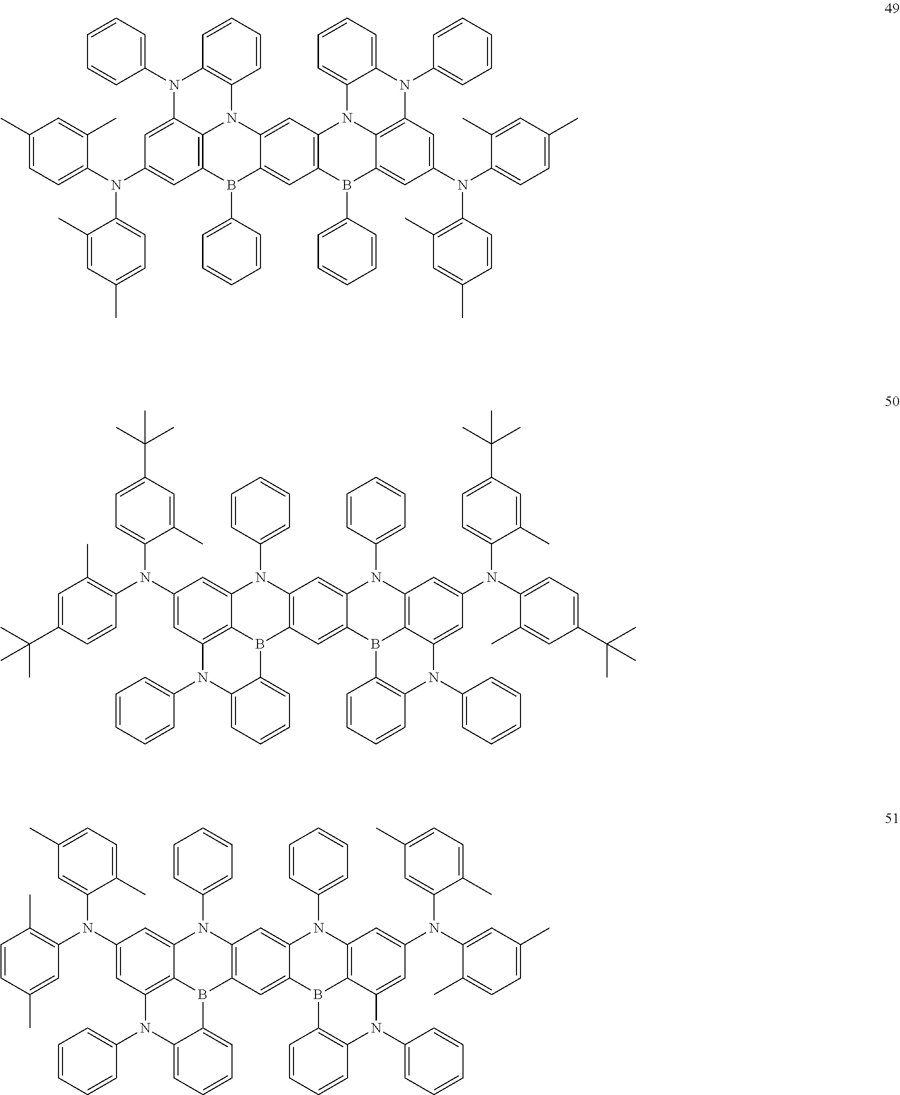

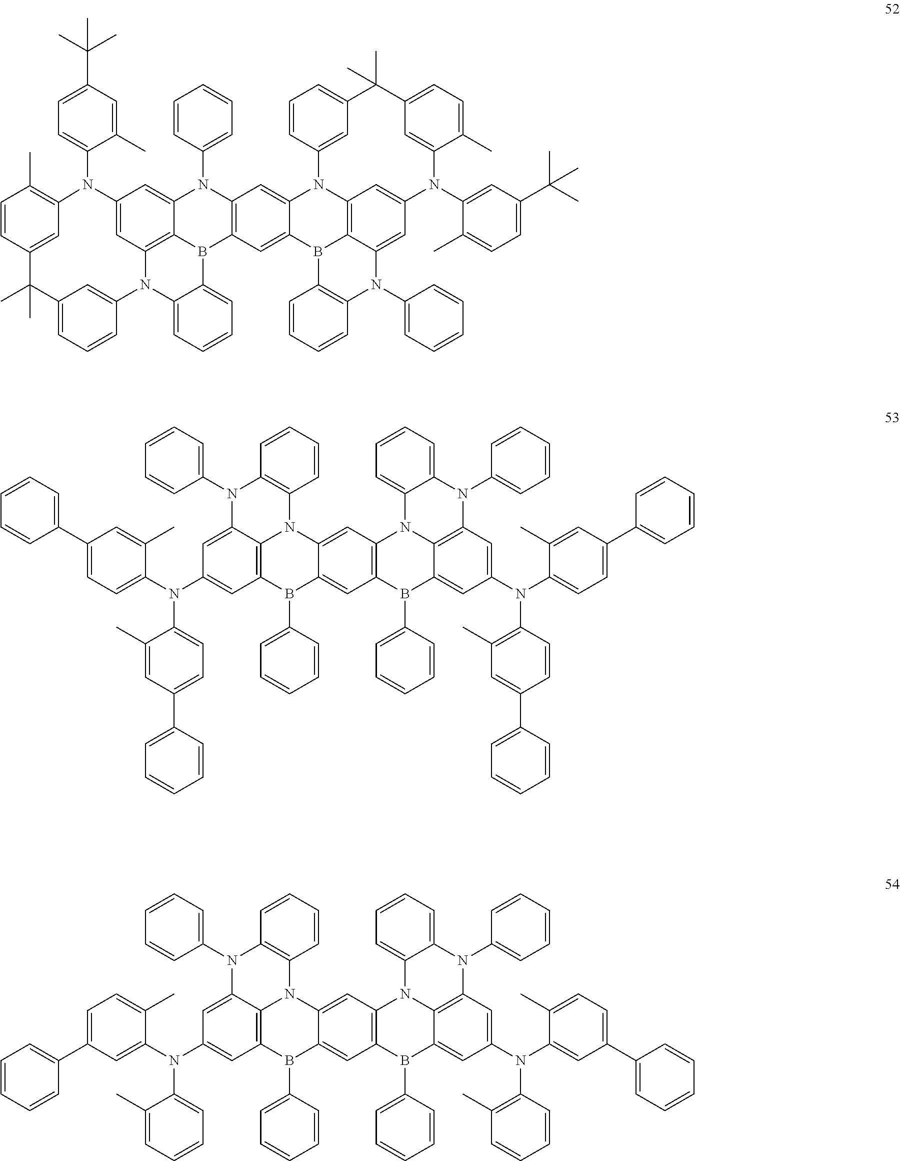

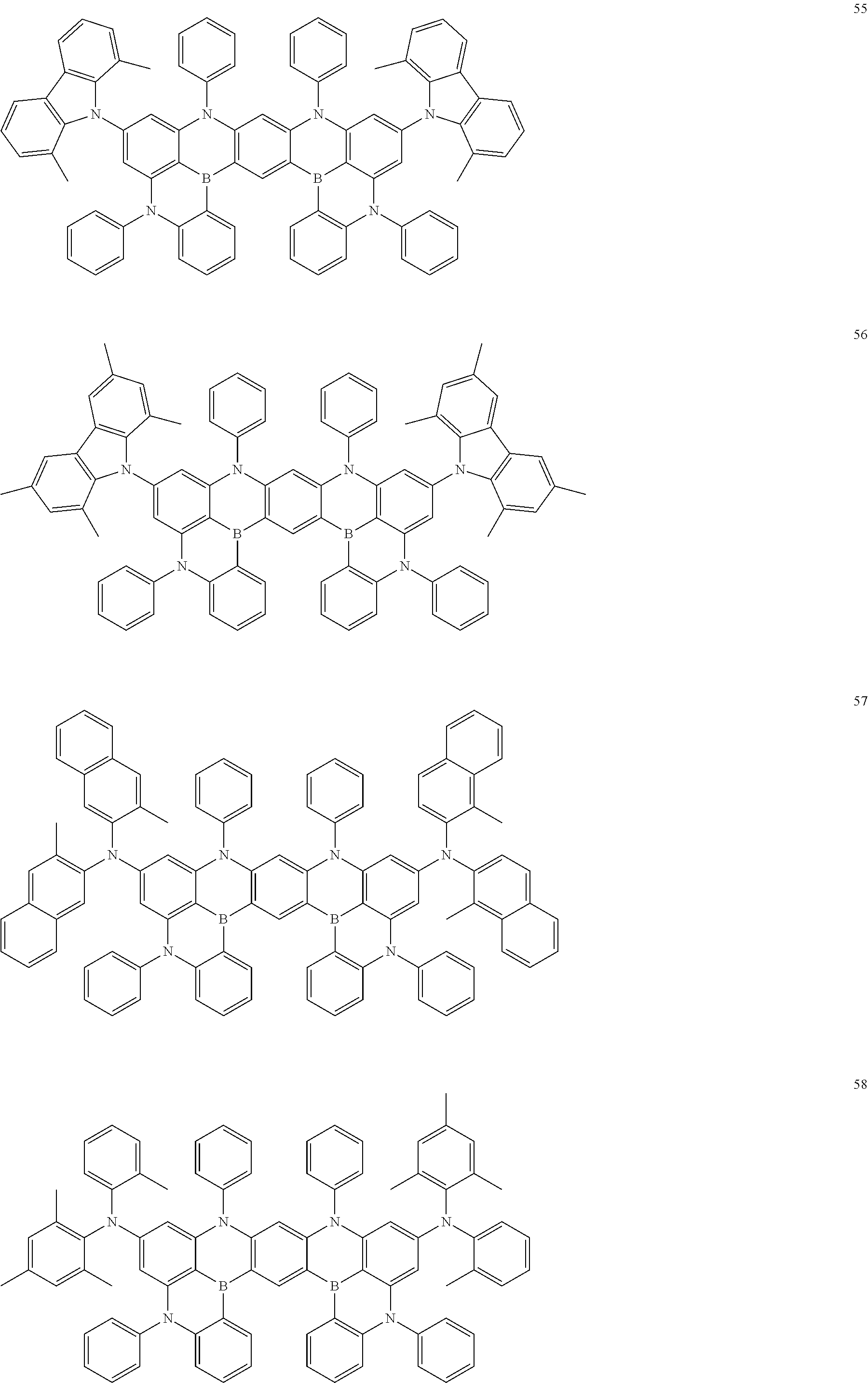

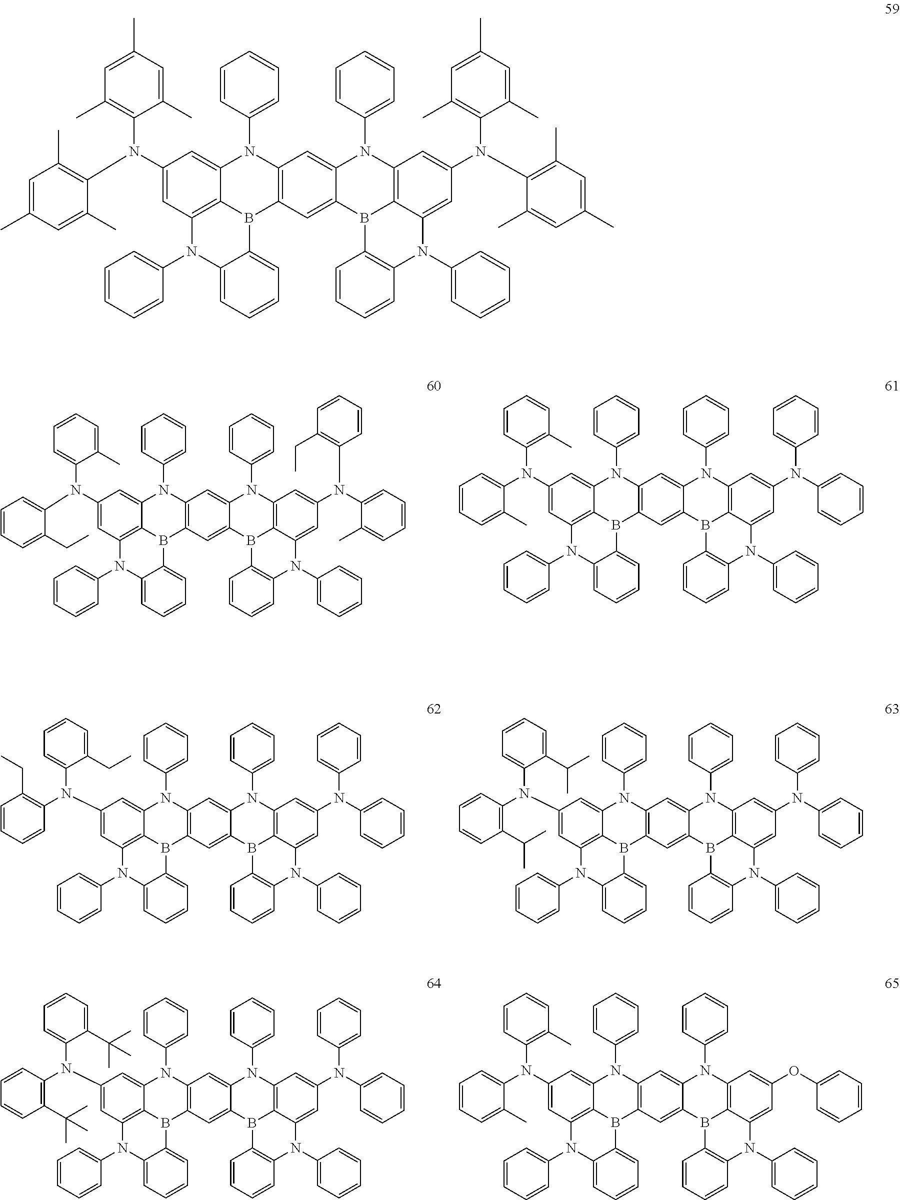

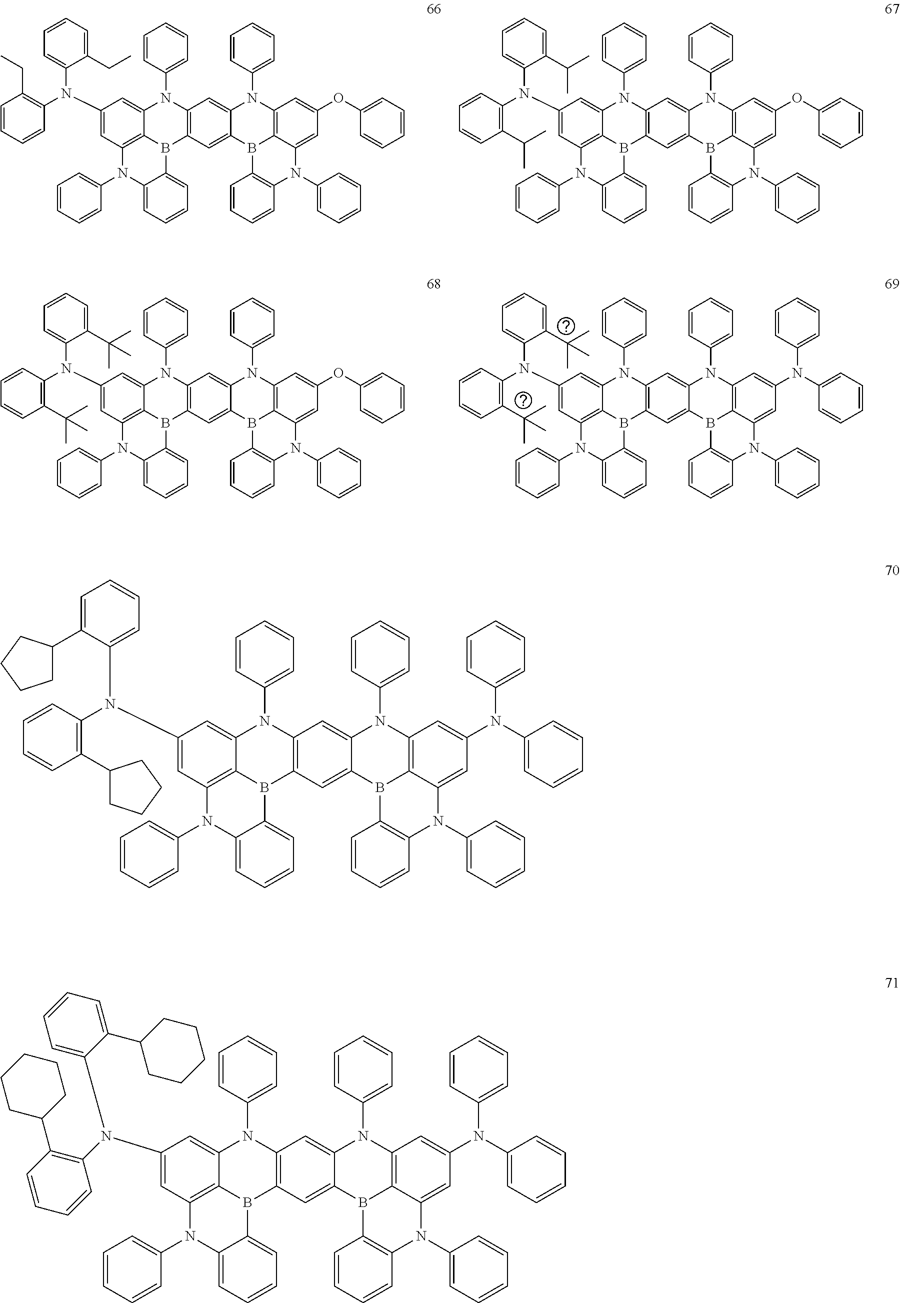

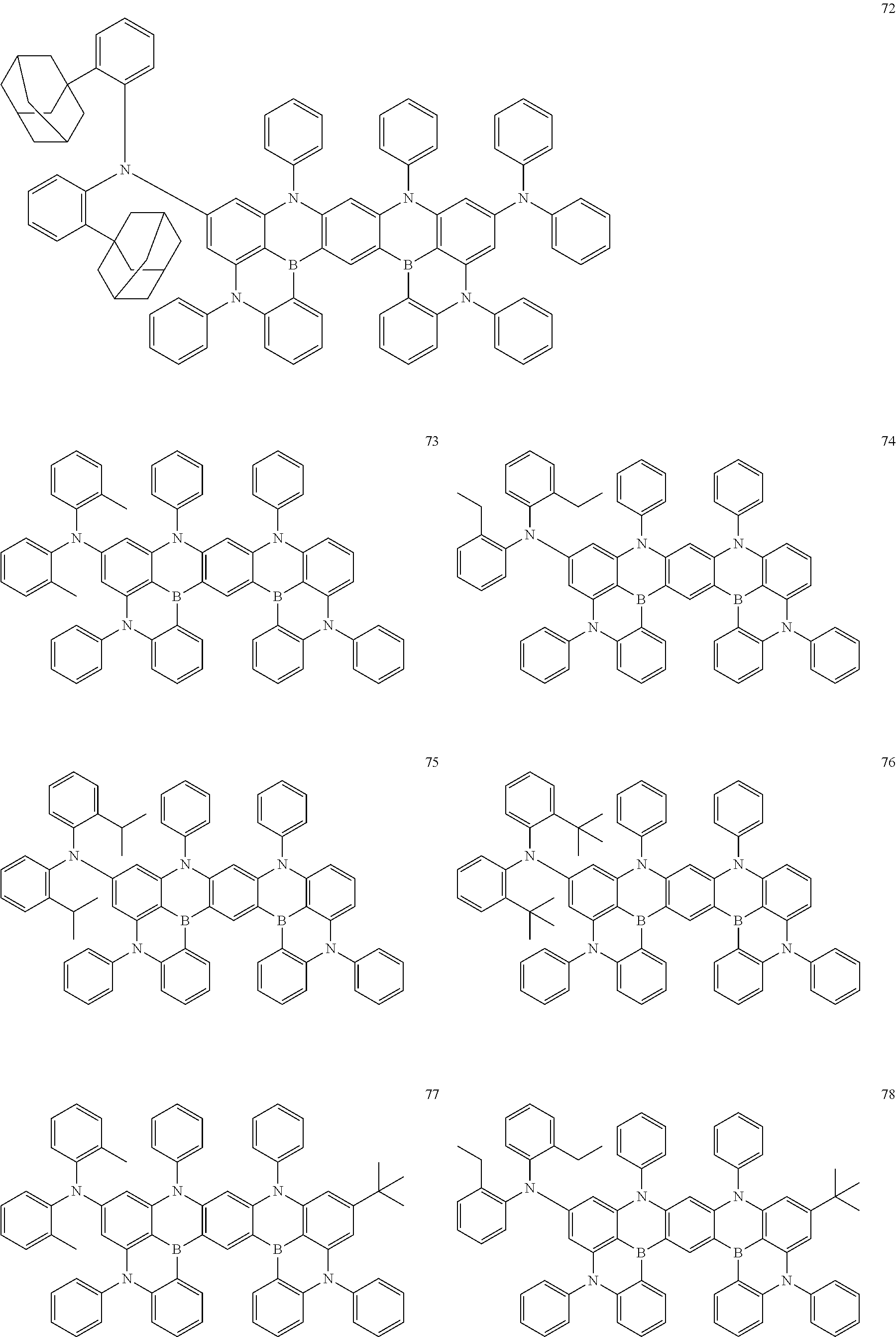

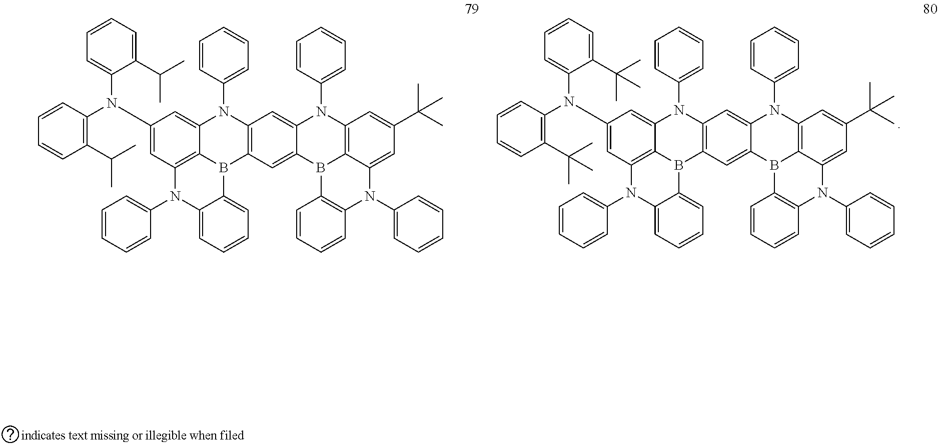 [SMILES: CC(C)c1ccccc1N(c1cc2c3c(c1)N(c1ccccc1)c1cc4c(cc1B3c1ccccc1N2c1ccccc1)B1c2ccccc2N(c2ccccc2)c2cc(C(C)(C)C)cc(c21)N4c1ccccc1)c1ccccc1C(C)C ; CC(C)(C)c1cc2c3c(c1)N(c1ccccc1)c1cc4c(cc1B3c1ccccc1N2c1ccccc1)B1c2ccccc2N(c2ccccc2)c2cc(N(c3ccccc3C(C)(C)C)c3ccccc3C(C)(C)C)cc(c21)N4c1ccccc1]

The polycyclic compound represented by Formula 1 according to one or more embodiments includes a group represented by Formula 2-1 or Formula 2-2 including an alkyl group at a specific position, and thus, may improve color purity, attain the blue shift of the wavelength of emitting light, and finely control the wavelength of emitting light.

For example, the polycyclic compound represented by Formula 1 according to one or more embodiments includes one or more groups represented by Formula 2-1 and/or Formula 2-2 at set or specific positions. The groups represented by Formula 2-1 and Formula 2-2 include substituents including alkyl groups represented by Z₁ and Z₂ at ortho positions with respect to carbon atoms connected with nitrogen. The groups represented by Formula 2-1 and Formula 2-2 having such a structure are combined with the polycyclic compound to induce twist effects due to steric hindrance, thereby changing the conjugation structure of a phosphor and controlling the wavelength of emitted light finely (e.g., more precisely). For example, according to the steric hindrance properties of Formula 2-1 or Formula 2-2, the wavelength of emitted light with about several nm to about tens of nm may be easily (e.g., suitably) controlled. Also, due to the twist effects, the entire rigidity of a phosphor may be improved, the phenomenon of reducing the full width at half maximum may be accompanied, intermolecular distance may be widened, and quenching phenomenon due to intermolecular π-πstacking may be restrained or reduced, thereby improving emission efficiency properties. Accordingly, in case of applying the polycyclic compound represented by Formula 1 as a dopant in an emission layer of an organic electroluminescence device, high emission efficiency and high color purity may be achieved. In addition, by introducing a substituent including an alkyl group, the aggregation of the dopant is reduced, solubility is improved, and thin film uniformity, solution processing properties, and device efficiency properties may be improved.

Referring to FIG. 4 to FIG. 7, the hole transport region HTR is provided on the first electrode EL1. The hole transport region HTR may include at least one selected from among a hole injection layer HIL, a hole transport layer HTL, a buffer layer or an emission auxiliary layer, and an electron blocking layer EBL. The thickness of the hole transport region HTR may be from about 50 Å to about 15,000 Å.

The hole transport region HTR may have a single layer formed using (e.g., consisting of) a single material, a single layer formed using multiple different materials, or a multilayer structure including multiple layers formed using multiple different materials.

For example, the hole transport region HTR may have the structure of a single layer of a hole injection layer HIL or a hole transport layer HTL, and may have a structure of a single layer formed using a hole injection material and a hole transport material. In one or more embodiments, the hole transport region HTR may have a structure of a single layer formed using multiple different materials, or a structure stacked from the first electrode EL1 of hole injection layer HIL/hole transport layer HTL, hole injection layer HIL/hole transport layer HTL/buffer layer, hole injection layer HIL/buffer layer, hole transport layer HTL/buffer layer, or hole injection layer HIL/hole transport layer HTL/electron blocking layer EBL, without limitation.

The hole transport region HTR may be formed using one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1 below.

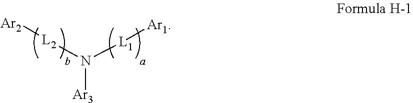

In Formula H-1 above, L₁ and L₂ may be each independently a direct linkage, a substituted or unsubstituted arylene group of 6 to 30 ring-forming carbon atoms, or a substituted or unsubstituted heteroarylene group of 2 to 30 ring-forming carbon atoms. “a” and “b” may be each independently an integer of 0 to 10. Meanwhile, if “a” or “b” is an integer of 2 or more, multiple L₁ and L₂ may be each independently a substituted or unsubstituted arylene group of 6 to 30 ring-forming carbon atoms, or a substituted or unsubstituted heteroarylene group of 2 to 30 ring-forming carbon atoms.

In Formula H-1, Ar₁ and Arₑ may be each independently a substituted or unsubstituted aryl group of 6 to 30 ring-forming carbon atoms, or a substituted or unsubstituted heteroaryl group of 2 to 30 ring-forming carbon atoms. In addition, in Formula H-1, Ar₃ may be a substituted or unsubstituted aryl group of 6 to 30 ring-forming carbon atoms.

The compound represented by Formula H-1 may be a monoamine compound. In one or more embodiments, the compound represented by Formula H-1 may be a diamine compound in which at least one selected from among Ar₁ to Ar₃ includes an amine group as a substituent. For example, the compound represented by Formula H-1 may be a carbazole-based compound in which at least one selected from among Ar₁ to Ar₃ includes a substituted or unsubstituted carbazole group, or a fluorene-based compound in which at least one selected from among Ar₁ to Ar₃ includes a substituted or unsubstituted fluorene group.

The compound represented by Formula H-1 may be represented by any one selected from among the compounds in Compound Group H below. However, the compounds shown in Compound Group H are only illustrations, and the compound represented by Formula H-1 is not limited to the compounds represented in Compound Group H below.

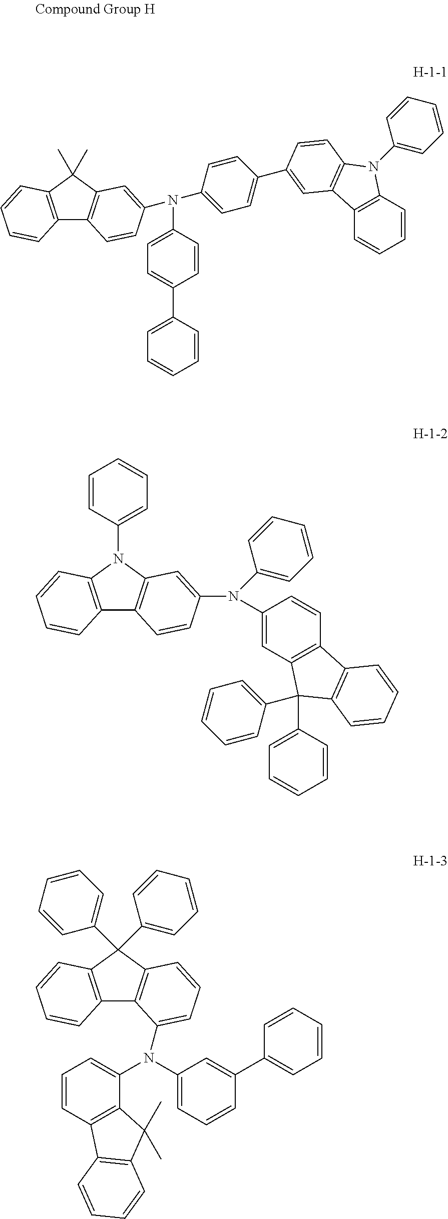 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

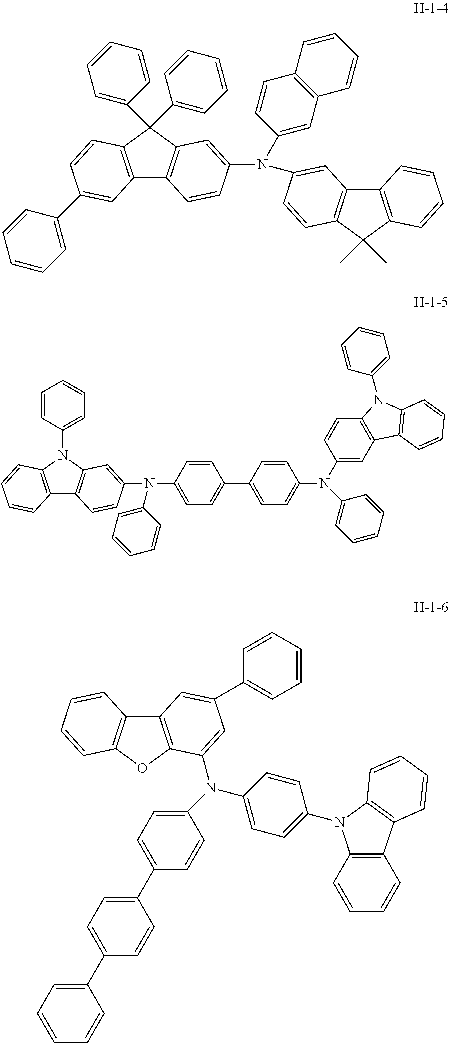 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

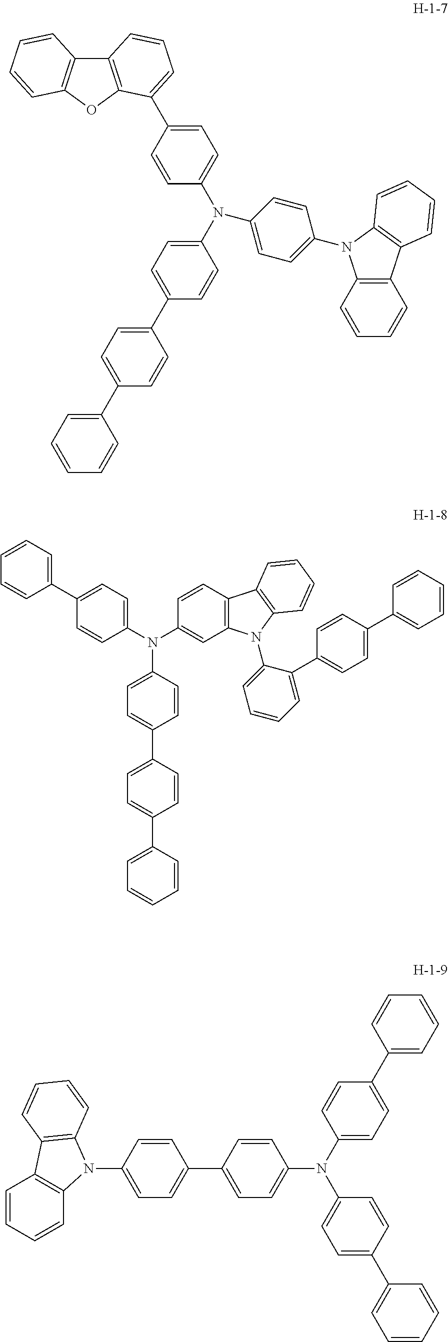 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

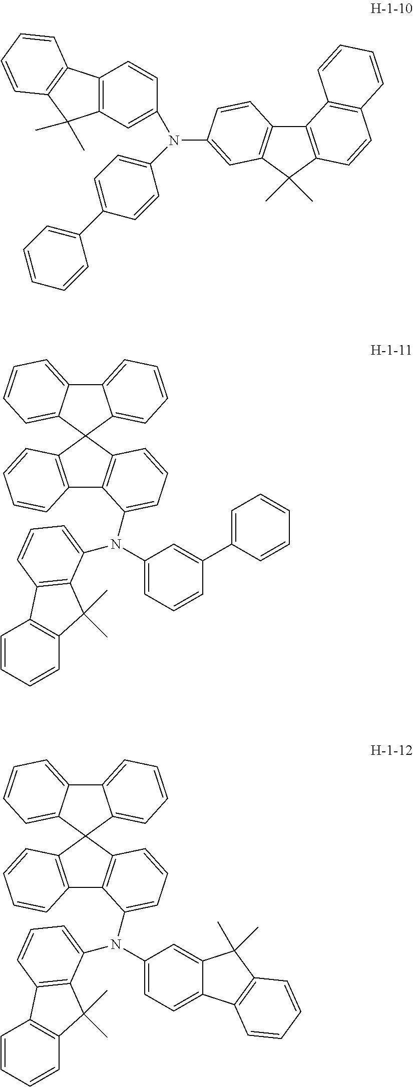 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

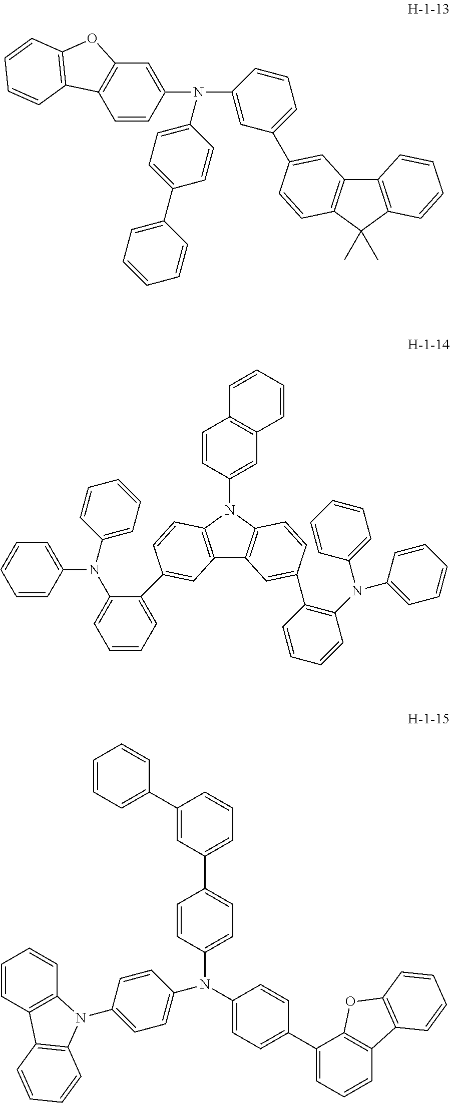 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

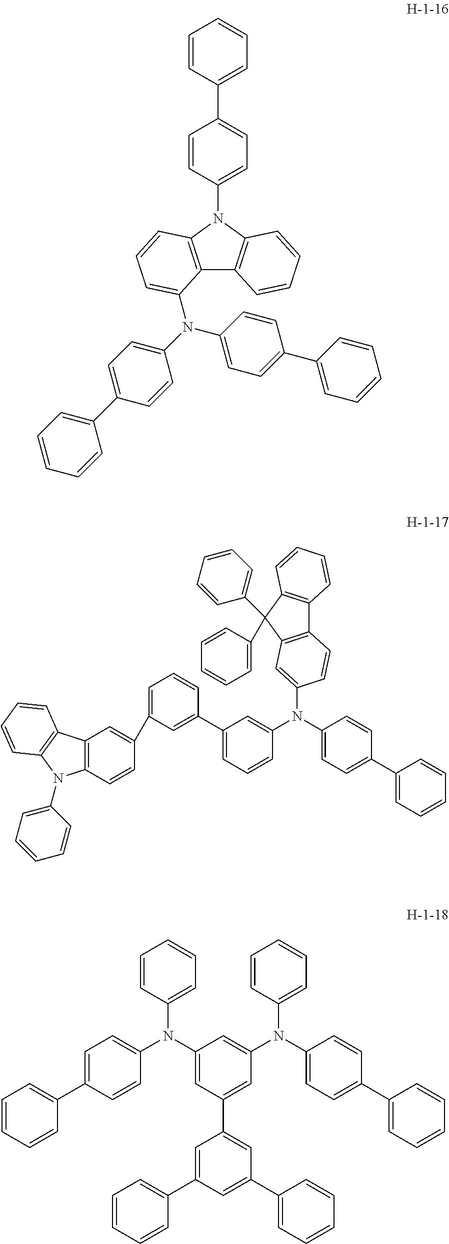 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

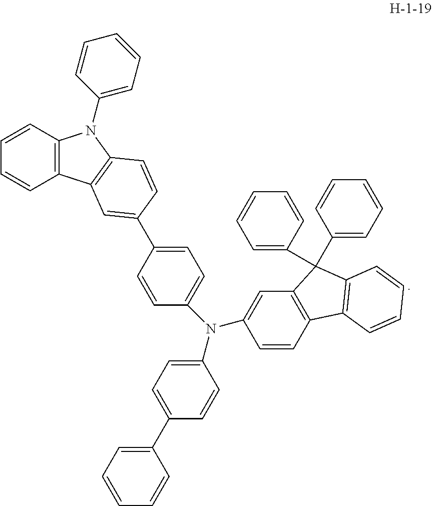 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound (such as copper phthalocyanine), N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], and dipyrazino[2,3-f:2′,3′-h]quinoxaline-2,3,6,7,10,11-hexacarbonitrile (HATCN).

The hole transport region HTR may include carbazole derivatives (such as N-phenyl carbazole and/or polyvinyl carbazole), fluorene-based derivatives, N,N′-bis(3-methylphenyl)-N,N′-diphenyl-[1,1′-biphenyl]-4,4′-diamine (TPD), triphenylamine-based derivatives (such as 4,4′,4″-tris(N-carbazolyl)triphenylamine (TCTA)), N,N′-di(1-naphthalene-1-yl)-N,N′-diphenyl-benzidine (NPB), 4,4′-cyclohexylidene bis[N,N-bis(4-methylphenyl)benzeneamine (TAPC), 4,4′-bis[N,N′-(3-tolyl)amino]-3,3′-dimethylbiphenyl (HMTPD), 1,3-bis(N-carbazolyl)benzene (mCP), etc.

In one or more embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region in at least one selected from among the hole injection layer HIL, hole transport layer HTL, and electron blocking layer EBL.

The thickness of the hole transport region HTR may be from about 100 Å to about 10,000 Å, for example, from about 100 Å to about 5,000 Å. In case where the hole transport region HTR includes a hole injection layer HIL, the thickness of the hole injection layer HIL may be, for example, from about 30 Å to about 1,000 Å. In case where the hole transport region HTR includes a hole transport layer HTL, the thickness of the hole transport layer HTL may be from about 30 Å to about 1,000 Å. For example, in case where the hole transport region HTR includes an electron blocking layer EBL, the thickness of the electron blocking layer EBL may be from about 10 Å to about 1,000 Å. If the thicknesses of the hole transport region HTR, the hole injection layer HIL, the hole transport layer HTL and/or the electron blocking layer EBL satisfy their respective above-described ranges, satisfactory (or suitable) hole transport properties may be achieved without substantial increase of a driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one selected from among metal halide compounds, quinone derivatives, metal oxides, and cyano group-containing compounds, without limitation. For example, the p-dopant may include metal halide compounds (such as CuI and/or RbI), quinone derivatives (such as tetracyanoquinodimethane (TCNQ) and/or 2,3,5,6-tetrafluoro-7,7′,8,8-tetracyanoquinodimethane (F4-TCNQ)), metal oxides (such as tungsten oxide and/or molybdenum oxide), cyano group-containing compounds (such as dipyrazino[2,3-f: 2′,3′-h]quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile), etc., without limitation.

As described above, the hole transport region HTR may further include at least one of a buffer layer or an electron blocking layer EBL, in addition to the hole injection layer HIL and the hole transport layer HTL. The buffer layer may compensate resonance distance according to the wavelength of light emitted from an emission layer EML and may increase light emitting efficiency. As to materials included in the buffer layer, any of the materials which may be included in the hole transport region HTR may be used. The electron blocking layer EBL is a layer playing the role of blocking or reducing the injection of electrons from an electron transport region ETR to a hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed using (e.g., consisting of) a single material, a single layer formed using multiple different materials, or a multilayer structure having multiple layers formed using multiple different materials.

The emission layer EML may emit one of red light, green light, blue light, yellow light, or cyan light. The emission layer EML may include a fluorescence emitting material or a phosphorescence emitting material.

In one or more embodiments, the emission layer EML may be a fluorescence emission layer. For example, a portion of light emitted from the emission layer EML may be due to thermally activated delayed fluorescence (TADF). For example, the emission layer EML may include light emitting components emitting thermally activated delayed fluorescence, and in one or more embodiments, the emission layer EML may be an emission layer emitting thermally activated delayed fluorescence which emits blue light.

The emission layer EML of the organic electroluminescence device ED of one or more embodiments may include the polycyclic compound according to one or more embodiments. The emission layer EML may include one or two or more types (e.g., kinds) of the polycyclic compound represented by Formula 1. For example, the emission layer EML may include at least one selected from among the compounds represented in Compound Group 1.

In one or more embodiments, the emission layer EML includes a host and a dopant, and the host may be a host for emitting delayed fluorescence, and the dopant may be a dopant for emitting delayed fluorescence. The polycyclic compound of one or more embodiments, represented by Formula 1 may be included as the dopant material of the emission layer EML. For example, the polycyclic compound of one or more embodiments, represented by Formula 1 may be used as a TADF dopant.

In the organic electroluminescence device ED of one or more embodiments, the emission layer EML may further include anthracene derivative(s), pyrene derivative(s), fluoranthene derivative(s), chrysene derivative(s), dihydrobenzanthracene derivative(s), and/or triphenylene derivative(s). For example, the emission layer EML may further include anthracene derivative(s) and/or pyrene derivative(s).

In the organic electroluminescence devices ED of embodiments, shown in FIG. 4 to FIG. 7, the emission layer EML may include a host and a dopant, and the emission layer EML may include a compound represented by Formula E-1 below. The compound represented by Formula E-1 below may be used as a fluorescence host material.

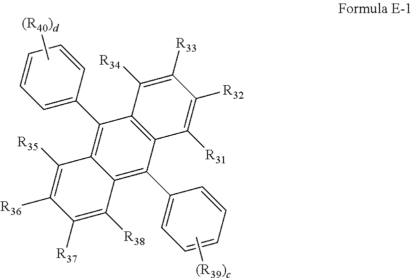

In Formula E-1, R₃₁ to R₄₀ may be each independently a hydrogen atom, a deuterium atom, a halogen atom, a substituted or unsubstituted silyl group, a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring. In one or more embodiments, R₃₁ to R₄₀ may be combined with an adjacent group to form a saturated hydrocarbon ring or an unsaturated hydrocarbon ring.

In Formula E-1, “c” and “d” may be each independently an integer of 0 to 5.

Formula E-1 may be represented by any one selected from among Compound E1 to Compound E19 below.

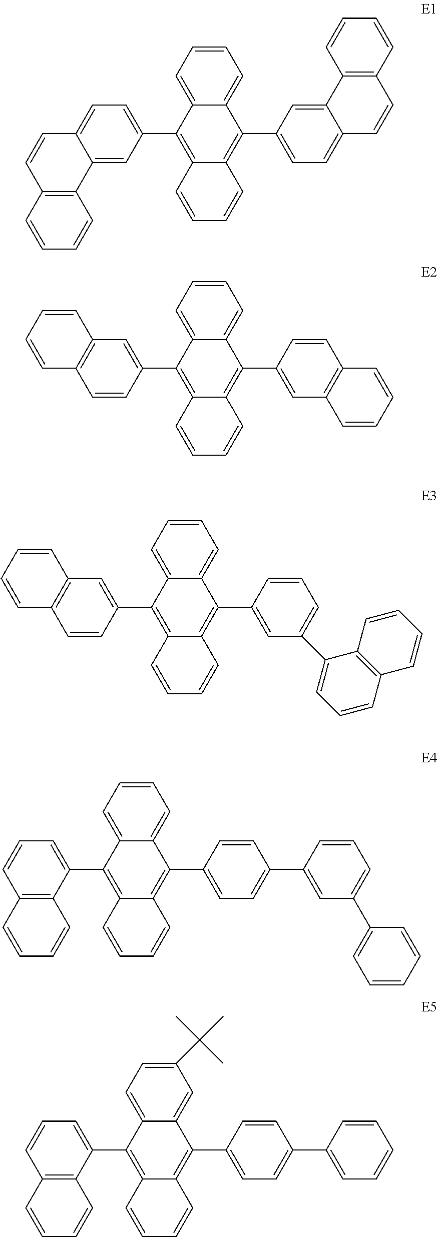

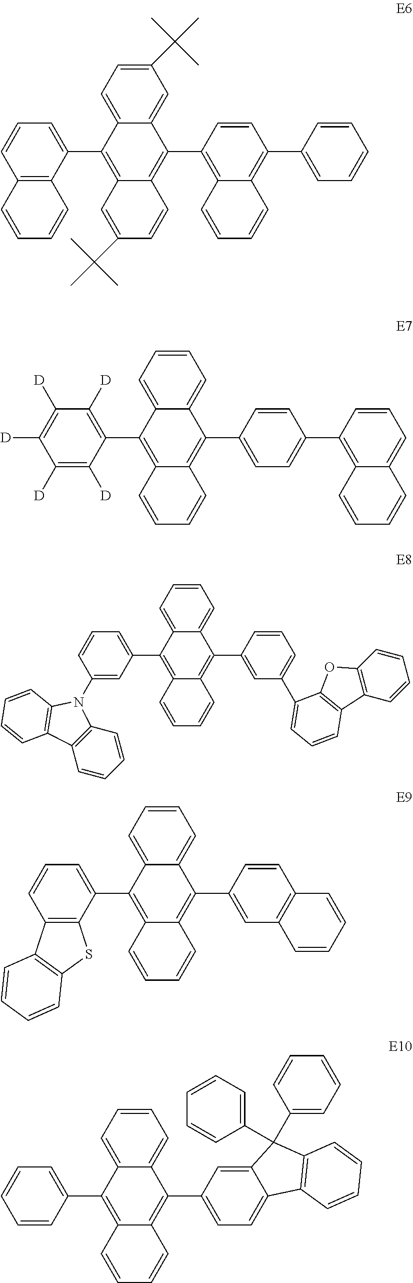

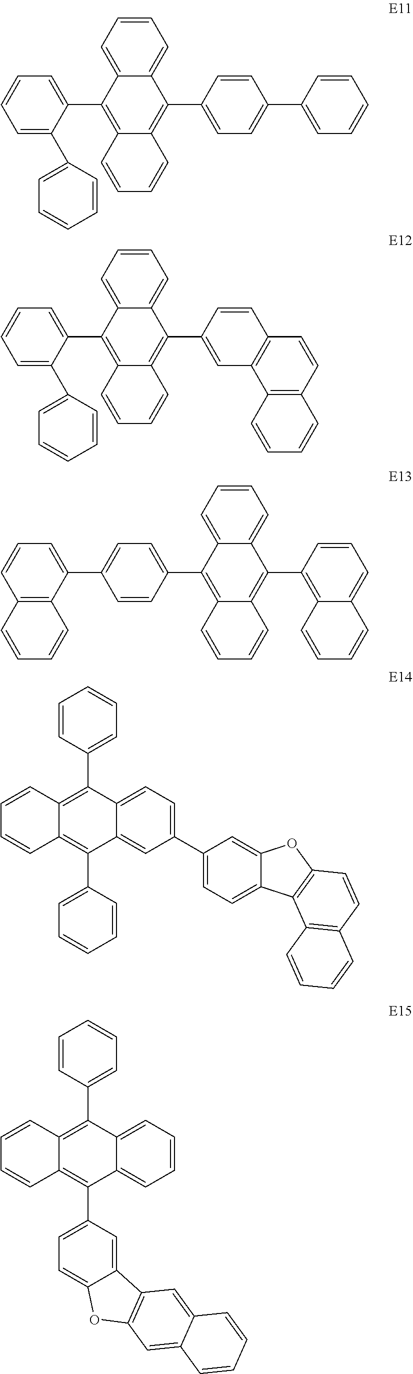

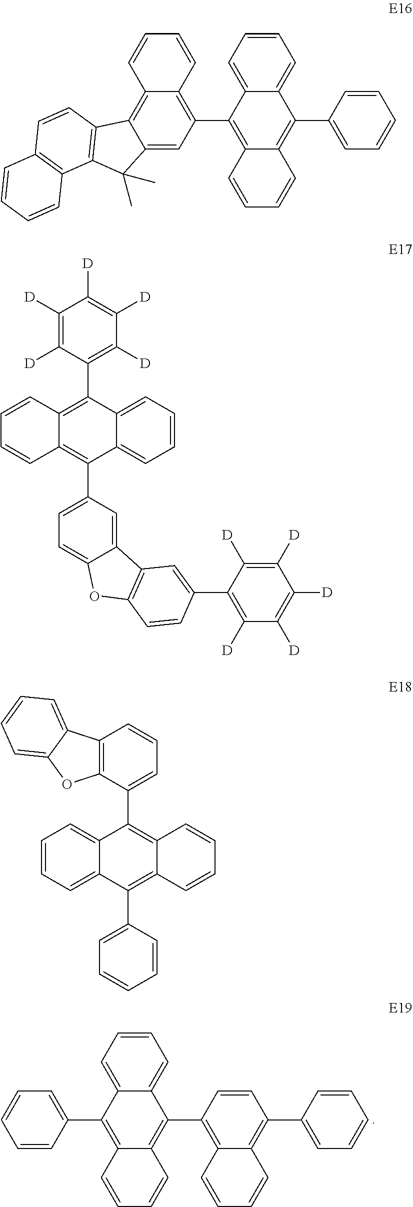

In one or more embodiments, the emission layer EML may include a compound represented by Formula E-2a or Formula E-2b below. The compound represented by Formula E-2a or Formula E-2b below may be used as a phosphorescence host material.

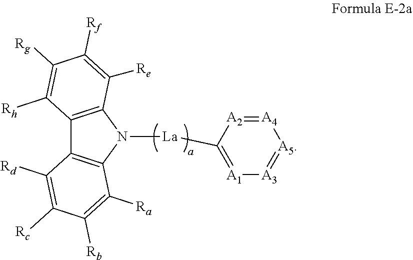

In Formula E-2a, “a” may be an integer of 0 to 10, Lₐ may be a direct linkage, a substituted or unsubstituted arylene group of 6 to 30 ring-forming carbon atoms, or a substituted or unsubstituted heteroarylene group of 2 to 30 ring-forming carbon atoms. Meanwhile, if “a” is an integer of 2 or more, multiple Lₐ may be each independently a substituted or unsubstituted arylene group of 6 to 30 ring-forming carbon atoms, or a substituted or unsubstituted heteroarylene group of 2 to 30 ring-forming carbon atoms.

In Formula E-2a, A₁ to A₅ may be each independently N or CR. Rₐ to R may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Rₐ to R may be combined with an adjacent group to form a hydrocarbon ring or a heterocycle including N, O, S, etc. as a ring-forming atom.

In Formula E-2a, two or three selected from A₁ to A₅ may be N, and the remainder may be CR.

(Cbz1 [symbol] [symbol] L_{b} [symbol] _{b} [symbol] Cbz2) Formula E-2b

In Formula E-2b, Cbz1 and Cbz2 may be each independently an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” is an integer of 0 to 10, and if “b” is an integer of 2 or more, multiple L_{b} may be each independently a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by any one selected from among the compounds in Compound Group E-2 below. However, the compounds shown in Compound Group E-2 below are only illustrations, and the compound represented by Formula E-2a or Formula E-2b is not limited to the compounds represented in Compound Group E-2 below.

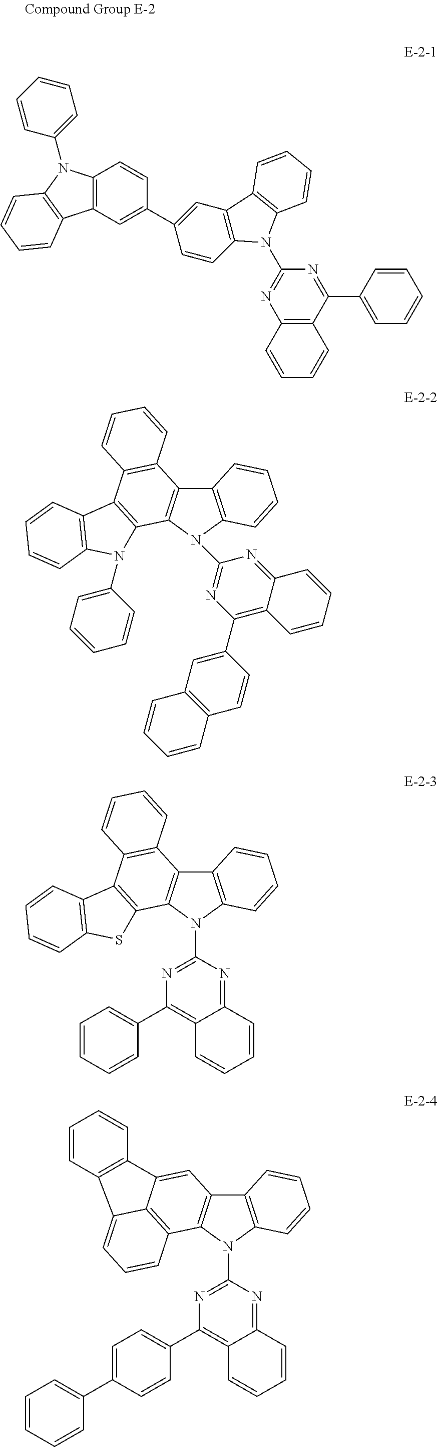

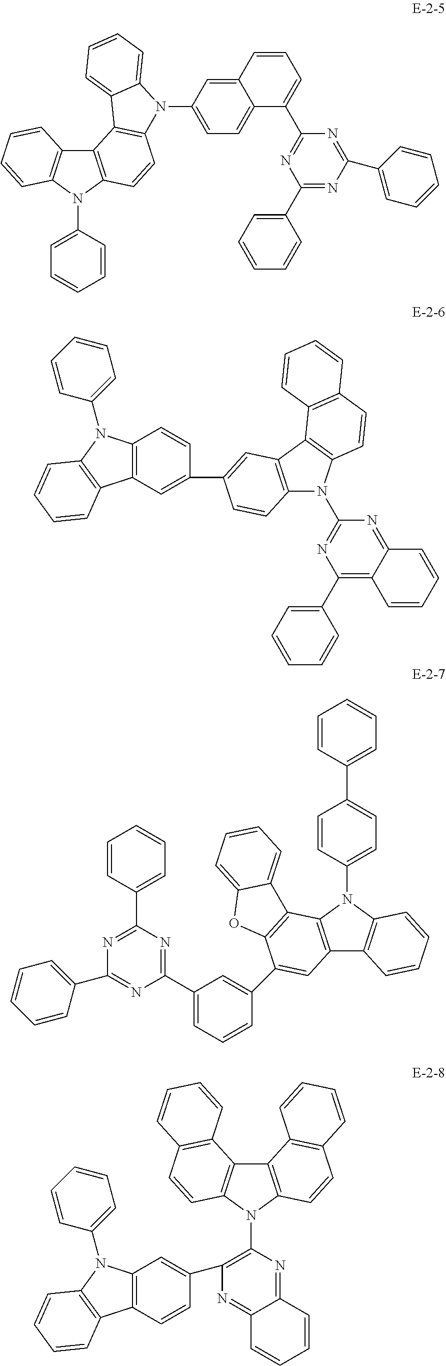

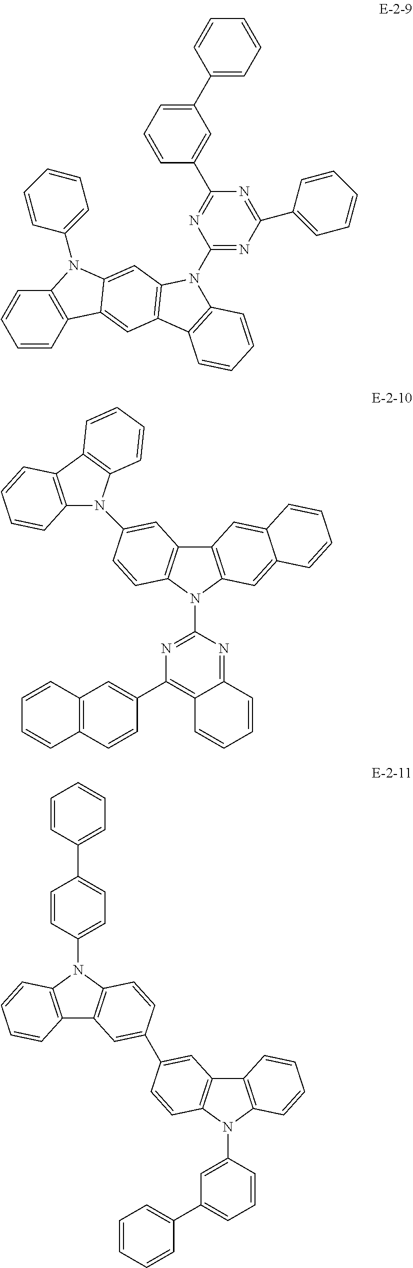

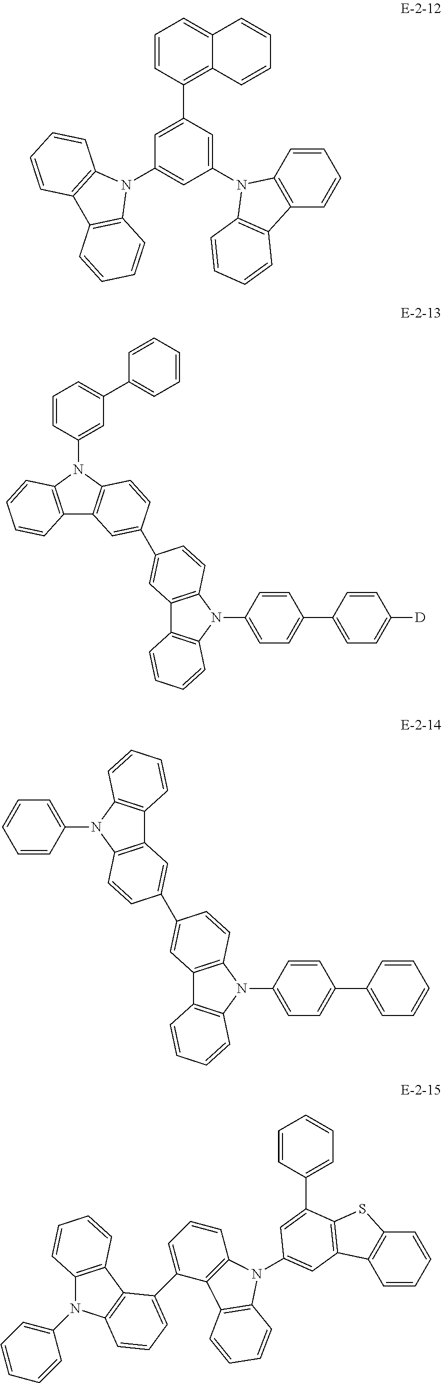 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

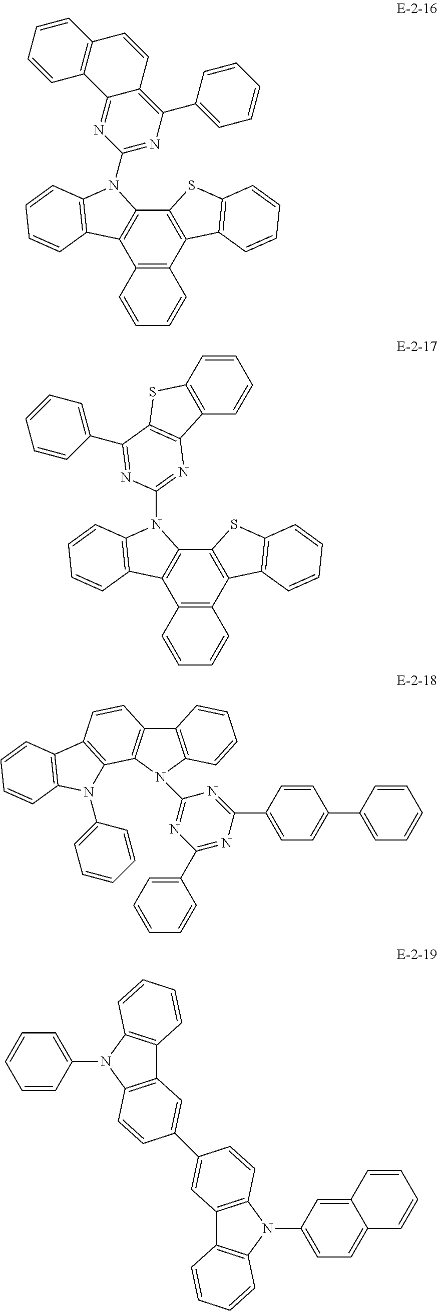

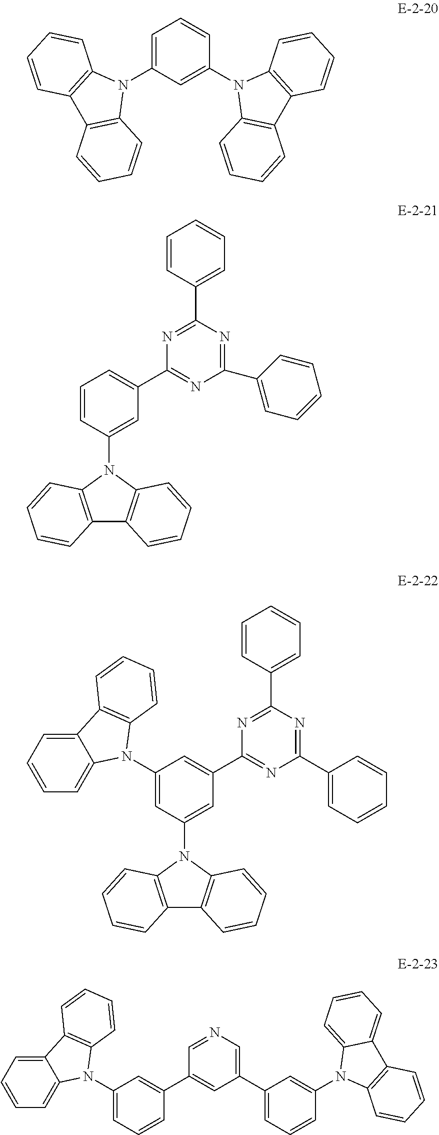 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

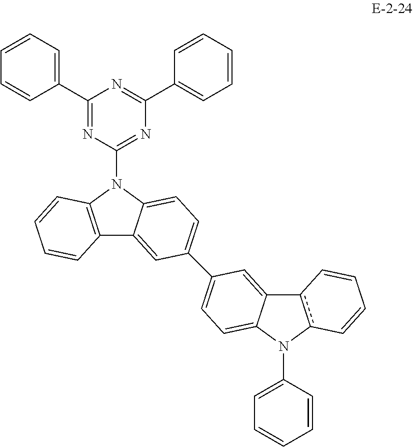

The emission layer EML may further include a suitable host material. For example, the emission layer EML may include, as a host material, at least one of bis[2-(diphenylphosphino)phenyl]ether oxide (DPEPO), 4,4′-bis(carbazol-9-yl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments of the present disclosure are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as the host material.

The emission layer EML may include a compound represented by Formula M-a or Formula M-b below. The compound represented by Formula M-a or Formula M-b may be used as a phosphorescence dopant material.

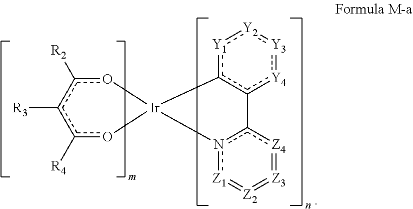

In Formula M-a, Y₁ to Y₄, and Z₁ to Z₄ may be each independently CR₁ or N, and R₁ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In Formula M-a, “m” is 0 or 1, and “n” is 2 or 3. In Formula M-a, if “m” is 0, “n” is 3, and if “m” is 1, “n” is 2.

The compound represented by Formula M-a may be used as a phosphorescence dopant.

The compound represented by Formula M-a may be represented by any one selected from among Compounds M-a1 to M-a23 below. However, Compounds M-a1 to M-a23 below are illustrations, and the compound represented by Formula M-a is not limited to the compounds represented by Compounds M-a1 to M-a23 below.

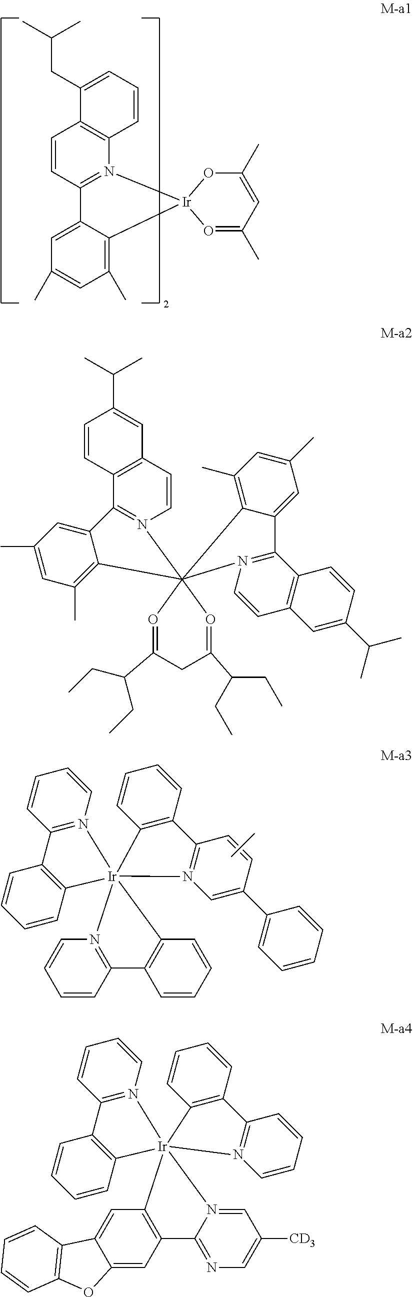

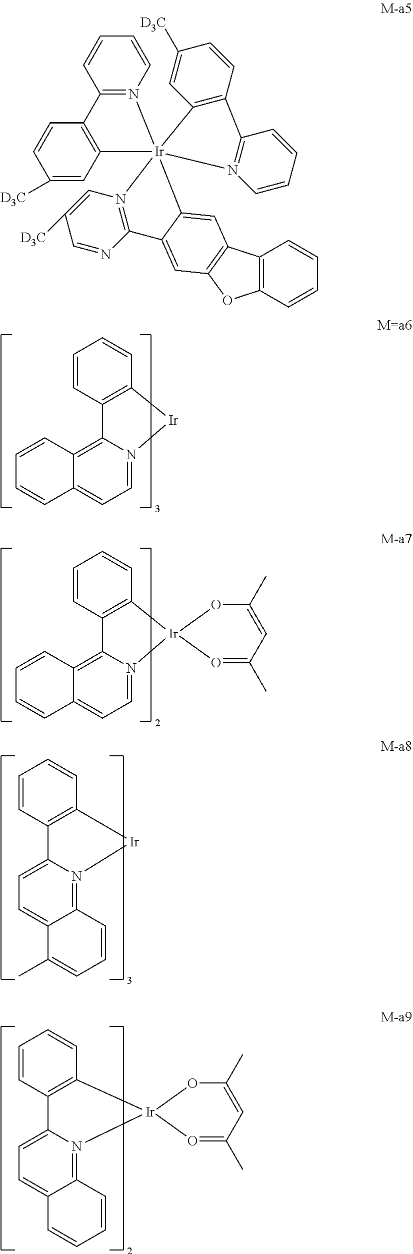

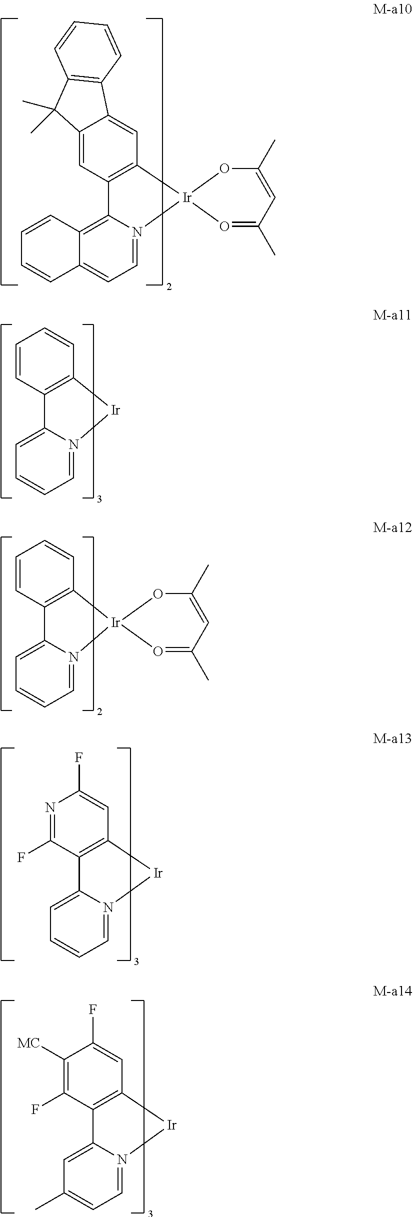

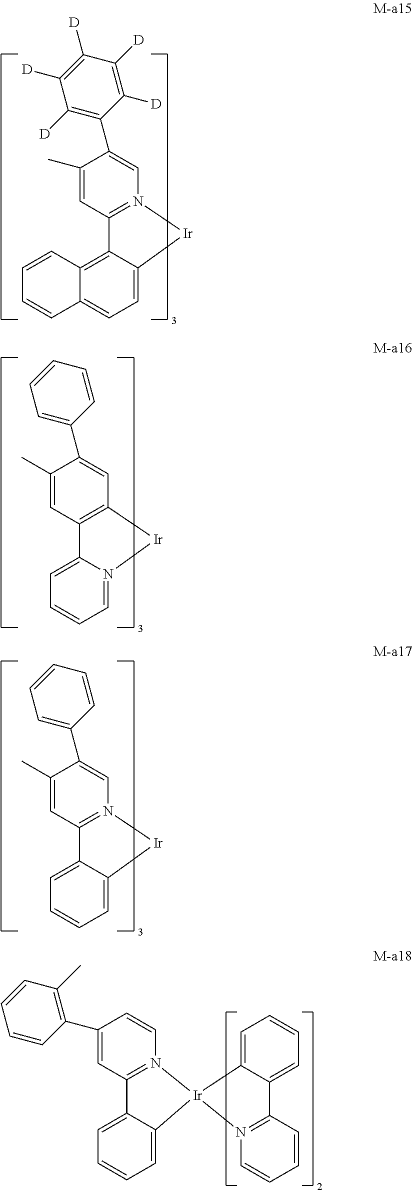

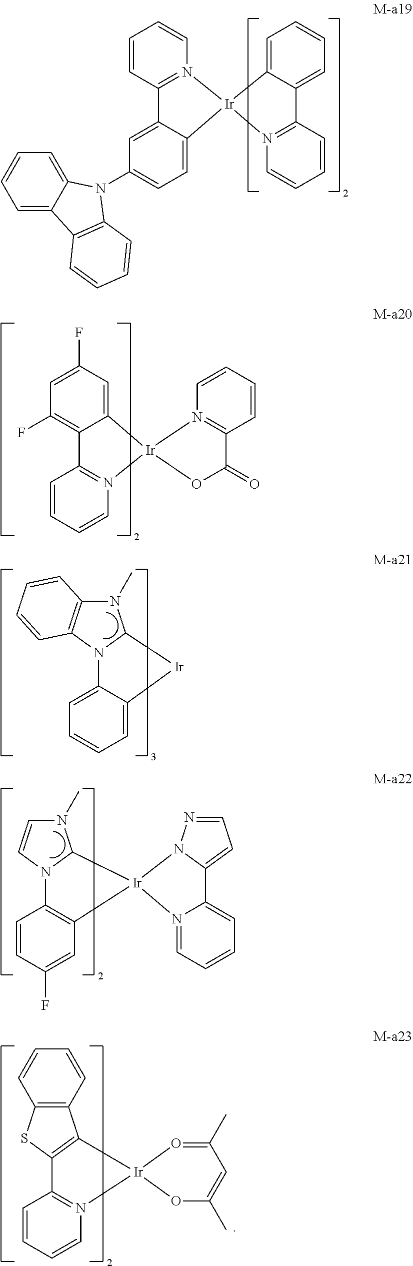

Compound M-a1 and Compound M-a2 may be used as red dopant materials, and Compound M-a3 to Compound M-a5 may be used as green dopant materials.

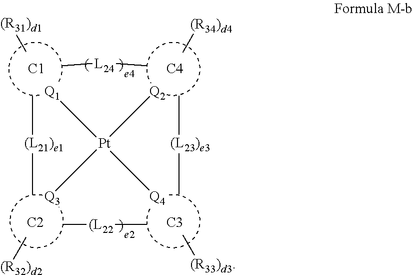

In Formula M-b, Q₁ to Q₄ are each independently C or N, and C1 to C4 are each independently a substituted or unsubstituted hydrocarbon ring of 5 to 30 ring-forming carbon atoms, or a substituted or unsubstituted heterocycle of 2 to 30 ring-forming carbon atoms. L₂₁ to L₂₄ are each independently a direct linkage, *—O—*, *—S—*,

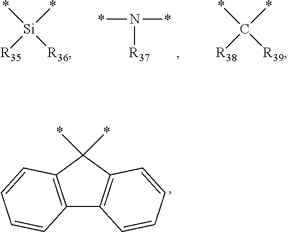

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, and e1 to e4 are each independently 0 or 1. R₃₁ to R₃₉ are each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and dl to d4 are each independently an integer of 0 to 4.

The compound represented by Formula M-b may be used as a blue phosphorescence dopant or a green phosphorescence dopant.

The compound represented by Formula M-b may be represented by any one selected from among the compounds below. However, the compounds below are illustrations, and the compound represented by Formula M-b is not limited to the compounds represented below.

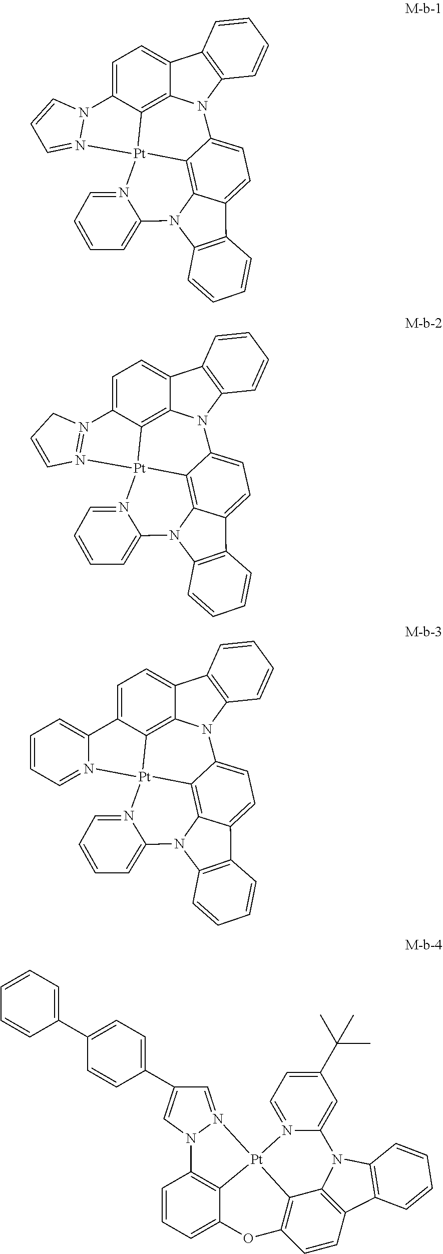

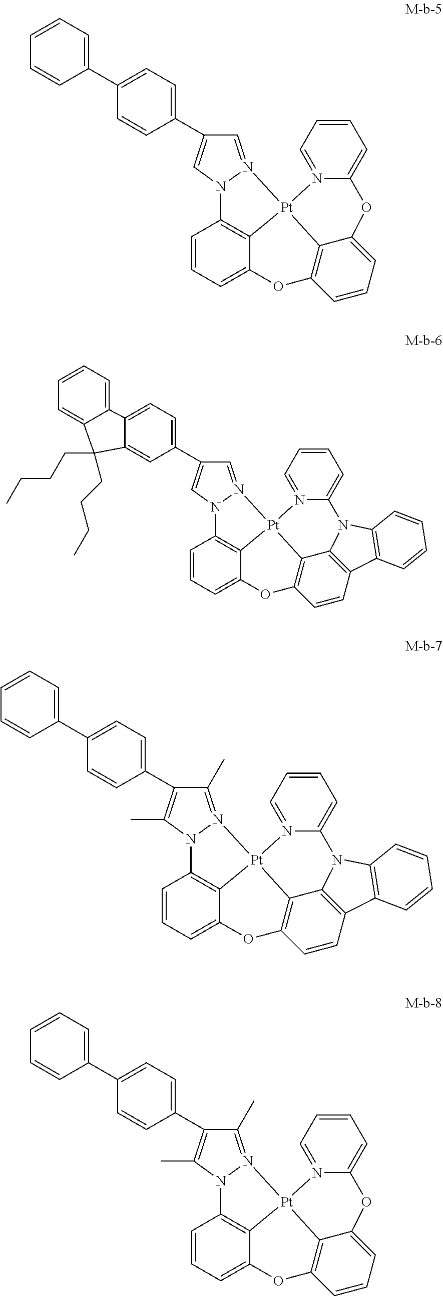

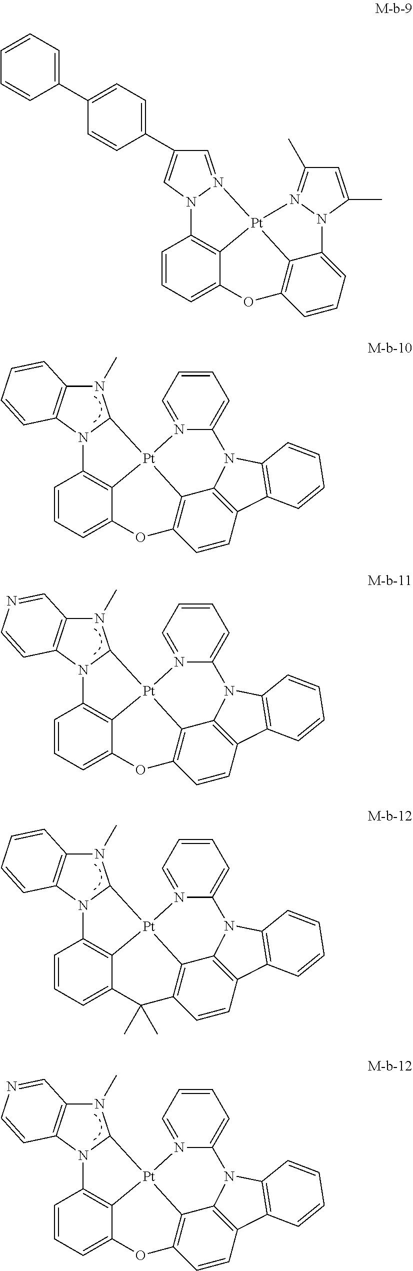

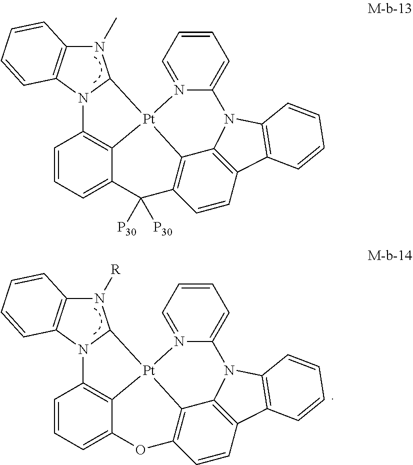

In the compounds above, R, R₃₈, and R₃₉ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

The emission layer EML may include any one selected from among Formula F-a to Formula F-c below. The compounds represented by Formula F-a to Formula F-c below may be used as fluorescence dopant materials.

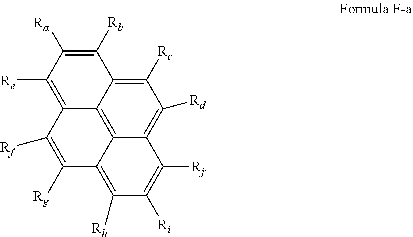

In Formula F-a, two selected from Rₐ to Rⱼ may be each independently substituted with *—NAr₁Ar₂. The remainder not substituted with *—NAr₁Ar₂ among Rₐ to Rⱼ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In *—NAr₁Ar₂, Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. For example, at least one selected from among Ar₁ and Arₑ may be a heteroaryl group including O or S as a ring-forming atom.

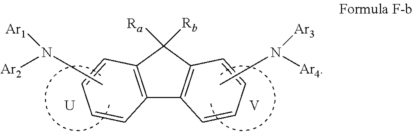

In Formula F-b, Rₐ and R_{b} may be each independently a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring.

In Formula F-b, U and V may be each independently a substituted or unsubstituted hydrocarbon ring of 5 to 30 ring-forming carbon atoms, or a substituted or unsubstituted heterocycle of 2 to 30 ring-forming carbon atoms.

In Formula F-b, the number of rings represented by U and V may be each independently 0 or 1. For example, in Formula F-b, if the number of U or V is 1, one ring forms a fused ring at the designated part by U or V, and if the number of U or V is 0, a ring is not present at the designated part by U or V. For example, if the number of U is 0, and the number of V is 1, or if the number of U is 1, and the number of V is 0, a fused ring having the fluorene core of Formula F-b may be a ring compound with four rings. If the number of both U and V is 0, the fused ring of Formula F-b may be a ring compound with three rings. If the number of both U and V is 1, a fused ring having the fluorene core of Formula F-b may be a ring compound with five rings.

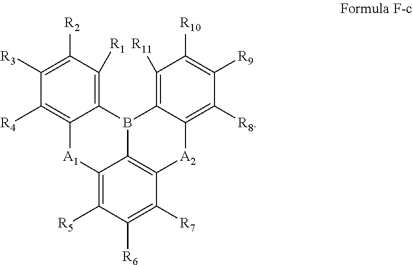

In Formula F-c, A₁ and A₂ may be each independently O, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ may be each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring.

In Formula F-c, A₁ and A₂ may be each independently combined with the substituents of an adjacent ring to form a fused ring. For example, if A₁ and A₂ are each independently NRₘ, A₁ may be combined with R₄ or R₅ to form a ring, and/or A₂ may be combined with R₇ or R₈ to form a ring.

In one or more embodiments, the emission layer EML may include, as a suitable dopant material, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and/or 4,4′-bis[2-(4-(N,N-diphenylamino)phenyl)vinyl]biphenyl (DPAVBi)), perylene and/or the derivatives thereof (for example, 2,5,8,11-tetra-t-butylperylene (TBP)), pyrene and/or the derivatives thereof (for example, 1,1-dipyrene, 1,4-dipyrenylbenzene, and/or 1,4-bis(N,N-diphenylamino)pyrene), etc.

The emission layer EML may include a suitable phosphorescence dopant material. For example, the phosphorescence dopant may use a metal complex including iridium (Ir), platinum (Pt), osmium (Os), gold (Au), titanium (Ti), zirconium (Zr), hafnium (Hf), europium (Eu), terbium (Tb) and/or thulium (Tm). For example, iridium(III) bis(4,6-difluorophenylpyridinato-N,C2′)picolinate (Flrpic), bis(2,4-difluorophenylpyridinato)-tetrakis(1-pyrazolyl)borate (Fir6), and/or platinum octaethyl porphyrin (PtOEP) may be used as the phosphorescence dopant. However, embodiments of the present disclosure are not limited thereto.

In the organic electroluminescence device ED of one or more embodiments, as shown in FIG. 4 to FIG. 7, the electron transport region ETR is provided on the emission layer EML. The electron transport region ETR may include at least one of a hole blocking layer HBL, an electron transport layer ETL, or an electron injection layer EIL. However, embodiments of the present disclosure are not limited thereto.

The electron transport region ETR may have a single layer formed using (e.g., consisting of) a single material, a single layer formed using multiple different materials, or a multilayer structure having multiple layers formed using multiple different materials.

For example, the electron transport region ETR may have a single layer structure of (e.g., consisting of) an electron injection layer EIL or an electron transport layer ETL, or a single layer structure formed using an electron injection material and an electron transport material. In one or more embodiments, the electron transport region ETR may have a single layer structure formed using multiple different materials, or a structure stacked from the emission layer EML of electron transport layer ETL/electron injection layer EIL, or hole blocking layer HBL/electron transport layer ETL/electron injection layer EIL, without limitation. The thickness of the electron transport region ETR may be, for example, from about 1,000 Å to about 1,500 Å.

The electron transport region ETR may be formed using one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-1 below.

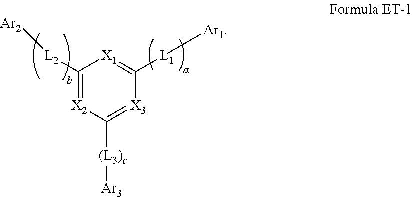

In Formula ET-1, at least one selected from among X₁ to X₃ is N, and the remainder are CRₐ. Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Arₐ may be each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-1, “a” to “c” may be each independently an integer of 0 to 10. In Formula ET-1, L₁ to L₃ may be each independently a direct linkage, a substituted or unsubstituted arylene group of 6 to 30 ring-forming carbon atoms, or a substituted or unsubstituted heteroarylene group of 2 to 30 ring-forming carbon atoms. Meanwhile, if “a” to “c” are each independently an integer of 2 or more, L₁ to L₃ may be each independently a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, embodiments of the present disclosure are not limited thereto, and the electron transport region ETR may include, for example, diphenyl[4-(triphenylsilyl)phenyl]phosphine oxide (TSPO1), tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), and/or mixture(s) thereof, without limitation.

In one or more embodiments, the electron transport region ETR may include a metal halide (such as LiF, NaCl, CsF, RbCl, RbI, CuI and/or KI), a metal in lanthanides (such as Yb), or a co-depositing material of the metal halide and the metal in lanthanides. For example, the electron transport region ETR may include KI:Yb, RbI:Yb, etc., as the co-depositing material. Meanwhile, the electron transport region ETR may use a metal oxide (such as Li₂O and/or BaO), and/or 8-hydroxy-lithium quinolate (Liq). However, embodiments of the present disclosure are not limited thereto. The electron transport region ETR also may be formed using a mixture material of an electron transport material and an insulating organo metal salt. The organo metal salt may be a material having an energy band gap of about 4 eV or more. For example, the organo metal salt may include, for example, metal acetate(s), metal benzoate(s), metal acetoacetate(s), metal acetylacetonate(s), and/or metal stearate(s).

The electron transport region ETR may include at least one of 2,9-dimethyl-4,7-diphenyl-1,10-phenanthroline (BCP), or 4,7-diphenyl-1,10-phenanthroline (Bphen) in addition to the aforementioned materials. However, embodiments of the present disclosure are not limited thereto.

The electron transport region ETR may include the compounds of the electron transport region in at least one selected from among an electron injection layer EIL, an electron transport layer ETL, and a hole blocking layer HBL.

If the electron transport region ETR includes the electron transport layer ETL, the thickness of the electron transport layer ETL may be from about 100 Å to about 1,000 Å, for example, from about 150 Å to about 500 Å. If the thickness of the electron transport layer ETL satisfies any of the above-described ranges, satisfactory (or suitable) electron transport properties may be obtained without a substantial increase of a driving voltage. If the electron transport region ETR includes the electron injection layer EIL, the thickness of the electron injection layer EIL may be from about 1 Å to about 100 Å, and from about 3 Å to about 90 Å. If the thickness of the electron injection layer EIL satisfies any of the above described ranges, satisfactory (or suitable) electron injection properties may be obtained without inducing a substantial increase of a driving voltage.

The second electrode EL2 is provided on the electron transport region ETR. The second electrode EL2 may be a common electrode. The second electrode EL2 may be a cathode or an anode, but embodiments of the present disclosure are not limited thereto. For example, if the first electrode EL1 is an anode, the second electrode EL2 may be a cathode, and if the first electrode EU is a cathode, the second electrode EL2 may be an anode.

The second electrode EL2 may be a transmissive electrode, a transflective electrode or a reflective electrode. If the second electrode EL2 is the transmissive electrode, the second electrode EL2 may include a transparent metal oxide, for example, ITO, IZO, ZnO, ITZO, etc.

If the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, compound(s) thereof, and/or mixture(s) thereof (for example, AgMg, AgYb, and/or MgAg). In one or more embodiments, the second electrode EL2 may have a multilayered structure including a reflective layer or a transflective layer formed using any of the above-described materials and a transparent conductive layer formed using ITO, IZO, ZnO, ITZO, etc. For example, the second electrode EL2 may include the aforementioned metal materials, combinations of two or more metal materials selected from the aforementioned metal materials, and/or oxides of the aforementioned metal materials.

In one or more embodiments, the second electrode EL2 may be connected (e.g., coupled) with an auxiliary electrode. If the second electrode EL2 is connected (e.g., coupled) with the auxiliary electrode, the resistance of the second electrode EL2 may decrease.

On the second electrode EL2 in the organic electroluminescence device ED of one or more embodiments, a capping layer CPL may be further provided. The capping layer CPL may include a multilayer structure or a single layer.

In one or more embodiments, the capping layer CPL may be an organic layer or an inorganic layer. For example, if the capping layer CPL includes an inorganic material, the inorganic material may include an alkali metal compound such as LiF, and/or an alkaline earth metal compound such as MgF₂, SiON, SiNx, SiOy, etc.

For example, if the capping layer CPL includes an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), etc., or may include an epoxy resin, and/or acrylate such as methacrylate. In one or more embodiments, a capping layer CPL may include at least one selected from among Compounds P1 to P5 below, but embodiments of the present disclosure are not limited thereto.

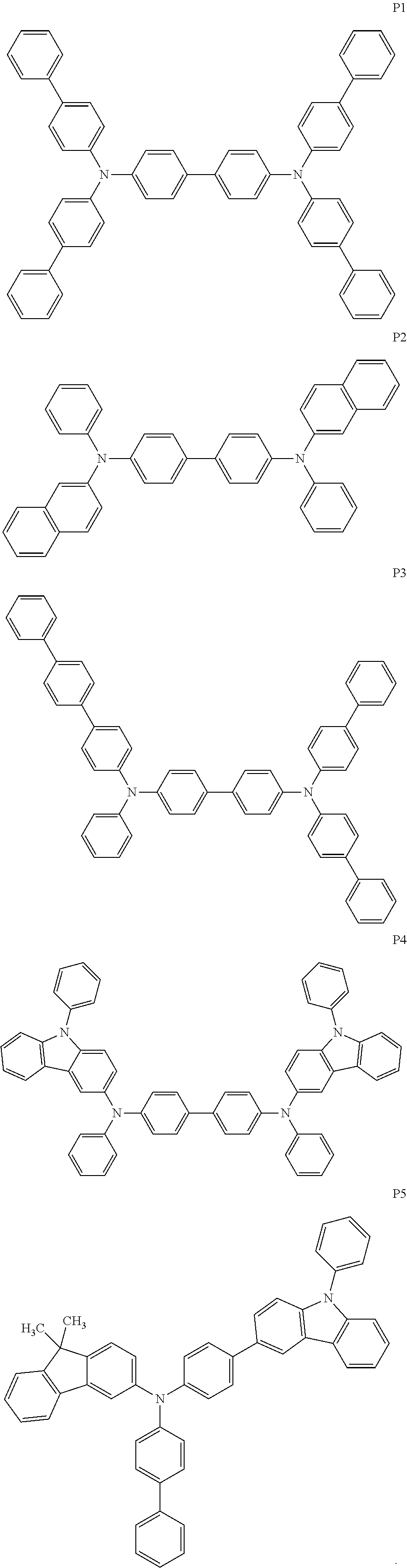 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the refractive index of the capping layer CPL may be about 1.6 or more. For example, the refractive index of the capping layer CPL with respect to light in a wavelength range of about 550 nm to about 660 nm may be about 1.6 or more.

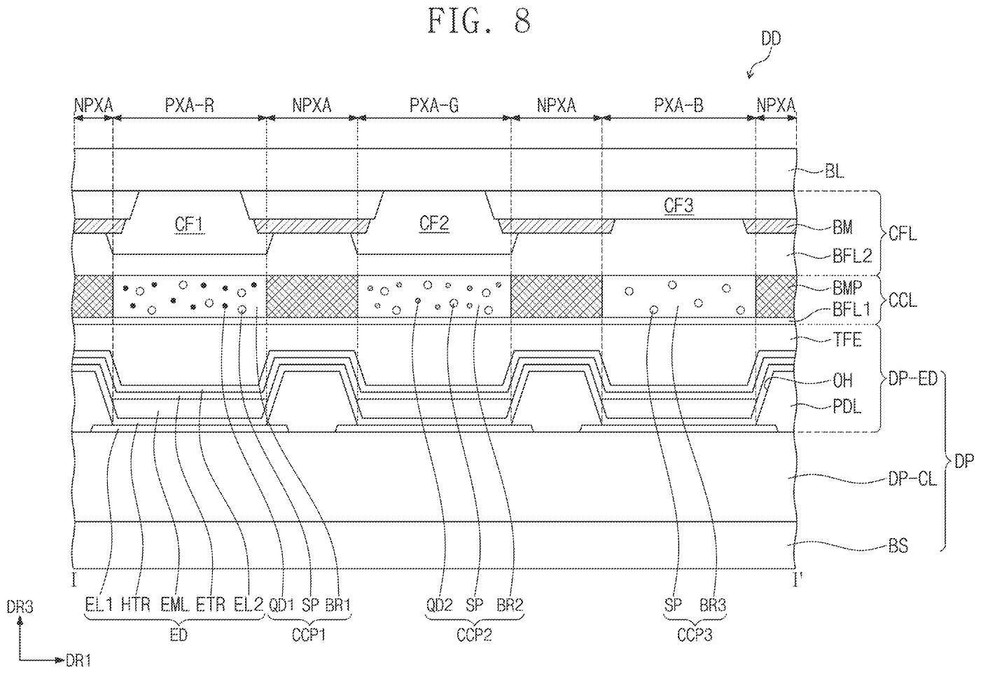

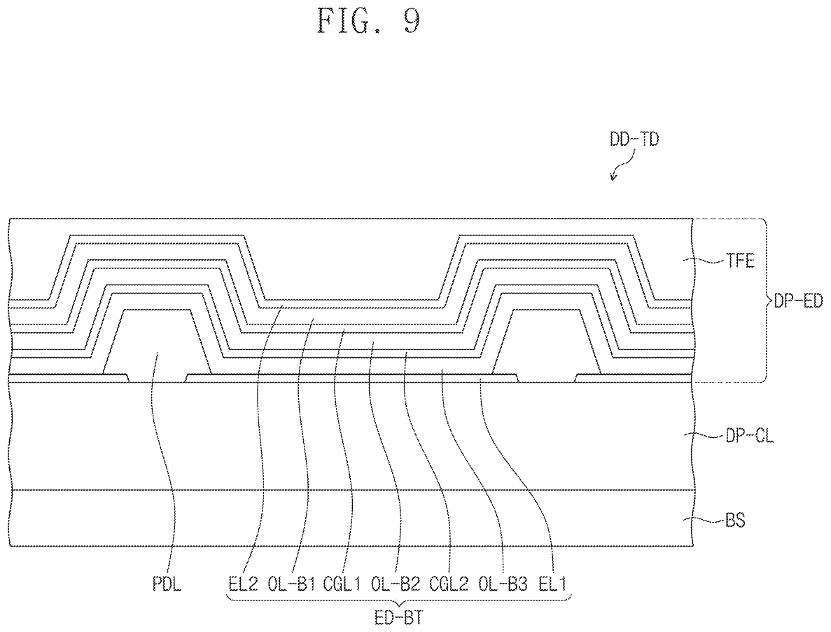

FIG. 8 and FIG. 9 are cross-sectional views on display apparatuses according to embodiments, respectively. In the explanation of the display apparatuses of embodiments referring to FIG. 8 and FIG. 9, the overlapping explanations for parts that have been described in connection with FIG. 1 to FIG. 7 may not be provided again, and the different features will be explained chiefly.

Referring to FIG. 8, the display apparatus DD according to one or more embodiments may include a display panel DP including a display device layer DP-ED, a light controlling layer CCL on the display panel DP and a color filter layer CFL.

In one or more embodiments shown in FIG. 8, the display panel DP includes a base layer BS, a circuit layer DP-CL provided on the base layer BS and a display device layer DP-ED, and the display device layer DP-ED may include an organic electroluminescence device ED.

The organic electroluminescence device ED may include a first electrode EL1, a hole transport region HTR on the first electrode EL1, an emission layer EML on the hole transport region HTR, an electron transport region ETR on the emission layer EML, and a second electrode EL2 on the electron transport region ETR. The same description of the structures of the organic electroluminescence devices of FIG. 3 to FIG. 7 may be applied to the structure of the organic electroluminescence device ED shown in FIG. 8.

Referring to FIG. 8, the emission layer EML may be provided in an opening part OH defined in a pixel definition layer PDL. For example, the emission layer EML divided by the pixel definition layer PDL and correspondingly provided to each of luminous areas PXA-R, PXA-G and PXA-B may emit light in the same wavelength region. In the display apparatus DD of one or more embodiments, the emission layer EML may emit blue light. In one or more embodiments, the emission layer EML may be provided as a common layer for all luminous areas PXA-R, PXA-G and PXA-B.

The light controlling layer CCL may be on the display panel DP. The light controlling layer CCL may include a light converter. The light converter may be a quantum dot or a phosphor. The light converter may transform the wavelength of light provided and then emit the transformed light. For example, the light controlling layer CCL may be a layer including a quantum dot or a layer including a phosphor.

The emission layer EML may include a quantum dot material. The core of the quantum dot may be selected from the group consisting of a II-VI group compound, a III-VI group compound, a IV-VI group compound, a IV group element, a IV group compound, and combinations thereof.

The II-VI group compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The III-VI group compound may include a binary compound such as In₂S₃ and/or In₂Se₃; a ternary compound such as InGaS₃ and/or InGaSe₃; or combination(s) thereof.

The I-III-VI group compound may be selected from a ternary compound selected from the group consisting of AgInS, AgInS₂, CuInS, CuInS₂, AgGaS₂, CuGaS₂, CuGaO₂, AgGaO₂, AgAlO₂ and mixtures thereof; and a quaternary compound such as AgInGaS₂ and/or CuInGaS₂.

The III-V group compound may be selected from the group consisting of a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. In one or more embodiments, the III-V group compound may further include a II group metal. For example, InZnP, etc. may be selected as a III-II-V group compound.

The IV-VI group compound may be selected from the group consisting of a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof. The IV group element may be selected from the group consisting of Si, Ge, and a mixture thereof. The IV group compound may be a binary compound selected from the group consisting of SiC, SiGe, and a mixture thereof.

The binary compound, the ternary compound and/or the quaternary compound may be present at uniform concentration in a particle or may be present at a partially different concentration distribution state in the same particle. In addition, a core/shell structure in which one quantum dot wraps another quantum dot may be possible. The interface of the core and the shell may have a concentration gradient in which the concentration of an element present in the shell is decreased toward the center.

In some embodiments, the quantum dot may have the above-described core-shell structure including a core including a nanocrystal and a shell wrapping (e.g., around or surround) the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer structure. Examples of the shell of the quantum dot may include a metal oxide, a non-metal oxide, a semiconductor compound, or combinations thereof.

For example, the metal oxide and the non-metal oxide may be selected from a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO; and a ternary compound such as MgAl₂O₄, CoFe₂O₄, NiFe₂O₄ and/or CoMn₂O₄, but embodiments of the present disclosure are not limited thereto.

In one or more embodiments, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments of the present disclosure are not limited thereto.

The quantum dot may have a full width of half maximum (FWHM) of emission wavelength spectrum of about 45 nm or less, for example, about 40 nm or less, and, about 30 nm or less. Within any of these ranges, color purity and/or color reproducibility may be improved. In addition, light emitted via such quantum dot is emitted in all directions, and light view angle properties may be improved.

In one or more embodiments, the shape of the quantum dot may be any suitable shape in the art, without specific limitation. For example, the shape of spherical, pyramidal, multi-arm, and/or cubic nanoparticle, nanotube, nanowire, nanofiber, nanoplate particle, etc. may be used.

The quantum dot may control the color of light emitted according to the particle size, and accordingly, the quantum dot may have various emission colors such as blue, red and green.

The light controlling layer CCL may include multiple light controlling parts CCP1, CCP2 and CCP3. The light controlling parts CCP1, CCP2 and CCP3 may be separated from one another.

Referring to FIG. 7, a partition pattern BMP may be between the separated light controlling parts CCP1, CCP2 and CCP3, but embodiments of the present disclosure are not limited thereto. In FIG. 7, the partition pattern BMP is shown as not overlapped with the light controlling parts CCP1, CCP2 and CCP3, but in one or more embodiments, at least a portion of the edge of the light controlling parts CCP1, CCP2 and CCP3 may be overlapped with the partition pattern BMP.

The light controlling layer CCL may include a first light controlling part CCP1 including a first quantum dot QD1 converting (e.g., to convert) first color light provided from the organic electroluminescence device ED into second color light, a second light controlling part CCP2 including a second quantum dot QD2 converting (e.g., to convert) first color light into third color light, and a third light controlling part CCP3 transmitting (e.g., to transmit) first color light.

In one or more embodiments, the first light controlling part CCP1 may provide red light, which is the second color light, and the second light controlling part CCP2 may provide green light, which is the third color light. The third light controlling part CCP3 may transmit and provide blue light, which is the first color light provided from the organic electroluminescence device ED. For example, the first quantum dot QD1 may be a red quantum dot, and the second quantum dot QD2 may be a green quantum dot. For the quantum dots QD1 and QD2, the same descriptions as those provided above may be applied.

In one or more embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include a quantum dot but may include the scatterer SP.

The scatterer SP may be an inorganic particle. For example, the scatterer SP may include at least one selected from among TiO₂, ZnO, Al₂O₃, SiO₂, and hollow silica. The scatterer SP may include at least one selected from among TiO₂, ZnO, Al₂O₃, SiO₂, and hollow silica, or may be a mixture of two or more materials selected from among TiO₂, ZnO, Al₂O₃, SiO₂, and hollow silica.

The first light controlling part CCP1, the second light controlling part CCP2, and the third light controlling part CCP3 may include base resins BR1, BR2 and BR3, respectively dispersing the quantum dots QD1 and QD2 and the scatterer SP. In one or more embodiments, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3. The base resins BR1, BR2 and BR3 are mediums in which the quantum dots QD1 and QD2 and the scatterer SP are dispersed, and may be composed of one or more suitable resin compositions which may be generally referred to as a binder. For example, the base resins BR1, BR2 and BR3 may each independently be acrylic resins, urethane-based resins, silicone-based resins, epoxy-based resins, etc. The base resins BR1, BR2 and BR3 may each independently be transparent resins. In one or more embodiments, the first base resin BR1, the second base resin BR2 and the third base resin BR3 may be the same or different from each other.

The light controlling layer CCL may include a barrier layer BFL1. The barrier layer BFL1 may play the role of blocking or reducing the penetration of moisture and/or oxygen (hereinafter, will be referred to as “humidity/oxygen”). The barrier layer BFL1 may be on the light controlling parts CCP1, CCP2 and CCP3 to block or reduce the exposure of the light controlling parts CCP1, CCP2 and CCP3 to humidity/oxygen. In one or more embodiments, the barrier layer BFL1 may cover the light controlling parts CCP1, CCP2 and CCP3. In one or more embodiments, the barrier layer BFL2 may be provided between a color filter layer CFL and the light controlling parts CCP1, CCP2 and CCP3.

The barrier layers BFL1 and BFL2 may include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and/or silicon oxynitride, or any suitable metal thin film capable of securing suitable light transmittance. In one or more embodiments, the barrier layers BFL1 and BFL2 may further include an organic layer. The barrier layers BFL1 and BFL2 may be composed of a single layer or multiple layers.

In the display apparatus DD of one or more embodiments, the color filter layer CFL may be on the light controlling layer CCL. For example, the color filter layer CFL may be directly on the light controlling layer CCL. In this case, the barrier layer BFL2 may be omitted.

The color filter layer CFL may include a light blocking part BM and filters CF-B, CF-G and CF-R. The color filter layer CFL may include a first filter CF1 transmitting (e.g., to transmit) second color light, a second filter CF2 transmitting (e.g., to transmit) third color light, and a third filter CF3 transmitting (e.g., to transmit) first color light. For example, the first filter CF1 may be a red filter, the second filter CF2 may be a green filter, and the third filter CF3 may be a blue filter. The filters CF1, CF2 and CF3 may each independently include a polymer photosensitive resin and a pigment and/or dye. The first filter CF1 may include a red pigment and/or dye, the second filter CF2 may include a green pigment and/or dye, and the third filter CF3 may include a blue pigment and/or dye. However, embodiments of the present disclosure are not limited thereto, and the third filter CF3 may not include the pigment or the dye. The third filter CF3 may include a polymer photosensitive resin and not include a pigment or dye. The third filter CF3 may be transparent. The third filter CF3 may be formed using (e.g., utilizing) a transparent photosensitive resin.

In one or more embodiments, the first filter CF1 and the second filter CF2 may be yellow filters. The first filter CF1 and the second filter CF2 may be provided in one body without distinction.

The light blocking part BM may be a black matrix. The light blocking part BM may be formed by including an organic light blocking material and/or an inorganic light blocking material including a black pigment and/or black dye. The light blocking part BM may prevent or reduce light leakage phenomenon and divide the boundaries among adjacent filters CF1, CF2 and CF3. In one or more embodiments, the light blocking part BM may be formed as a blue filter.

The first to third filters CF1, CF2 and CF3 may correspond to a red luminous area PXA-R, a green luminous area PXA-G, and a blue luminous area PXA-B, respectively.

On the color filter layer CFL, a base substrate BL may be provided. The base substrate BL may be a member providing a base surface on which the color filter layer CFL, the light controlling layer CCL, etc. are positioned. The base substrate BL may be a glass substrate, a metal substrate, a plastic substrate, etc. However, embodiments of the present disclosure are not limited thereto, and the base substrate BL may be an inorganic layer, an organic layer or a composite material layer (e.g., including an organic material and an inorganic material). In one or more embodiments, the base substrate BL may be omitted in one or more embodiments.

FIG. 9 is a cross-sectional view showing a portion of the display apparatus according to one or more embodiments. In FIG. 9, the cross-sectional view of a portion corresponding to the display panel DP in FIG. 8 is shown. In a display apparatus DD-TD of one or more embodiments, the organic electroluminescence device ED-BT may include multiple light emitting structures OL-B1, OL-B2 and OL-B3. The organic electroluminescence device ED-BT may include oppositely positioned first electrode EL1 and second electrode EL2, and the multiple light emitting structures OL-B1, OL-B2 and OL-B3 stacked in the stated order in a thickness direction and provided between the first electrode EL1 and the second electrode EL2. Each of the light emitting structures OL-B1, OL-B2 and OL-B3 may include an emission layer EML (FIG. 8), and a hole transport region HTR and an electron transport region ETR, with the emission layer EML (FIG. 8) therebetween.

For example, the organic electroluminescence device ED-BT included in the display apparatus DD-TD of one or more embodiments may be an organic electroluminescence device of a tandem structure including multiple emission layers. If the organic electroluminescence device ED includes multiple emission layers, at least one emission layer EML may include the polycyclic compound according to the present embodiments as described above.

In one or more embodiments shown in FIG. 9, light emitted from the light emitting structures OL-B1, OL-B2 and OL-B3 may be all blue light. However, embodiments of the present disclosure are not limited thereto, and the wavelength regions of light emitted from the light emitting structures OL-B1, OL-B2 and OL-B3 may be different from each other. For example, the organic electroluminescence device ED-BT including the multiple light emitting structures OL-B1, OL-B2 and OL-B3 emitting light in different wavelength regions may emit white light.

Between neighboring light emitting structures OL-B1, OL-B2 and OL-B3, a charge generating layer CGL may be provided. The charge generating layer CGL may include a p-type charge generating layer and/or an n-type charge generating layer.

Hereinafter, the present disclosure will be explained referring to Examples and Comparative Examples. However, these embodiments are only illustrations to assist in the understanding of the present disclosure, and the scope of the present disclosure is not limited thereto.

### Synthetic Examples

The compounds according to the embodiments of the present disclosure may be synthesized by, for example, as follows. However, the synthetic method of the compound according to one or more embodiments is not limited to the embodiments below.

### 1. Synthesis of Compound 1

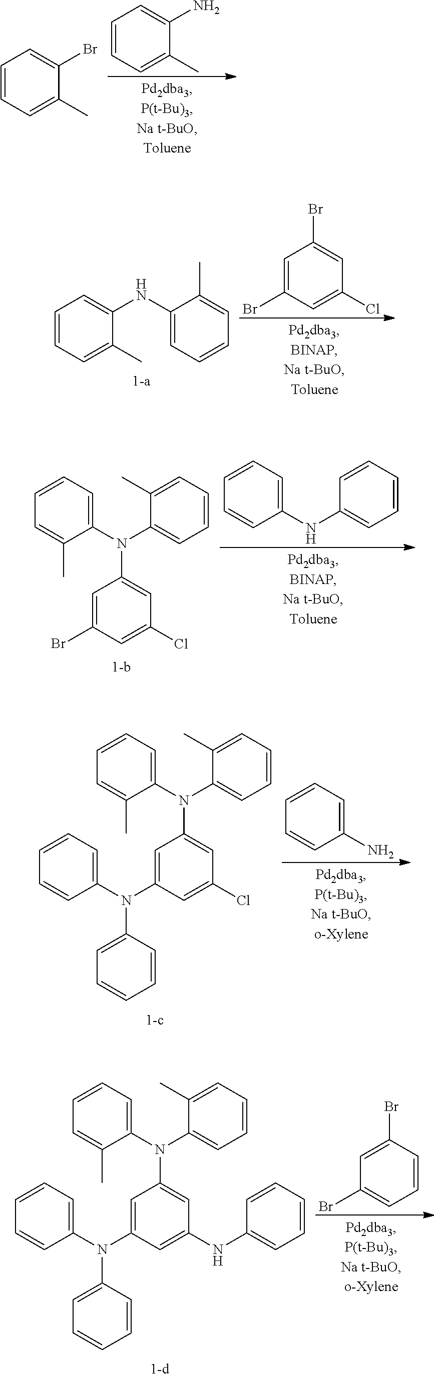

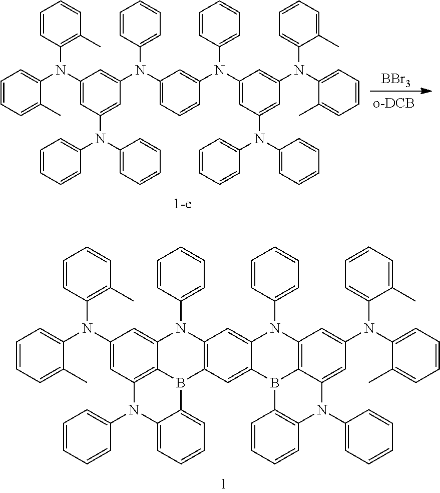

### 1.1 Synthesis of Intermediate 1-a

Under an argon atmosphere, to a 2 L flask, 1-bromo-2-methylbenzene (50 g, 292 mmol), o-toluidine (31 g, 292 mmol), tris-tert-butyl phosphine (13 mL, 29.2 mmol), sodium tert-butoxide (85 g, 876 mmol), and Pd₂dba₃ (13 g, 14.6 mmol) were put and dissolved in 1 L of toluene, and the reaction solution was stirred at about 100 degrees for about 6 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 1-a (colorless liquid, 41 g, 72%).

ESI-LCMS: [M]⁺: C₁₄H₁₅N. 197.1207.

¹H-NMR (400 MHz, CDCl₃): 7.13 (m, 6H), 6.91 (m, 2H), 2.12 (s, 6H).

### 1.2 Synthesis of Intermediate 1-b

Under an argon atmosphere, to a 2 L flask, Intermediate 1-a (40 g, 203 mmol), 3,5-dibromo-chlorobenzene (54 g, 203 mmol), BINAP (12.5 g, 20 mmol), sodium tert-butoxide (58 g, 609 mmol), and Pd₂dba₃ (9.3 g, 10 mmol) were put and dissolved in 1 L of toluene, and the reaction solution was stirred at about 90 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 1-b (white solid, 42 g, 54%).

ESI-LCMS: [M]⁺: C₂₀H₁₇NBrCl. 385.0112.

### 1.3 Synthesis of Intermediate 1-c

Under an argon atmosphere, to a 2 L flask, Intermediate 1-b (40 g, 103 mmol), diphenylamine (17 g, 103 mmol), BINAP (6.3 g, 10 mmol), sodium tert-butoxide (30 g, 309 mmol), and Pd₂dba₃ (4.7 g, 5 mmol) were put and dissolved in 1 L of toluene, and the reaction solution was stirred at about 90 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 1-c (white solid, 29 g, 61%).

ESI-LCMS: [M]⁺: C₃₂H₂₇N₂Cl. 474.1895.

### 1.4 Synthesis of Intermediate 1-d

Under an argon atmosphere, to a 2 L flask, Intermediate 1-c (29 g, 61 mmol), aniline (5.9 g, 61 mmol), tris-tert-butyl phosphine (2.8 mL, 6.2 mmol), sodium tert-butoxide (18 g, 183 mmol), and Pd₂dba₃ (2.8 g, 3.1 mmol) were put and dissolved in 600 mL of o-xylene, and the reaction solution was stirred at about 140 degrees for about 6 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 1-d (light brown liquid, 22 g, 70%).

ESI-LCMS: [M]⁺: C₃₈H₃₃N₃. 531.2661.

### 1.5 Synthesis of Intermediate 1-e

Under an argon atmosphere, to a 2 L flask, Intermediate 1-d (22 g, 41 mmol), 1,3-dibromobenzene (4.9 g, 20 mmol), tris-tert-butyl phosphine (1.0 mL, 2.0 mmol), sodium tert-butoxide (5.8 g, 60 mmol), and Pd₂dba₃ (0.9 g, 1 mmol) were put and dissolved in 600 mL of toluene, and the reaction solution was stirred at about 100 degrees for about 6 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 1-e (white liquid, 15 g, 68%).

ESI-LCMS: [M]⁺: C₈₂H₆₈N₆. 1136.5554.

### 1.6 Synthesis of Compound 1

Under an argon atmosphere, in a 1 L flask, Intermediate 1-e (15 g, 13 mmol) was dissolved in 500 mL of o-dichlorobenzene and cooled to 0 degrees in an ice-water bath. Boron tribromide (5 eq) was slowly added dropwisely to the reaction solution, the temperature was slowly elevated to room temperature, and stirring was performed for about 20 minutes. The temperature was elevated to about 150 degrees and stirring was performed for about 12 hours. After cooling, triethylamine (5 mL) was slowly added thereto dropwisely to quench the reaction, and all solvents were removed under a reduced pressure. The solid thus obtained was washed with MeOH and separated by column chromatography using silica gel and a developing solvent of CH₂Cl₂ and hexane to obtain Compound 1 (yellow solid, 1.8 g, 12%).

ESI-LCMS: [M]⁺: C₈₂H₆₂N₆B₂. 1152.5151.

¹H-NMR (400 MHz, CDCl₃): 10.21 (s, 1H), 9.32 (d, 2H), 7.24 (m, 10H), 7.15 (m, 10H), 7.02 (m, 24H), 6.91 (m, 4H), 6.83 (s, 1H), 6.49 (s, 4H), 2.12 (s, 8H).

### 2. Synthesis of Compound 15

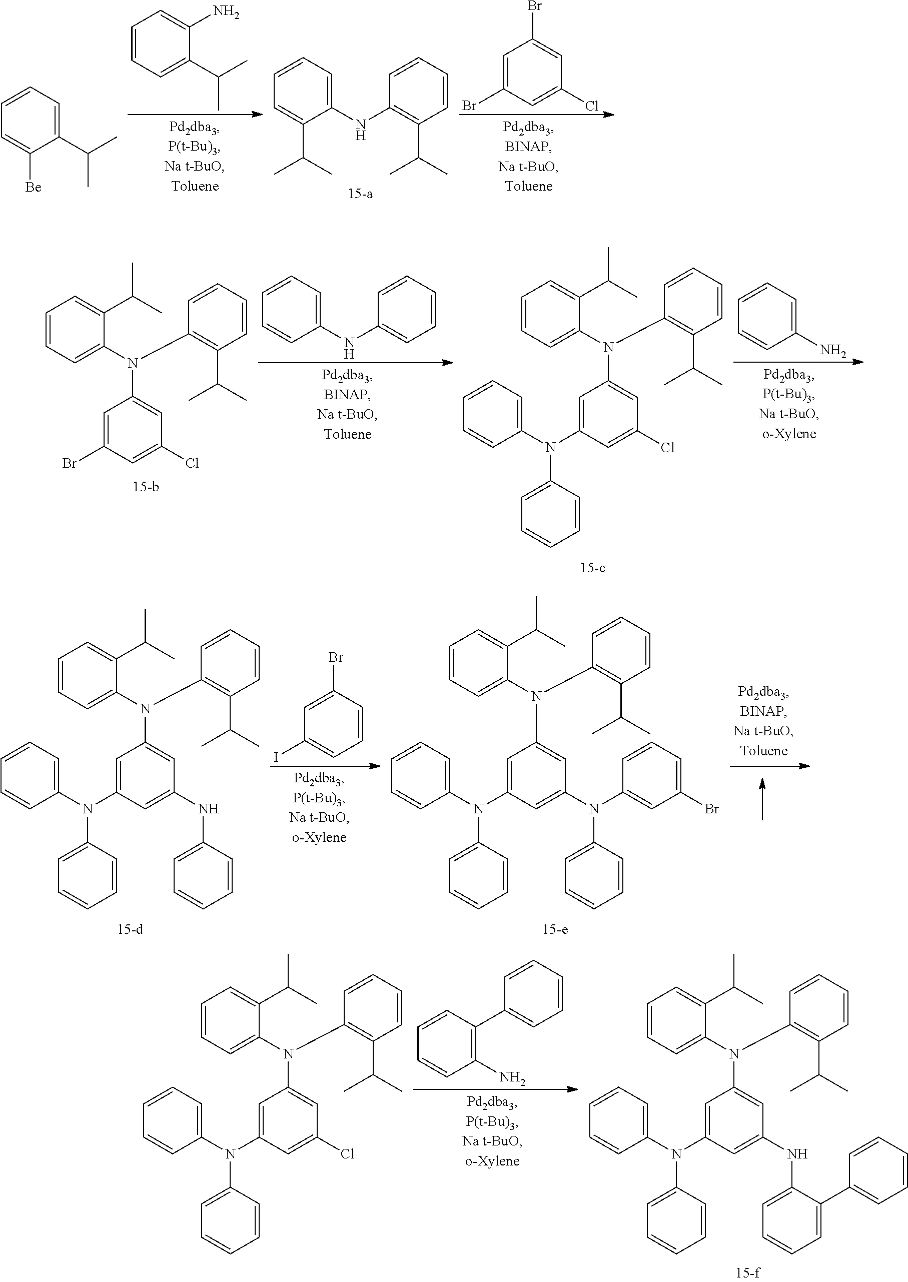

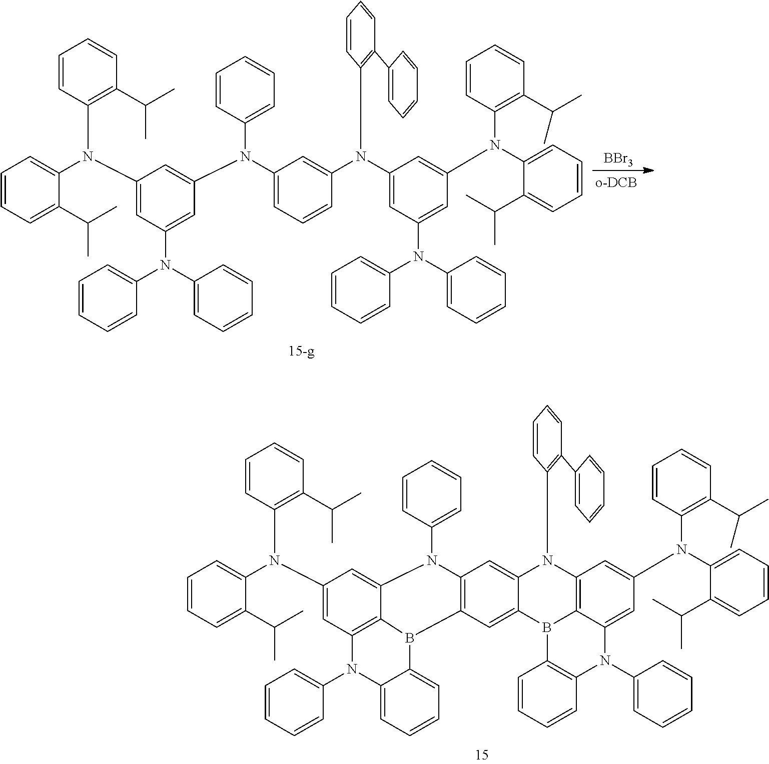

### 2.1 Synthesis of Intermediate 15-a

Under an argon atmosphere, to a 2 L flask, 1-bromo-2-isopropylbenzene (50 g, 251 mmol), 2-isopropylaniline (34 g, 251 mmol), tris-tert-butyl phosphine (12 mL, 25 mmol), sodium tert-butoxide (72 g, 753 mmol), and Pd₂dba₃ (11.5 g, 12.5 mmol) were put and dissolved in 1 L of toluene, and the reaction solution was stirred at about 100 degrees for about 6 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 15-a (colorless liquid, 46 g, 73%).

ESI-LCMS: [M]⁺: C₁₈H₂₃N. 253.1818.

¹H-NMR (400 MHz, CDCl₃): 7.28 (d, 2H), 7.19 (m, 4H), 6.96 (m, 2H), 2.88 (m, 2H), 1.19 (d, 8H).

### 2.2 Synthesis of Intermediate 15-b

Under an argon atmosphere, to a 2 L flask, Intermediate 15-a (45 g, 177 mmol), 3,5-dibromo-chlorobenzene (48 g, 177 mmol), BINAP (11 g, 17.8 mmol), sodium tert-butoxide (51 g, 531 mmol), and Pd₂dba₃ (8.1 g, 8.9 mmol) were put and dissolved in 1 L of toluene, and the reaction solution was stirred at about 90 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 15-b (white solid, 40 g, 52%).

ESI-LCMS: [M]⁺: C₂₄H₂₅NBrCl. 442.0939.

### 2.3 Synthesis of Intermediate 15-c

Under an argon atmosphere, to a 2 L flask, Intermediate 15-b (40 g, 90 mmol), diphenylamine (15 g, 90 mmol), BINAP (5.6 g, 9 mmol), sodium tert-butoxide (26 g, 270 mmol), and Pd₂dba₃ (4.1 g, 4.55 mmol) were put and dissolved in 1 L of toluene, and the reaction solution was stirred at about 90 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 15-c (white solid, 31 g, 66%).

ESI-LCMS: [M]⁺: C₃₆H₃₅N₂Cl. 530.2598.

### 2.4 Synthesis of Intermediate 15-d

Under an argon atmosphere, to a 2 L flask, Intermediate 15-c (30 g, 56 mmol), aniline (5.4 g, 56 mmol), tris-tert-butyl phosphine (2.5 mL, 5.6 mmol), sodium tert-butoxide (16 g, 168 mmol), and Pd₂dba₃ (2.5 g, 2.8 mmol) were put and dissolved in 600 mL of o-xylene, and the reaction solution was stirred at about 140 degrees for about 6 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 15-d (light brown liquid, 22 g, 68%).

ESI-LCMS: [M]⁺: C₄₂H₄₁N₃. 587.3313.

2.5 Synthesis of Intermediate 15-e

Under an argon atmosphere, to a 2 L flask, Intermediate 15-d (22 g, 37 mmol), 1-bromo-3-iodobenzene (5.0 g, 18 mmol), tris-tert-butyl phosphine (0.8 mL, 1.8 mmol), sodium tert-butoxide (5.1 g, 54 mmol), and Pd₂dba₃ (0.8 g, 0.9 mmol) were put and dissolved in 600 mL of toluene, and the reaction solution was stirred at about 100 degrees for about 6 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 15-e (white solid, 15 g, 63%).

ESI-LCMS: [M]⁺: C₉₆H₈₈N₆. 1324.7071.

### 2.6 Synthesis of Intermediate 15-f

Under an argon atmosphere, to a 2 L flask, Intermediate 15-c (20 g, 37 mmol), 2-amino biphenyl (6.4 g, 37 mmol), tris-tert-butyl phosphine (1.7 mL, 3.8 mmol), sodium tert-butoxide (10 g, 111 mmol), and Pd₂dba₃ (1.7 g, 1.9 mmol) were put and dissolved in 400 mL of o-xylene, and the reaction solution was stirred at about 140 degrees for about 6 hours. After cooling, water (1 L) and ethyl acetate (300 mL) were put, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 15-f (white solid, 19 g, 77%).

ESI-LCMS: [M]⁺: C₄₈H₄₅N₃. 663.3636.

### 2.7 Synthesis of Intermediate 15-g

Under an argon atmosphere, to a 2 L flask, Intermediate 15-e (20 g, 26 mmol), Intermediate 15-f (18 g, 26 mmol), BINAP (1.6 g, 2.6 mmol), sodium tert-butoxide (7.5 g, 78 mmol), and Pd₂dba₃ (1.2 g, 1.3 mmol) were put and dissolved in 400 mL of toluene, and the reaction solution was stirred at about 100 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 15-g (white solid, 26 g, 76%).

ESI-LCMS: [M]⁺: C₉₆H₈₈N₆. 1324.7101.

### 2.8 Synthesis of Compound 15

Under an argon atmosphere, in a 1 L flask, Intermediate 15-g (25 g, 18 mmol) was dissolved in 500 mL of o-dichlorobenzene and cooled to 0 degrees in an ice-water bath. Boron tribromide (5 eq) was slowly added dropwisely to the reaction solution, the temperature was slowly elevated to room temperature, and stirring was performed for about 20 minutes. The reaction solution was heated to about 150 degrees and stirred for about 12 hours. After cooling, triethylamine (5 mL) was slowly added thereto dropwisely to quench the reaction, and all solvents were removed under a reduced pressure. The solid thus obtained was washed with MeOH and separated by column chromatography using silica gel and a developing solvent of CH₂Cl₂ and hexane to obtain Compound 15 (yellow solid, 2.1 g, 9%).

ESI-LCMS: [M]⁺: C₉₆H₈₂N₆B₂. 1340.6719.

¹H-NMR (400 MHz, CDCl₃): 10.36 (s, 1H), 9.45 (d, 2H), 8.10 (d, 1H), 7.40 (m, 5H), 7.24 (m, 25H), 7.15 (m, 15H), 6.83 (s, 1H), 6.52 (s, 4H), 2.88 (m, 4H), 1.12 (d, 16H).

### 3. Synthesis of Compound 21

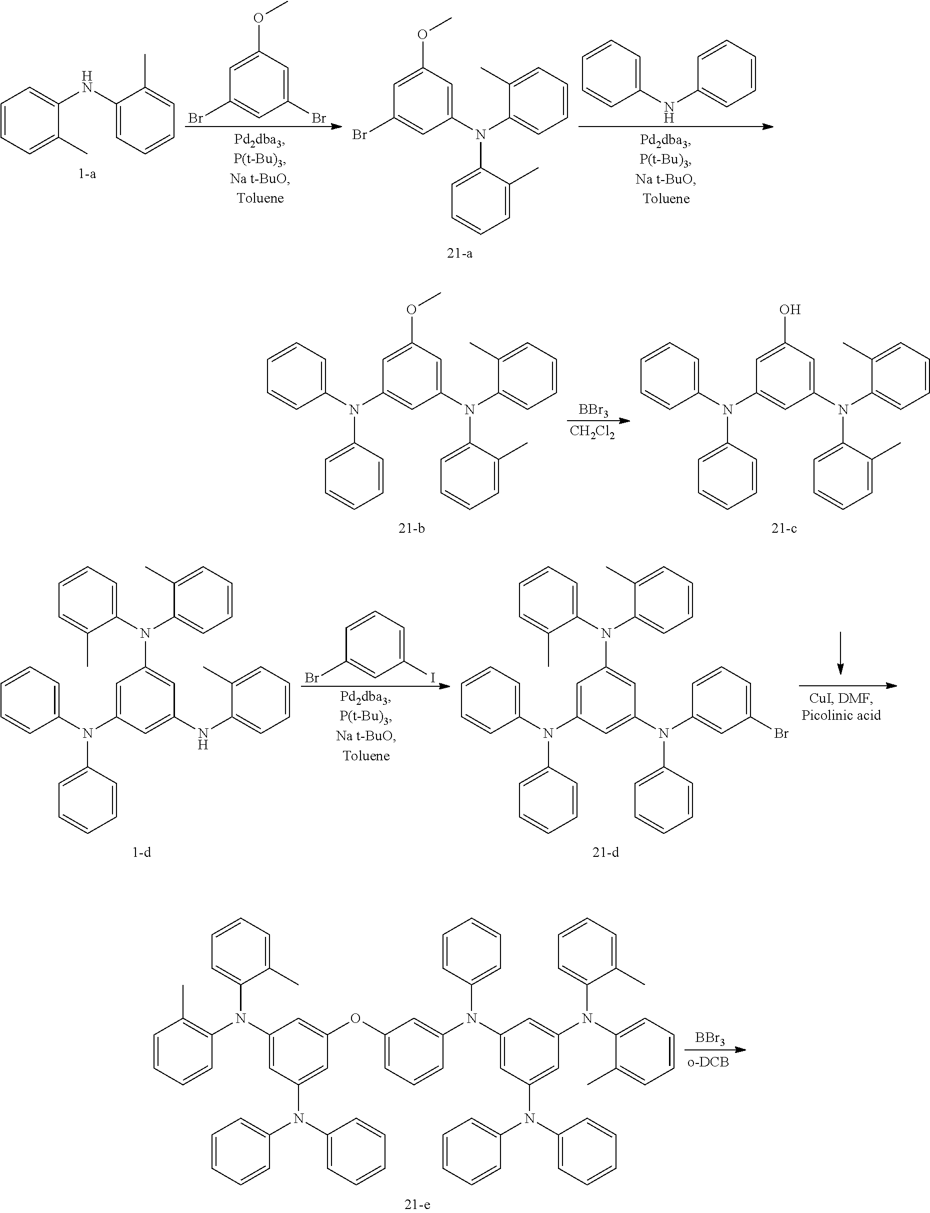

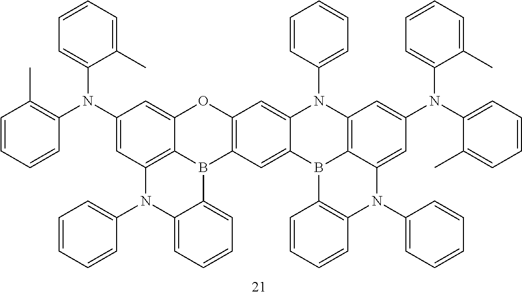 [SMILES: Cc1ccccc1N(c1cc2c3c(c1)N(c1ccccc1)c1ccccc1B3c1cc3c(cc1O2)N(c1ccccc1)c1cc(N(c2ccccc2C)c2ccccc2C)cc2c1B3c1ccccc1N2c1ccccc1)c1ccccc1C]

### 3.1 Synthesis of Intermediate 21-a

Under an argon atmosphere, to a 2 L flask, Intermediate 1-a (50 g, 254 mmol), 3,5-dibromo-methoxybenzene (68 g, 254 mmol), tris-tert-butyl phosphine (12 mL, 25.4 mmol), sodium tert-butoxide (73 g, 762 mmol), and Pd₂dba₃ (11.6 g, 12.7 mmol) were put and dissolved in 1 L of toluene, and the reaction solution was stirred at about 100 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 21-a (white solid, 49 g, 51%).

ESI-LCMS: [M]⁺: C₂₁H₂₀NOBr. 381.0516.

### 3.2 Synthesis of Intermediate 21-b

Under an argon atmosphere, to a 2 L flask, Intermediate 21-a (45 g, 117 mmol), diphenylamine (20 g, 254 mmol), tris-tert-butyl phosphine (10 mL, 12 mmol), sodium tert-butoxide (34 g, 351 mmol), and Pd₂dba₃ (5.3 g, 5.9 mmol) were put and dissolved in 1 L of toluene, and the reaction solution was stirred at about 100 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 21-b (white solid, 40 g, 73%).

ESI-LCMS: [M]⁺: C₃₃H₃₀N₂O. 470.2312.

### 3.3 Synthesis of Intermediate 21-c

Under an argon atmosphere, to a 2 L flask, Intermediate 21-b (40 g, 85 mmol) was put and dissolved in 1 L of CH₂Cl₂, and the reaction solution was cooled to 0 degrees in an ice-water bath. While keeping 0 degrees, BBr₃ (3 equiv.) was slowly added dropwisely. After slowly elevating the temperature to room temperature, stirring was performed for about 12 hours. The reaction solution was slowly poured into water (1 L), and extraction with ethyl acetate (300 mL) was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 21-c (gray solid, 22 g, 77%).

ESI-LCMS: [M]⁺: C₃₂H₂₈N₂O. 456.0167.

### 3.4 Synthesis of Intermediate 21-d

Under an argon atmosphere, to a 2 L flask, Intermediate 1-d (30 g, 56 mmol), 3-iodo-bromobenzene (16 g, 56 mmol), tris-tert-butyl phosphine (2.5 mL, 5.6 mmol), sodium tert-butoxide (16 g, 168 mmol), and Pd₂dba₃ (2.5 g, 2.8 mmol) were put and dissolved in 1 L mL of toluene, and the reaction solution was stirred at about 100 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 21-d (white solid, 25 g, 67%).

ESI-LCMS: [M]⁺: C₄₄H₃₆N₃Br. 685.1097.

### 3.5 Synthesis of Intermediate 21-e

Under an argon atmosphere, to a 2 L flask, Intermediate 21-d (20 g, 29 mmol), Intermediate 21-c (13 g, 29 mmol), copper iodide (5.5 g, 29 mmol), potassium carbonate (12 g, 87 mmol), and picolinic acid (3.7 g, 29 mmol) were put and dissolved in 300 mL of DMF, and the reaction solution was stirred at about 180 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 21-e (white solid, 1.46 g, 59%).

ESI-LCMS: [M]⁺: C₇₆H₆₃N₅O. 1031.4321.

### 3.6 Synthesis of Compound 21

Under an argon atmosphere, in a 1 L flask, Intermediate 21-e (18 g, 18 mmol) was dissolved in 500 mL of o-dichlorobenzene and cooled to 0 degrees in an ice-water bath. Boron tribromide (5 eq) was slowly added dropwisely to the reaction solution, the temperature was slowly elevated to room temperature, and stirring was performed for about 20 minutes. The reaction solution was heated to about 150 degrees and stirred for about 12 hours. After cooling, triethylamine (5 mL) was slowly added thereto dropwisely to quench the reaction, and all solvents were removed under a reduced pressure. The solid thus obtained was washed with MeOH and separated by column chromatography using silica gel and a developing solvent of CH₂Cl₂ and hexane to obtain Compound 21 (yellow solid, 1.6 g, 8%).

ESI-LCMS: [M]⁺: C₇₆H₅₇B₂N₅O. 1077.4787.

¹H-NMR (400 MHz, CDCl₃): 10.27 (5, 1H), 9.88 (d, 2H), 8.10 (d, 1H), 7.40 (m, 5H), 7.24 (m, 25H), 7.15 (m, 15H), 6.83 (5, 1H), 6.52 (5, 4H), 2.88 (m, 4H), 1.12 (d, 16H).

### 4. Synthesis of Compound 32

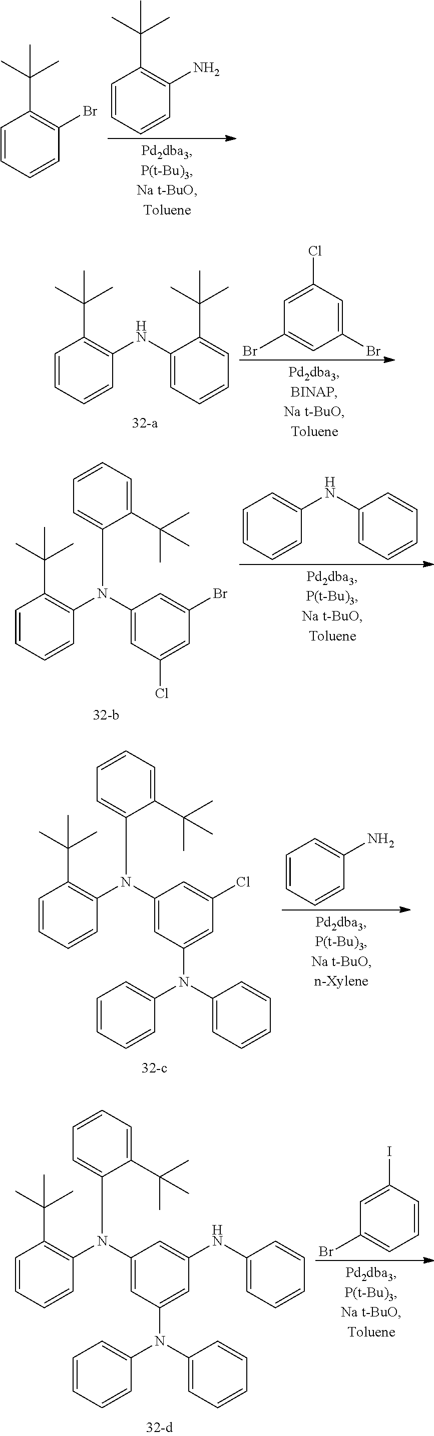

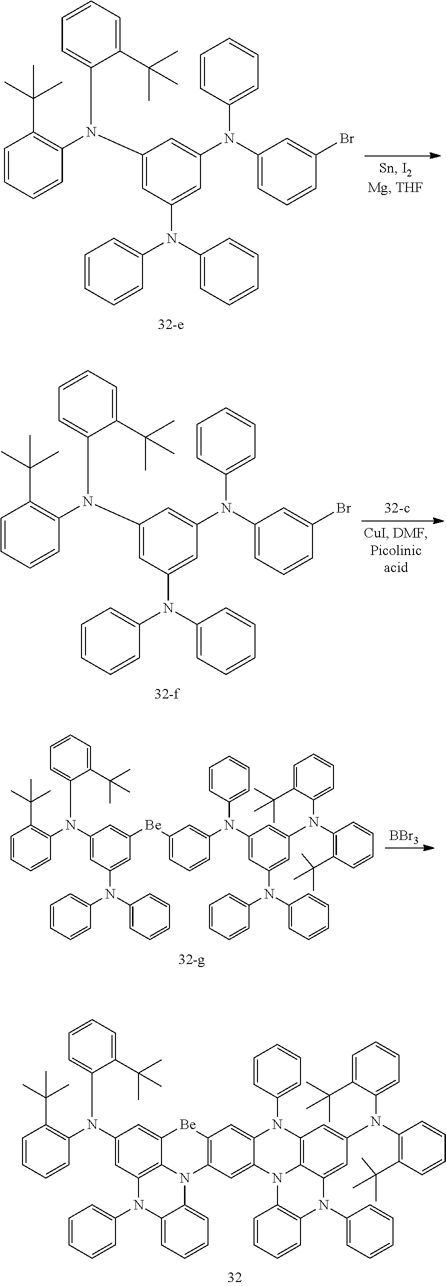

### 4.1 Synthesis of Intermediate 32-a

Under an argon atmosphere, to a 2 L flask, 2-tert-butylaniline (30 g, 201 mmol), 1-bromo-2-tert-butylbenzene (43 g, 201 mmol), tris-tert-butyl phosphine (9.2 mL, 20.2 mmol), sodium tert-butoxide (58 g, 603 mmol), and Pd₂dba₃ (9.2 g, 10.1 mmol) were put and dissolved in 1 L of toluene, and the reaction solution was stirred at about 100 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 32-a (colorless liquid, 45 g, 81%).

ESI-LCMS: [M]⁺: C₂₀H₂₇N. 281.2001.

¹H-NMR (400 MHz, CDCl₃): 7.20 (d, 2H), 7.11 (m, 6H), 1.37 (18H).

### 4.2 Synthesis of Intermediate 32-b

Under an argon atmosphere, to a 2 L flask, Intermediate 32-a (45 g, 160 mmol), 3,5-dibromo-chlorobenzene (43 g, 160 mmol), BINAP (10 g, 20.2 mmol), sodium tert-butoxide (46 g, 480 mmol), and Pd₂dba₃ (7.3 g, 8.0 mmol) were put and dissolved in 1 L of toluene, and the reaction solution was stirred at about 100 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 32-b (white solid, 39 g, 52%).

ESI-LCMS: [M]⁺: C₂₆H₂₉NBrCl. 469.1212.

### 4.3 Synthesis of Intermediate 32-c

Under an argon atmosphere, to a 2 L flask, Intermediate 32-b (39 g, 83 mmol), diphenylamine (14 g, 83 mmol), tris-tert-butyl phosphine (4.0 mL, 8.0 mmol), sodium tert-butoxide (23 g, 240 mmol), and Pd₂dba₃ (3.8 g, 4.0 mmol) were put and dissolved in 800 mL of toluene, and the reaction solution was stirred at about 100 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 32-c (white solid, 32 g, 64%).

ESI-LCMS: [M]⁺: C₃₈H₃₉N₂Br. 602.2311.

### 4.4 Synthesis of Intermediate 32-d

Under an argon atmosphere, to a 2 L flask, Intermediate 32-c (32 g, 53 mmol), aniline (5.1 g, 53 mmol), tris-tert-butyl phosphine (2.4 mL, 5.4 mmol), sodium tert-butoxide (14.4 g, 150 mmol), and Pd₂dba₃ (2.4 g, 2.7 mmol) were put and dissolved in 800 mL of o-xylene, and the reaction solution was stirred at about 140 degrees for about 6 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 32-d (white solid, 23 g, 72%).

ESI-LCMS: [M]⁺: C₄₄H₄₅N₃. 615.2019.

### 4.5 Synthesis of Intermediate 32-e

Under an argon atmosphere, to a 2 L flask, Intermediate 32-d (23 g, 37 mmol), 3-bromo-iodobenzene (10.6 g, 37 mmol), tris-tert-butyl phosphine (1.7 mL, 3.8 mmol), sodium tert-butoxide (10.6 g, 111 mmol), and Pd₂dba₃ (1.7 g, 1.9 mmol) were put and dissolved in 500 mL of toluene, and the reaction solution was stirred at about 100 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 32-e (white solid, 20 g, 73%).

ESI-LCMS: [M]⁺: C₅₀H₄₈N₃Br. 769.2897.

### 4.6 Synthesis of Intermediate 32-f

Under an argon atmosphere, to a 1 L flask, Mg (0.6 g, 26 mmol) was put and 300 mL of anhydrous THF was put. While stirring the reaction solution, I₂ was added, the temperature was elevated to about 60 degrees, and stirring was performed for about 15 minutes. If the color of the reaction solution was changed into gray, the reaction solution was cooled to room temperature, and Intermediate 32-e (20 g, 26 mmol) dissolved in 100 mL of anhydrous THF was slowly added thereto dropwisely. The temperature was elevated again to about 80 degrees, and refluxing and stirring was performed for about 30 minutes. A Se powder (12 g, 78 mmol) was added thereto, followed by refluxing and stirring for about 2 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 32-f (white solid, 8.6 g, 43%).

ESI-LCMS: [M]⁺: C₅₀H₄₉N₃Se. 771.3030.

### 4.7 Synthesis of Intermediate 32-g

Under an argon atmosphere, to a 1 L flask, Intermediate 32-f (8.6 g, 11 mmol), Intermediate 32-c (6.1 g, 11 mmol), copper iodide (2.1 g, 11 mmol), potassium carbonate (4.5 g, 33 mmol), and picolinic acid (1.3 g, 11 mmol) were put and dissolved in 200 mL of DMF, and the reaction solution was stirred at about 180 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 32-g (white solid, 11.5 g, 82%).

ESI-LCMS: [M]⁺: C₈₈H₈₇N₅Se. 1293.6001.

### 4.8 Synthesis of Compound 32

Under an argon atmosphere, in a 1 L flask, Intermediate 32-g (11 g, 8.5 mmol) was dissolved in 500 mL of o-dichlorobenzene and cooled to 0 degrees in an ice-water bath. Boron tribromide (5 eq) was slowly added dropwisely to the reaction solution, the temperature was slowly elevated to room temperature, and stirring was performed for about 20 minutes. The reaction solution was heated to about 150 degrees and stirred for about 12 hours. After cooling, triethylamine (5 mL) was slowly added thereto dropwisely to quench the reaction, and all solvents were removed under a reduced pressure. The solid thus obtained was washed with MeOH and separated by column chromatography using silica gel and a developing solvent of CH₂Cl₂ and hexane to obtain Compound 32 (yellow solid, 1.2 g, 11%).

ESI-LCMS: [M]⁺: C₈₈H₈₁B₂N₅Se. 1309.1557.

¹H-NMR (400 MHz, CDCl₃): 10.11 (s, 1H), 9.76 (d, 2H), 7.29 (m, 12H), 7.15 (m, 24H), 7.11 (m, 2H), 6.77 (m, 1H), 6.49 (s, 2H), 1.37 (s, 36H).

### 5. Synthesis of Compound 39

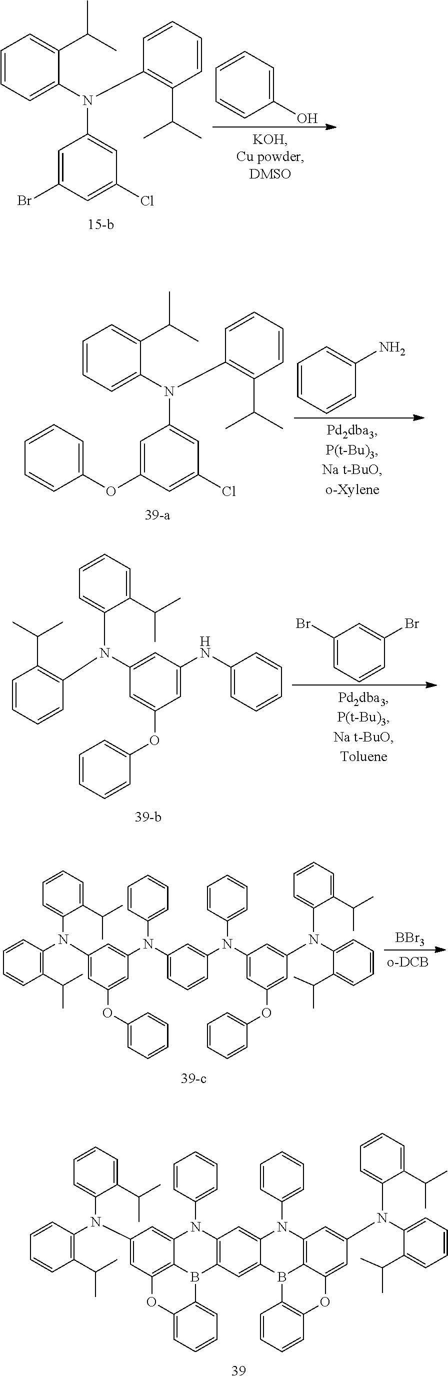

### 5.1 Synthesis of Intermediate 39-a

Under an argon atmosphere, to a 2 L flask, Intermediate 15-b (30 g, 68 mmol), phenol (13 g, 135 mmol), Copper powder (2.7 g, 68 mmol), and potassium hydroxide (11.4 g, 204 mmol) were put and dissolved in 800 mL of DMSO, and the reaction solution was stirred at about 150 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 39-a (colorless liquid, 27 g, 88%).

ESI-LCMS: [M]⁺: C₃₀H₃₀NOCl. 455.2012.

### 5.2 Synthesis of Intermediate 39-b

Under an argon atmosphere, to a 2 L flask, Intermediate 39-a (30 g, 59 mmol), aniline (5.7 g, 59 mmol), tris-tert-butyl phosphine (2.7 mL, 5.8 mmol), sodium tert-butoxide (17 g, 177 mmol), and Pd₂dba₃ (2.7 g, 2.9 mmol) were put and dissolved in 500 mL of o-xylene, and the reaction solution was stirred at about 140 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 39-b (white solid, 22 g, 73%).

ESI-LCMS: [M]⁺: C₃₆H₃₆N₂O. 512.2314.

### 5.3 Synthesis of Intermediate 39-c

Under an argon atmosphere, to a 1 L flask, Intermediate 39-b (22 g, 43 mmol), 1,3-dibromobenzene (5.0 g, 21 mmol), tris-tert-butyl phosphine (1.0 mL, 2.2 mmol), sodium tert-butoxide (6 g, 63 mmol), and Pd₂dba₃ (0.96 g, 1.1 mmol) were put and dissolved in 300 mL of toluene, and the reaction solution was stirred at about 100 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 39-c (white solid, 17 g, 77%).

ESI-LCMS: [M]⁺: C₇₈H₇₄N₄O₂. 1098.4437.

### 5.4 Synthesis of Compound 39

Under an argon atmosphere, in a 1 L flask, Intermediate 39-c (17 g, 15 mmol) was dissolved in 500 mL of o-dichlorobenzene, and cooled to 0 degrees in an ice-water bath. Boron tribromide (5 eq) was slowly added dropwisely to the reaction solution, the temperature was slowly elevated to room temperature, and stirring was performed for about 20 minutes. The reaction solution was heated to about 150 degrees and stirred for about 12 hours. After cooling, triethylamine (5 mL) was slowly added thereto dropwisely to quench the reaction, and all solvents were removed under a reduced pressure. The solid thus obtained was washed with MeOH and separated by column chromatography using silica gel and a developing solvent of CH₂Cl₂ and hexane to obtain Compound 39 (yellow solid, 0.7 g, 4%).

ESI-LCMS: [M]⁺: C₇₈H₆₈B₂N₄O₂. 1114.5514.

¹H-NMR (400 MHz, CDCl₃): 10.21 (s, 1H), 9.81 (d, 2H), 7.35 (m, 2H), 7.28 (m, 8H), 7.19 (m, 7H), 7.00 (m, 14H), 6.83 (s, 1H), 6.55 (s, 4H), 1.37 (s, 36H).

### 6. Synthesis of Compound 45

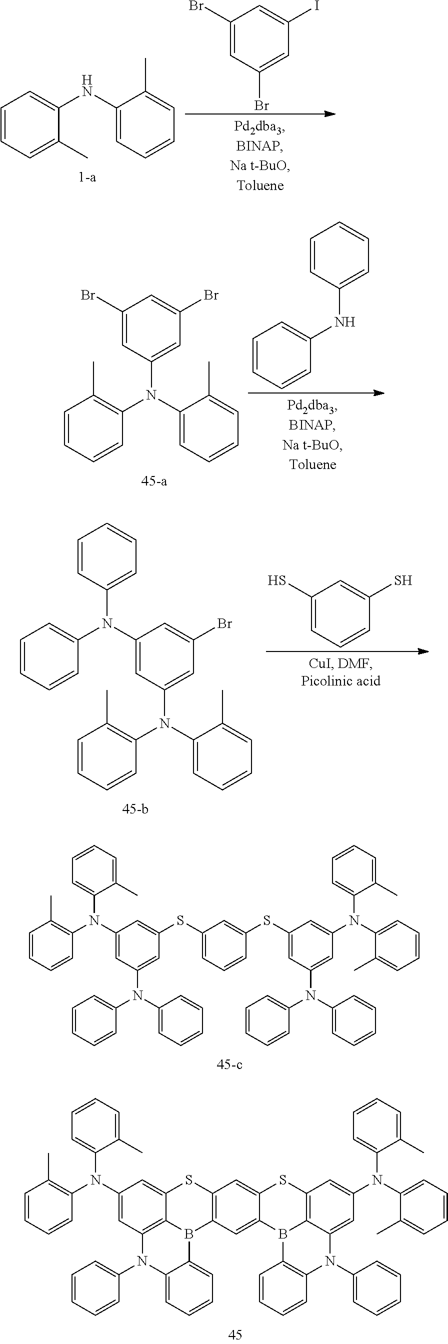

### 6.1 Synthesis of Intermediate 45-a

Under an argon atmosphere, to a 2 L flask, Intermediate 1-a (50 g, 253 mmol), 1,3-dibromo-5-iodobenzene (92 g, 253 mmol), BINAP (16 g, 25 mmol), sodium tert-butoxide (73 g, 759 mmol), and Pd₂dba₃ (11.6 g, 12.5 mmol) were put and dissolved in 1.5 L of toluene, and the reaction solution was stirred at about 100 degrees for about 12 hours. After cooling, water (1 L) and ethyl acetate (1 L) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 45-a (white solid, 41 g, 38%).

ESI-LCMS: [M]⁺: C₂₀H₁₇Br₂N. 428.9971.

### 6.2 Synthesis of Intermediate 45-b

Under an argon atmosphere, to a 2 L flask, Intermediate 45-a (40 g, 93 mmol), diphenylamine (16 g, 93 mmol), BINAP (5.9 g, 9.4 mmol), sodium tert-butoxide (27 g, 279 mmol), and Pd₂dba₃ (4.3 g, 4.7 mmol) were put and dissolved in 1 L of toluene, and the reaction solution was stirred at about 100 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 45-b (white solid, 22 g, 47%).

ESI-LCMS: [M]⁺: C₃₂H₂₇BrN₂. 518.1431.

### 6.3 Synthesis of Intermediate 45-c

Under an argon atmosphere, to a 2 L flask, Intermediate 45-b (22 g, 42 mmol), 1,3-dithiophenol (3 g, 21 mmol), CuI (4 g, 21 mmol), and 2-picolinic acid (2.6 g, 21 mmol) were put and dissolved in 200 mL of DMF, and the reaction solution was stirred at about 160 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 45-c (white solid, 14 g, 66%).

ESI-LCMS: [M]⁺: C₇₀H₅₈N₄S₂. 1018.4311.

### 6.4 Synthesis of Compound 45

Under an argon atmosphere, in a 1 L flask, Intermediate 45-c (14 g, 13 mmol) was dissolved in 500 mL of o-dichlorobenzene and cooled to 0 degrees in an ice-water bath. Boron tribromide (5 eq) was slowly added dropwisely to the reaction solution, the temperature was slowly elevated to room temperature, and stirring was performed for about 20 minutes. The reaction solution was heated to about 150 degrees and stirred for about 12 hours. After cooling, triethylamine (5 mL) was slowly added thereto dropwisely to quench the reaction, and all solvents were removed under a reduced pressure. The solid thus obtained was washed with MeOH and separated by column chromatography using silica gel and a developing solvent of CH₂Cl₂ and hexane to obtain Compound 45 (yellow solid, 1.07 g, 8%).

ESI-LCMS: [M]⁺: C₇₀H₅₂B₂N₄S₂. 1034.3838.

¹H-NMR (400 MHz, CDCl₃): 10.11 (s, 1H), 9.66 (d, 2H), 7.42 (s, 2H), 7.28 (m, 8H), 7.19 (m, 7H), 7.00 (m, 14H), 6.57 (s, 2H), 2.12 (s, 12H).

### 7. Synthesis of Compound 77

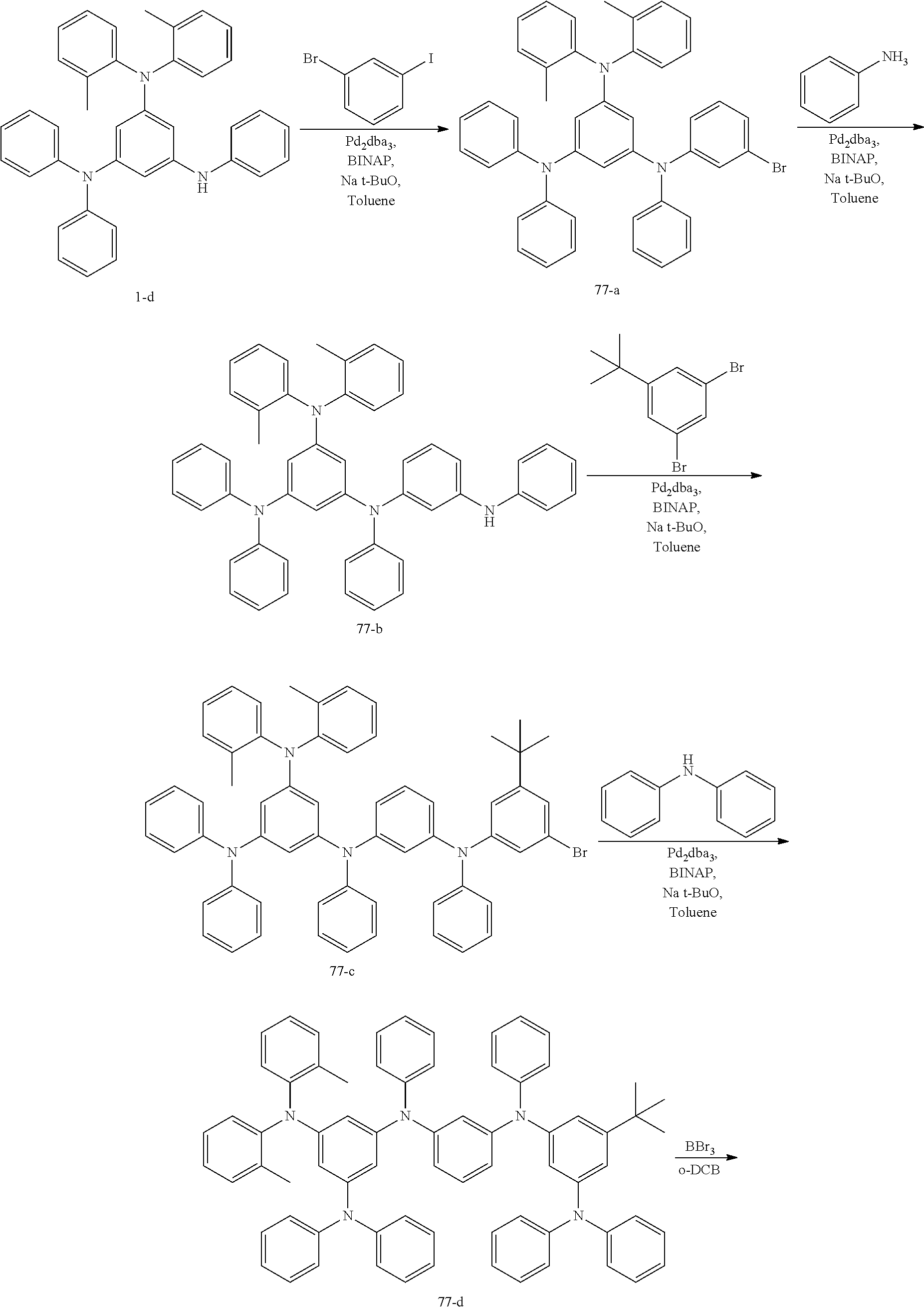

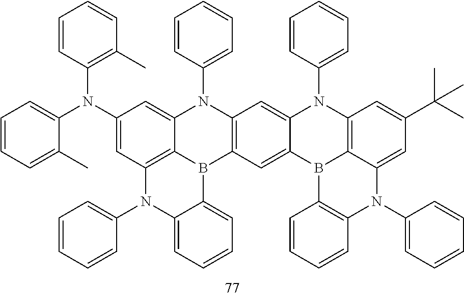 [SMILES: Cc1ccccc1N(c1cc2c3c(c1)N(c1ccccc1)c1cc4c(cc1B3c1ccccc1N2c1ccccc1)B1c2ccccc2N(c2ccccc2)c2cc(C(C)(C)C)cc(c21)N4c1ccccc1)c1ccccc1C]

### 7.1 Synthesis of Intermediate 77-a

Under an argon atmosphere, to a 2 L flask, Intermediate 1-d (30 g, 56 mmol), 3-iodo-bromobenzene (16 g, 56 mmol), BINAP (3.5 g, 5.6 mmol), sodium tert-butoxide (16 g, 168 mmol), and Pd₂dba₃ (2.6 g, 2.8 mmol) were put and dissolved in 500 mL of toluene, and the reaction solution was stirred at about 100 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 77-a (white solid, 25 g, 64%).

ESI-LCMS: [M]⁺: C₄₄H₃₆BrN₃. 685.2121.

### 7.2 Synthesis of Intermediate 77-b

Under an argon atmosphere, to a 1 L flask, Intermediate 77-a (25 g, 36 mmol), aniline (3.5 g, 56 mmol), BINAP (2.2 g, 3.6 mmol), sodium tert-butoxide (10.3 g, 108 mmol), and Pd₂dba₃ (1.6 g, 1.8 mmol) were put and dissolved in 350 mL of toluene, and the reaction solution was stirred at about 100 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 77-b (brown liquid, 19 g, 76%).

ESI-LCMS: [M]⁺: C₅₀H₄₂N₄. 698.3114.

### 7.3 Synthesis of Intermediate 77-c

Under an argon atmosphere, to a 1 L flask, Intermediate 77-b (19 g, 27 mmol), 3,5-dibromo-tert-butylbenzene (7.9 g, 27 mmol), BINAP (1.7 g, 2.8 mmol), sodium tert-butoxide (7.7 g, 81 mmol), and Pd₂dba₃ (1.2 g, 1.4 mmol) were put and dissolved in 300 mL of toluene, and the reaction solution was stirred at about 100 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 77-c (white solid, 13.7 g, 56%).

ESI-LCMS: [M]⁺: C₆₀H₅₃N₄Br. 908.2027.

### 7.4 Synthesis of Intermediate 77-d

Under an argon atmosphere, to a 1 L flask, Intermediate 77-c (13 g, 14 mmol), diphenylamine (2.4 g, 14 mmol), BINAP (0.8 g, 1.4 mmol), sodium tert-butoxide (4.0 g, 42 mmol), and Pd₂dba₃ (0.6 g, 0.7 mmol) were put and dissolved in 300 mL of toluene, and the reaction solution was stirred at about 100 degrees for about 12 hours. After cooling, water (1 L) and ethyl acetate (300 mL) were added, and extraction was performed. Organic layers were collected, dried with MgSO₄ and filtered. The solvent of the filtrate was removed under a reduced pressure, and the solid thus obtained was separated by column chromatography using silica gel and a developing solvent of CH₂Cl₂ and hexane to obtain Intermediate 77-d (white solid, 10.9 g, 78%).

ESI-LCMS: [M]⁺: C₇₂H₆₃N₅. 997.4011.

### 7.5 Synthesis of Compound 77

Under an argon atmosphere, in a 1 L flask, Intermediate 77-d (10 g, 10 mmol) was dissolved in 500 mL of o-dichlorobenzene and cooled to 0 degrees in an ice-water bath. Boron tribromide (5 eq) was slowly added dropwisely to the reaction solution, the temperature was slowly elevated to room temperature, and stirring was performed for about 20 minutes. The reaction solution was heated to about 150 degrees and stirred for about 12 hours. After cooling, triethylamine (5 mL) was slowly added thereto dropwisely to quench the reaction, and all solvents were removed under a reduced pressure. The solid thus obtained was washed with MeOH and separated by column chromatography using silica gel and a developing solvent of CH₂Cl₂ and hexane to obtain Compound 77 (yellow solid, 1.1 g, 11%).

ESI-LCMS: [M]⁺: C₇₂H₅₇B₂N₅. 1013.7148.

¹H-NMR (400 MHz, CDCl₃): 10.22 (s, 1H), 9.78 (d, 2H), 7.29 (m, 10H), 7.14 (m, 16H), 7.02 (m, 6H), 6.83 (s, 1H), 6.49 (s, 2H), 2.12 (s, 6H), 1.32 (s, 9H).

### Manufacture of Organic Electroluminescence Device

Organic electroluminescence devices were manufactured using Example Compounds and Comparative Compounds below as materials of an emission layer.

### Example Compounds

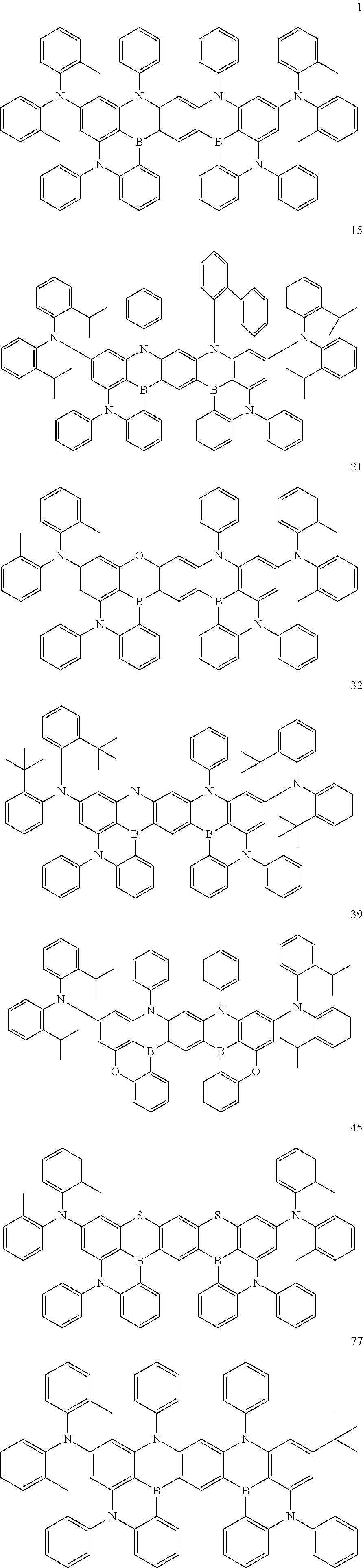

### Comparative Compounds

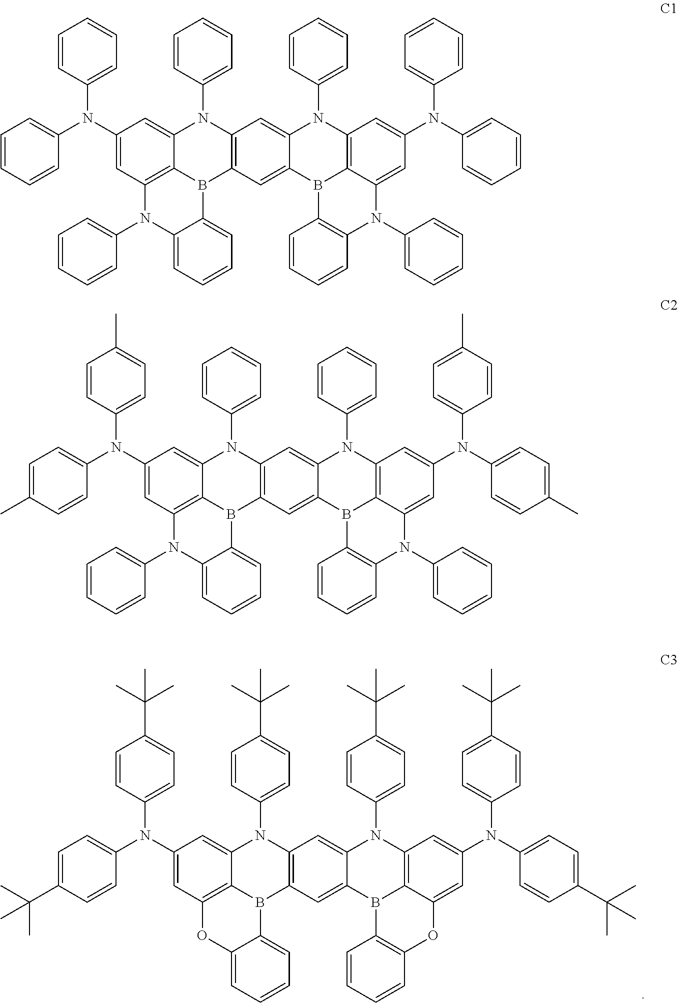

The organic electroluminescence devices of the Examples and Comparative Examples were manufactured by a method below.

On a glass substrate, ITO with a thickness of about 1,200 Å was patterned to form a first electrode and washed with ultrasonic waves using isopropyl alcohol and pure water for about five minutes for each, exposed to ultraviolet rays for about 30 minutes and cleansed by exposing to ozone. On the glass substrate on which the ITO was formed, α-NPD was vacuum deposited as a hole injection layer to a thickness of about 300 Å, and H-1-19 was vacuum deposited to a thickness of about 200 Å to form a hole transport layer. On the hole transport layer, a hole transport compound of CzSi was vacuum deposited to a thickness of about 100 Å to form an emission auxiliary layer.

Then, the polycyclic compound of one or more embodiments or the Comparative Compound were co-deposited with mCP in a weight ratio of 99:1 to form a layer having a thickness of about 200 Å to form an emission layer.

After that, on the emission layer, TSPO1 was vacuum deposited to form an electron transport layer having a thickness of about 200 Å, and on the electron transport layer, an electron transport compound of TPBi was vacuum deposited to form a buffer layer having a thickness of about 300 Å. Then, an alkali metal halide of LiF was deposited to form an electron injection layer having a thickness of about 10 Å, and Al was vacuum deposited to form an LiF/Al electrode having a thickness of about 3,000 Å. On the electrode, P4 was vacuum deposited to a thickness of about 700 Å to form a capping layer and to manufacture an organic electroluminescence device.

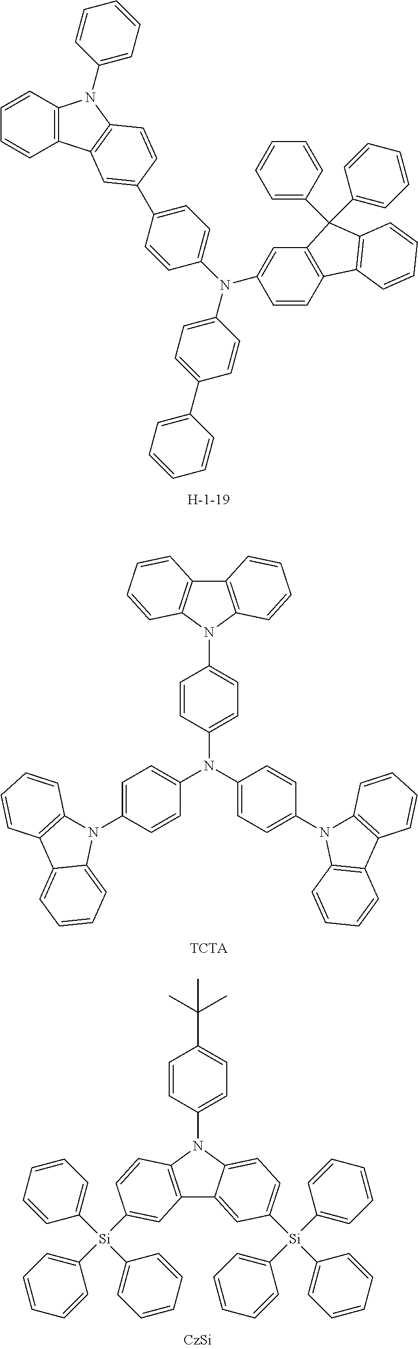 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1]

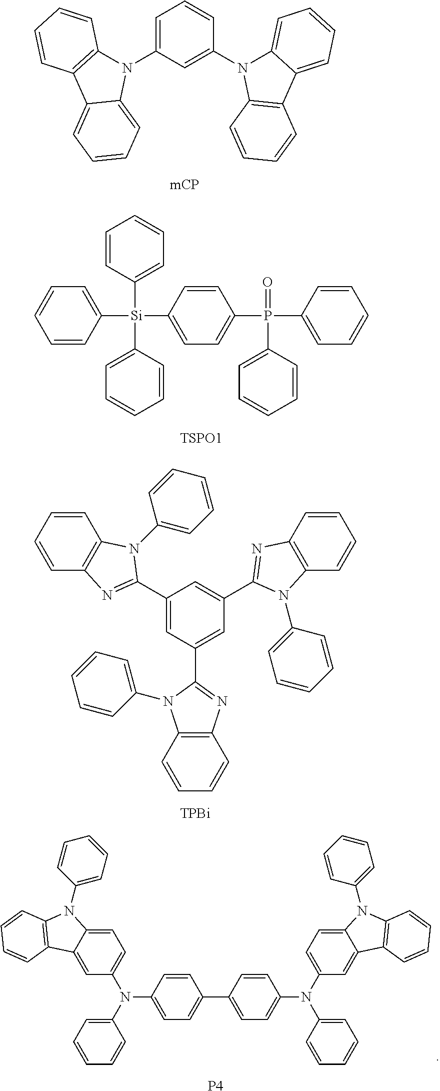

### Evaluation of Properties of Organic Electroluminescence Device

In order to evaluate the properties of the organic electroluminescence devices of the Examples and Comparative Examples, a driving voltage and efficiency (cd/A) were measured at a current density of about 10 mA/cm², and evaluation was conducted on time from an initial value when continuously driving at the current density of about 10 mA/cm² to a point where luminance was deteriorated to about 95% regarding a relative value of Comparative Example 1 as relative device life.

TABLE 1

| | Light- | Driving | | Emission | Device |
|---|---|---|---|---|---|
| | emitting | voltage | Efficiency | color | life ratio |
| | material | (V) | (cd/A) | (nm) | (T95) |
| Example 1 | Compound 1 | 4.4 | 25.7 | 460 | 2.71 |
| Example 2 | Compound 15 | 4.4 | 26.3 | 458 | 4.30 |
| Example 3 | Compound 21 | 4.2 | 23.2 | 455 | 1.68 |
| Example 4 | Compound 32 | 4.3 | 28.9 | 456 | 4.01 |
| Example 5 | Compound 39 | 4.5 | 22.7 | 460 | 3.11 |
| Example 6 | Compound 45 | 4.4 | 27.5 | 454 | 2.59 |
| Example 7 | Compound 77 | 4.4 | 24.9 | 464 | 2.27 |
| Cornparative | Compound C1 | 4.3 | 21.5 | 466 | 1.00 |
| Example 1 | | | | | |
| Cornparative | Compound C2 | 4.5 | 20.7 | 470 | 1.23 |
| Example 2 | | | | | |
| Cornparative | Compound C3 | 4.4 | 20.9 | 462 | 0.78 |
| Example 3 | | | | | |

Referring to the results of Table 1, it could be confirmed that the Examples of the organic electroluminescence devices using the polycyclic compound according to one or more embodiments of the present disclosure as the material of an emission layer showed a lower driving voltage value and showed relatively higher emission efficiency and life (lifespan) when compared with the Comparative Examples.

The polycyclic compound according to one or more embodiments may include a structure in which five benzene rings are connected via two boron atoms and four heteroatoms and includes a structure in which a group represented by Formula 2-1 or Formula 2-2 including a nitrogen atom is connected at the para position of a benzene ring to which the boron atom is connected. Accordingly, due to multiple resonance effects, the HOMO and LUMO overlap is minimized or reduced, and a small ΔE_{ST} value is shown, and accordingly, the polycyclic compound may be used as a material for emitting delayed fluorescence. In addition, the groups represented by Formula 2-1 and Formula 2-2 include substituents including alkyl groups or sterically bulky groups at ortho positions with respect to carbon connected with nitrogen atoms, and if connected with the polycyclic compound represented by Formula 1 according to one or more embodiments, twist effects of the substituents may be generated, intermolecular interaction may be restrained, and if applied to an organic electroluminescence device, high emission efficiency properties may be expected.

Similar to the Examples, Comparative Example 1 to Comparative Example 3 have a core structure including two boron atoms and includes a structure in which diphenylamine is connected as a terminal substituent at the para position of a benzene ring to which a boron atom is connected. However, because a substituent having steric hindrance properties is not included at the ortho position relative to the nitrogen atom of the diphenylamine group, twist effects are degraded, and accordingly, red shift phenomenon is shown. In addition, because intermolecular interaction was not effectively (or suitably) restrained, degraded results of device efficiency and life were shown when compared with the organic electroluminescence devices of the Examples.

For example, in Comparative Example 2 and Comparative Example 3, the alkyl groups are included in diphenylamine groups as peripheral substituents, but all are connected at the para position relative to a nitrogen atom, and it could be confirmed that red shift and quenching phenomenon due to intermolecular interaction, which are basically the defects of a multiresonant core, were not solved (or were not suitably solved).

The organic electroluminescence device of one or more embodiments includes the polycyclic compound of one or more embodiments and may show improved emission efficiency. In addition, the organic electroluminescence device of one or more embodiments includes the polycyclic compound of one or more embodiments as a material of an emission layer, and high emission efficiency in a blue light wavelength region may be accomplished.

The organic electroluminescence device of one or more embodiments may show improved device characteristics of a low driving voltage and high efficiency.

The polycyclic compound of one or more embodiments may be included in the emission layer of an organic electroluminescence device and may contribute to the increase of the efficiency of the organic electroluminescence device.

Although the embodiments of the present disclosure have been described, it is understood that the present disclosure should not be limited to these embodiments, but various changes and modifications can be made by one ordinary skilled in the art within the spirit and scope of the present disclosure as hereinafter claimed by the following claims and equivalents thereof.

What is claimed is:

1. An organic electroluminescence device, comprising:
a first electrode;
an organic layer on the first electrode; and
a second electrode on the organic layer;
wherein the first electrode and the second electrode each independently comprises at least one selected from among Ag, Mg, Cu, Al, Pt, Pd, Au, Ni, Nd, Ir, Cr, Li, Ca, LiF, Mo, Ti, W, In, Sn, Zn, compounds thereof, mixtures thereof, and oxides thereof, and
the organic layer comprises a polycyclic compound represented by the following Formula 1: 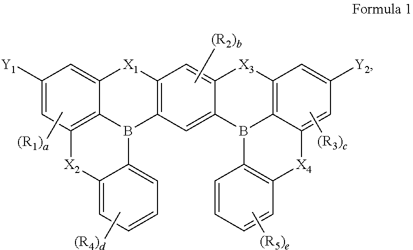
wherein, in Formula 1,
X₁ to X₄ are each independently CR₆R₇, NR₈, O, S, or Se,
R₁ to R₇ are each independently a hydrogen atom, a deuterium atom, a halogen atom, a nitro group, a cyano group, a hydroxyl group, a substituted or unsubstituted amine group, a substituted or unsubstituted thiol group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring,
R₈ is a hydrogen atom, a deuterium atom, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring,
Y₁ and Y₂ are each independently a hydrogen atom, a deuterium atom, a halogen atom, a substituted or unsubstituted silyl group, a substituted or unsubstituted oxy group, a substituted or unsubstituted amine group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring,
a to c are each independently an integer of 0 to 2, and
d and e are each independently an integer of 0 to 4,
where at least one selected from among Y₁ and Y₂ is represented by the following Formula 2-1 or Formula 2-2: 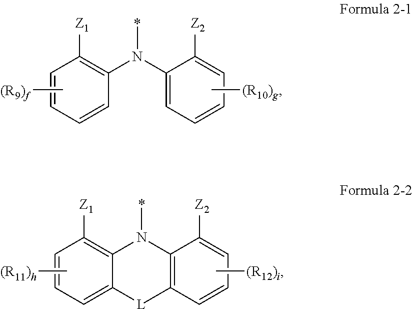
and
wherein, in Formula 2-1 and Formula 2-2,
L is a direct linkage, CR₁₃R₁₄, O, or S,
R₉ to R₁₂ are each independently a hydrogen atom, a deuterium atom, a halogen atom, a cyano group, a nitro group, a hydroxyl group, a substituted or unsubstituted silyl group, a substituted or unsubstituted oxy group, a substituted or unsubstituted thiol group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring,
R₁₃ and R₁₄ are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
Z₁ and Z₂ are each independently a substituted or unsubstituted silyl group, a substituted or unsubstituted alkyl group of 1 to 20 carbon atoms, a substituted or unsubstituted cycloalkyl group of 3 to 20 carbon atoms, a substituted or unsubstituted bicycloalkyl group of 5 to 30 carbon atoms, or a substituted or unsubstituted tricycloalkyl group of 8 to 30 carbon atoms,
f and g are each independently an integer of 0 to 4, and
h and i are each independently an integer of 0 to 3.

2. The organic electroluminescence device of claim 1, wherein the organic layer comprises:
a hole transport region on the first electrode;
an emission layer on the hole transport region; and
an electron transport region on the emission layer, and
wherein at least one selected from among the hole transport region, the emission layer, and the electron transport region comprises the polycyclic compound.

3. The organic electroluminescence device of claim 2, wherein the emission layer comprises the polycyclic compound and is to emit delayed fluorescence.

4. The organic electroluminescence device of claim 3, wherein the emission layer is a delayed fluorescence emission layer comprising a host and a dopant, and the dopant comprises the polycyclic compound represented by Formula 1.

5. The organic electroluminescence device of claim 2, wherein the electron transport region comprises:
an electron transport layer on the emission layer; and
an electron injection layer on the electron transport layer, and
wherein the electron transport layer or the electron injection layer comprises the polycyclic compound.

6. The organic electroluminescence device of claim 1, wherein Formula 2-2 is represented by the following Formula 3: 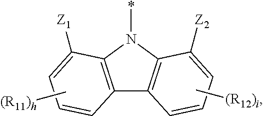
and
wherein in Formula 3,
Z₁, Z₂, R₁₁, R₁₂, h, and i are the same as defined in Formula 2-2.

7. The organic electroluminescence device of claim 1, wherein Formula 1 is represented by any one selected from among the following Formula 4-1 to Formula 4-4: 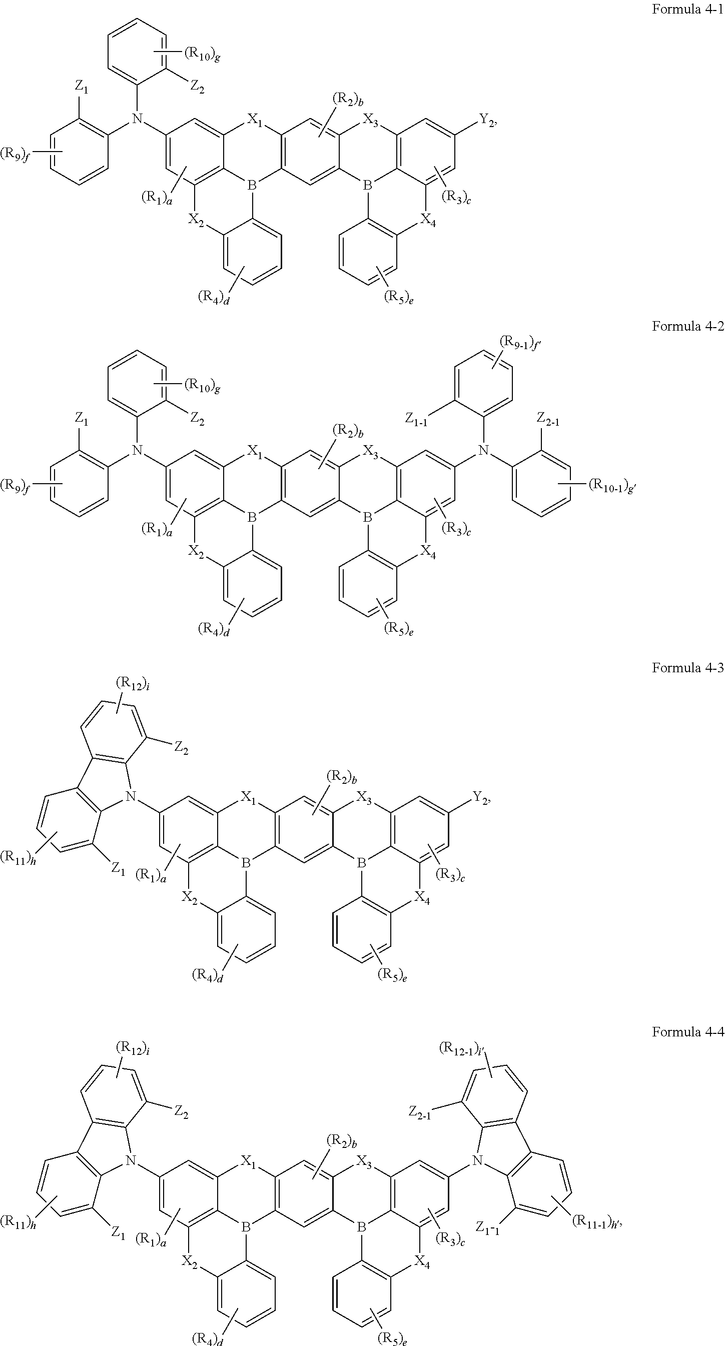
in Formula 4-1 to Formula 4-4,
Z₁₋₁ and Z₂₋₁ are each independently a substituted or unsubstituted silyl group, a substituted or unsubstituted alkyl group of 1 to 20 carbon atoms, a substituted or unsubstituted cycloalkyl group of 3 to 20 carbon atoms, a substituted or unsubstituted bicycloalkyl group of 5 to 30 carbon atoms, or a substituted or unsubstituted tricycloalkyl group of 8 to 30 carbon atoms,
R₉₋₁, R₁₀₋₁, R₁₁₋₁, and R₁₂₋₁ are each independently a hydrogen atom, a deuterium atom, a halogen atom, a cyano group, a nitro group, a hydroxyl group, a substituted or unsubstituted silyl group, a substituted or unsubstituted oxy group, a substituted or unsubstituted thiol group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring,
f′ and g′ are each independently an integer of 0 to 4,
h′ and are each independently an integer of 0 to 3, and
X₁ to X₄, R₁ to R₅, a to e, Y₂, Z₁, Z₂, R₉ to R₁₂, and f to i are the same as defined in Formula 1 and Formula 2.

8. The organic electroluminescence device of claim 1, wherein Z₁ and Z₂ are each independently a silyl group substituted with a substituted or unsubstituted alkyl group of 1 to 10 carbon atoms, a substituted or unsubstituted alkyl group of 1 to 10 carbon atoms, a substituted or unsubstituted cycloalkyl group of 3 to 10 ring-forming carbon atoms, a substituted or unsubstituted bicycloalkyl group of 5 to 10 ring-forming carbon atoms, or a substituted or unsubstituted tricycloalkyl group of 8 to 12 ring-forming carbon atoms.

9. The organic electroluminescence device of claim 1, wherein at least one selected from among X₁ to X₄ is NAr₁, and
Ar₁ is a substituted or unsubstituted aryl group of 6 to 30 ring-forming carbon atoms, or a substituted or unsubstituted heteroaryl group of 2 to 30 ring-forming carbon atoms.

10. The organic electroluminescence device of claim 1, wherein Formula 1 is represented by any one selected from among the following Formula 5-1 to Formula 5-5: 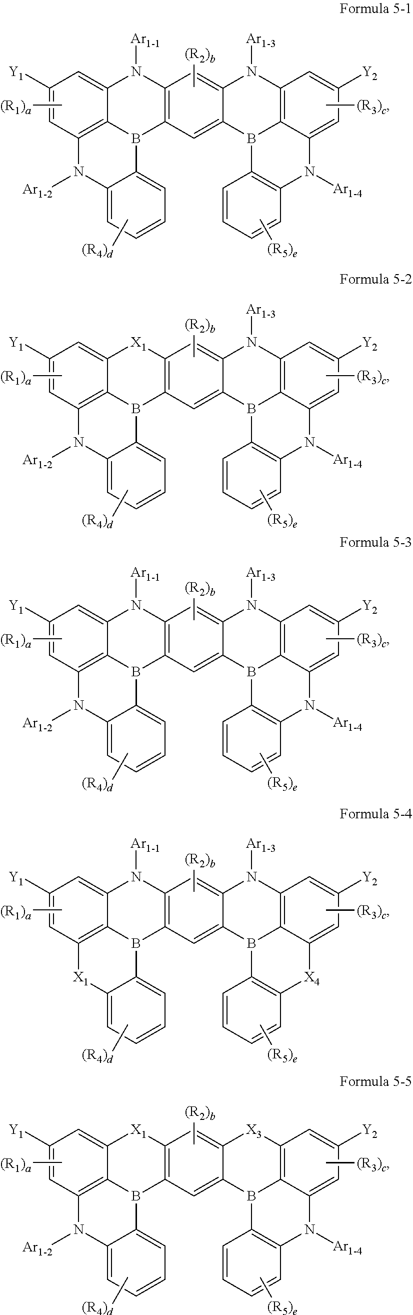
in Formula 5-1 to Formula 5-5,
X₁ to X₄ are each independently O, S, or Se,
Ar₁₋₁ to Ar₁₋₄ are each independently a substituted or unsubstituted aryl group of 6 to 30 ring-forming carbon atoms, or a substituted or unsubstituted heteroaryl group of 2 to 30 ring-forming carbon atoms, and
Y₁, Y₂, R₁ to R₅, and a to e are the same as defined in Formula 1.

11. The organic electroluminescence device of claim 10, wherein Ar₁₋₁ to Ar₁₋₄ are each independently represented by any one selected from among the following Formula 6-1 to Formula 6-3: 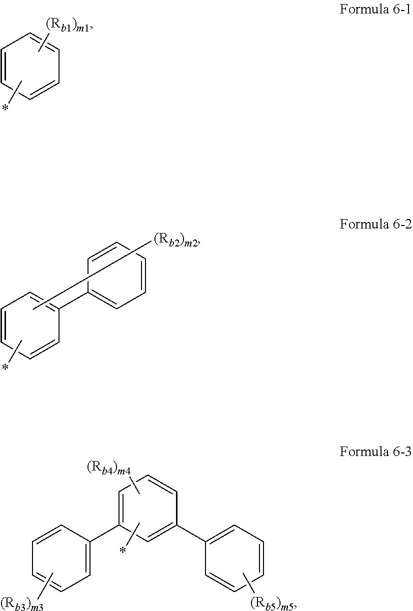
in Formula 6-1 to Formula 6-3,
R_{b1} to R_{b5} are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring,
m1, m3, and m5 are each independently an integer of 0 to 5,
m2 is an integer of 0 to 9, and
m4 is an integer of 0 to 3.

12. The organic electroluminescence device of claim 1, wherein the polycyclic compound represented by Formula 1 is any one selected from among compounds represented in the following Compound Group 1:

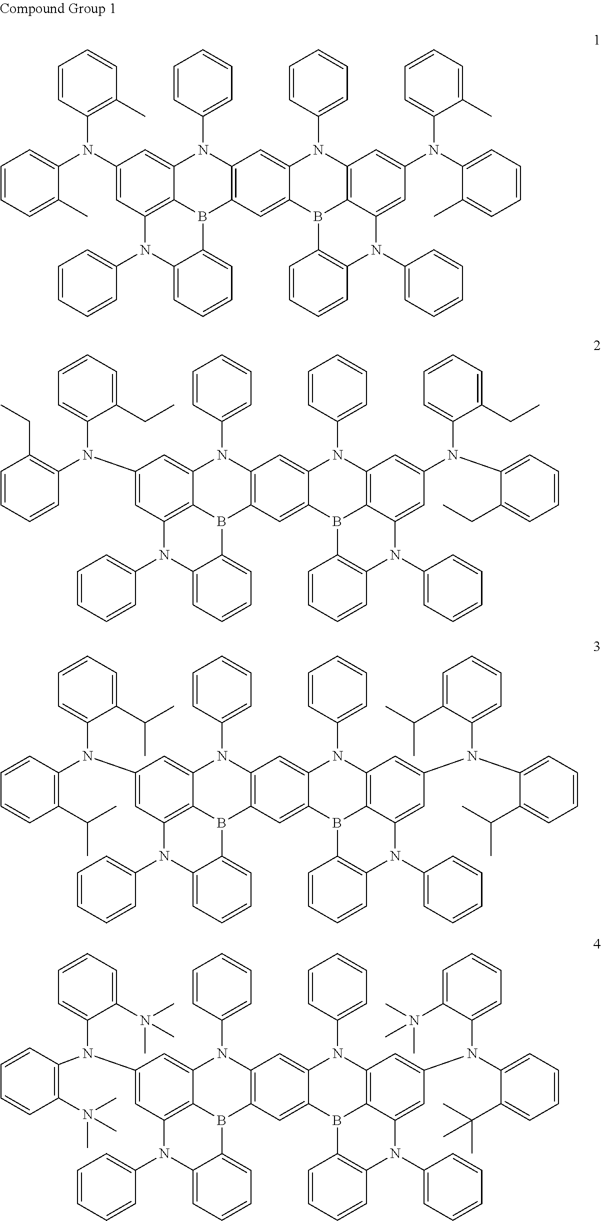

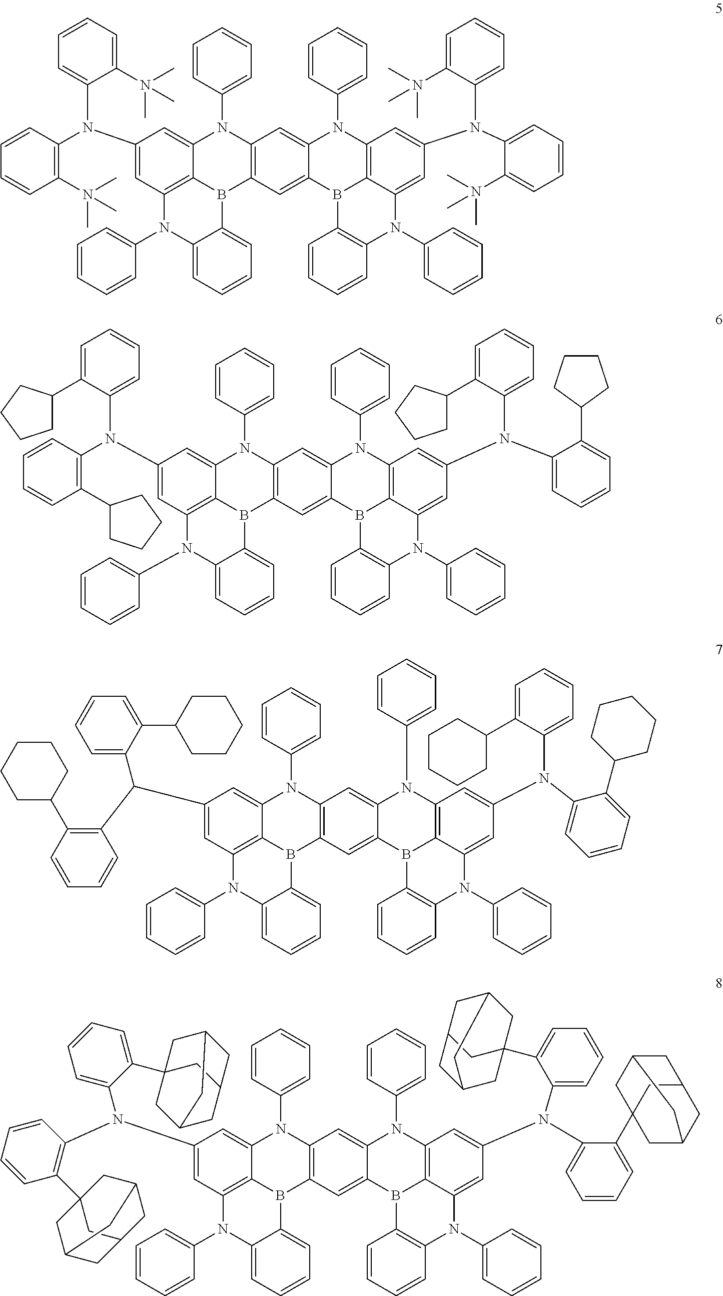

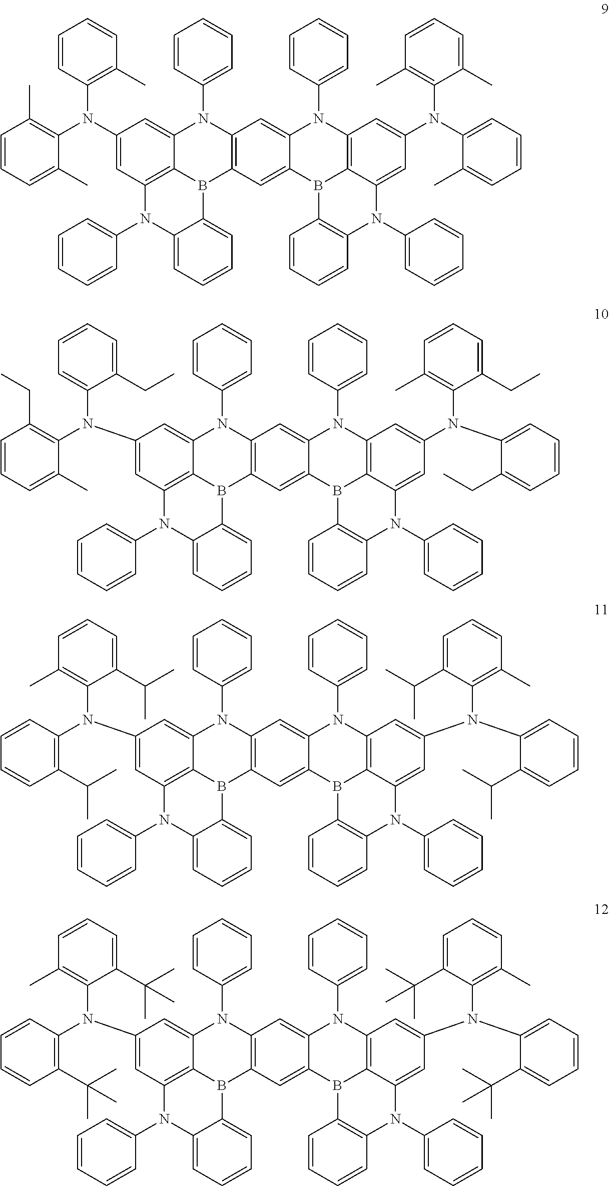

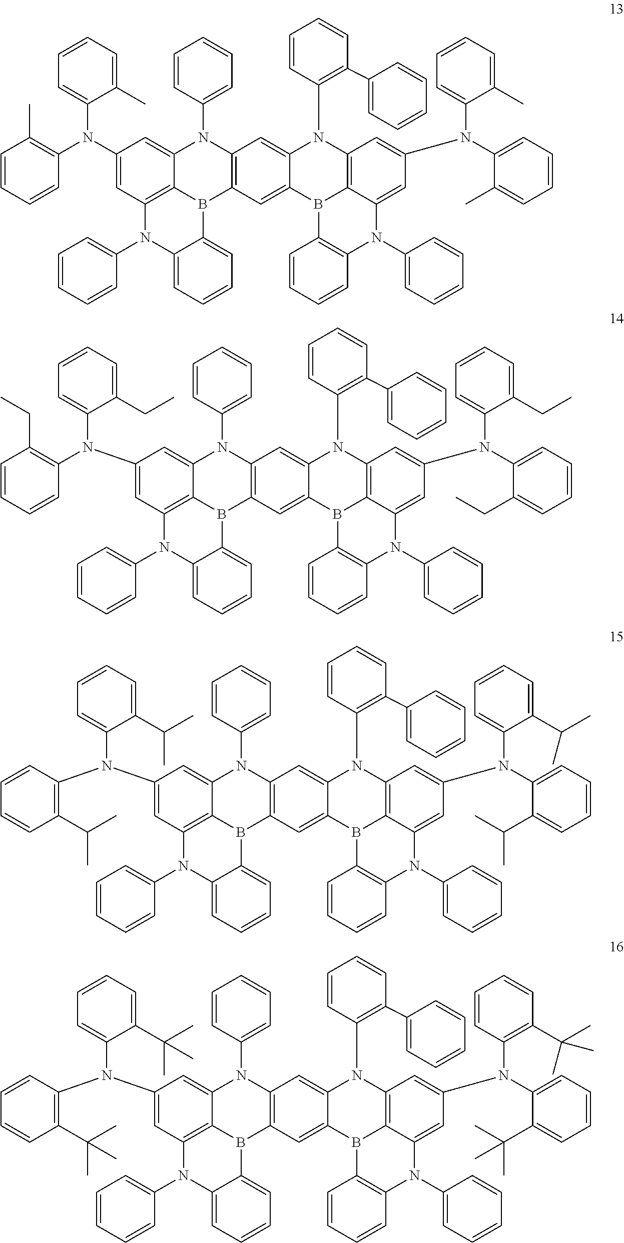

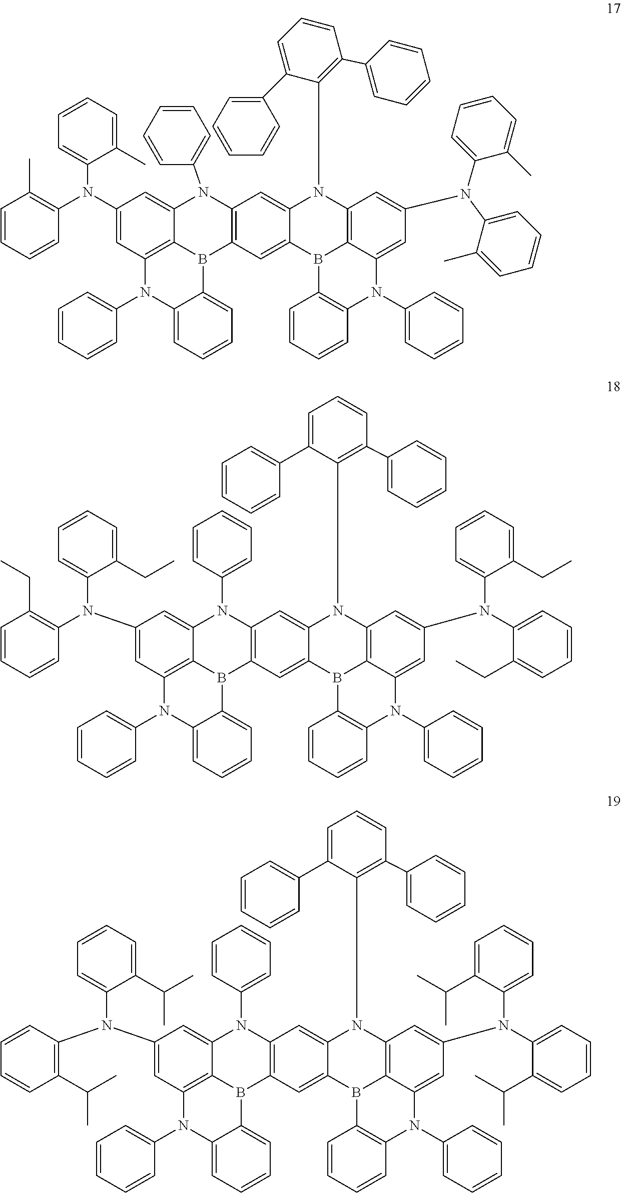

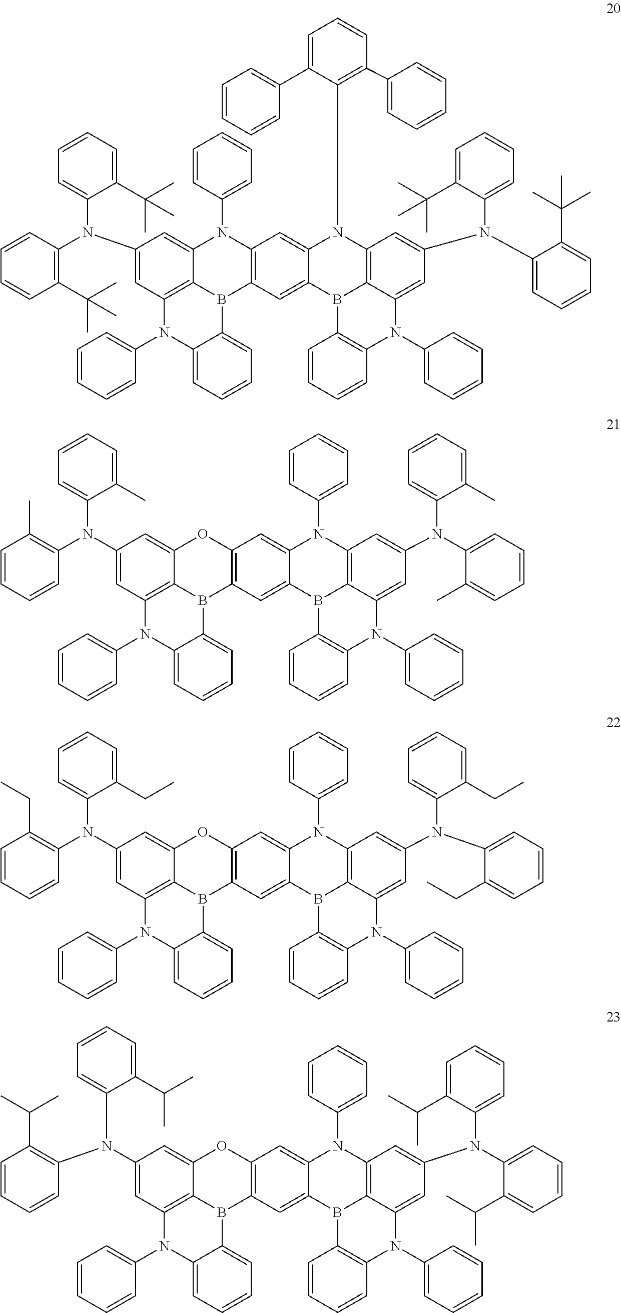

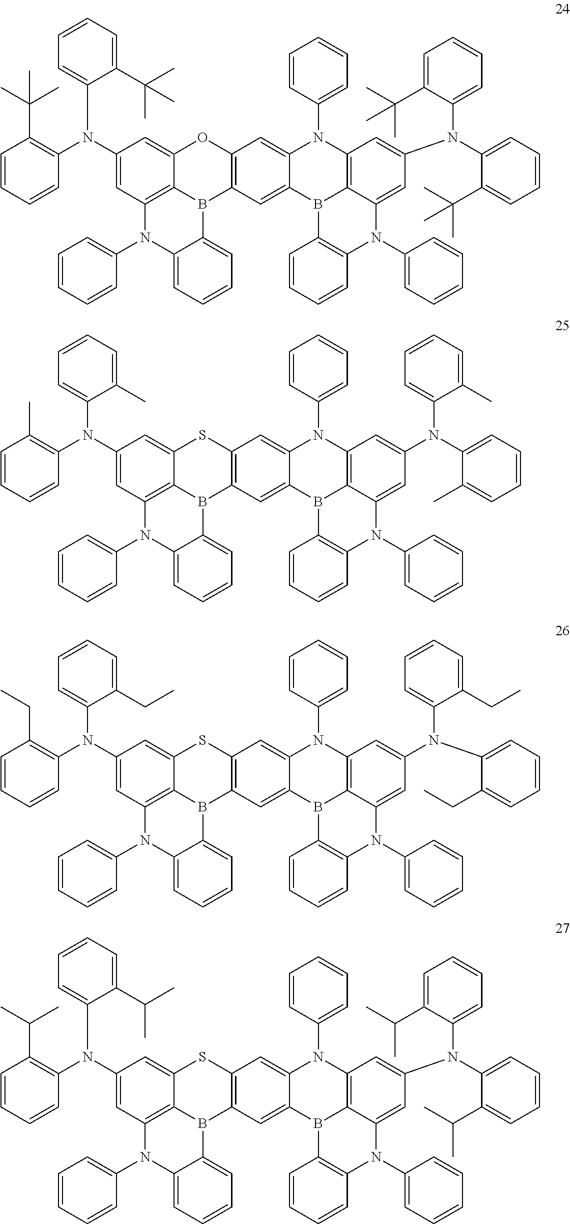

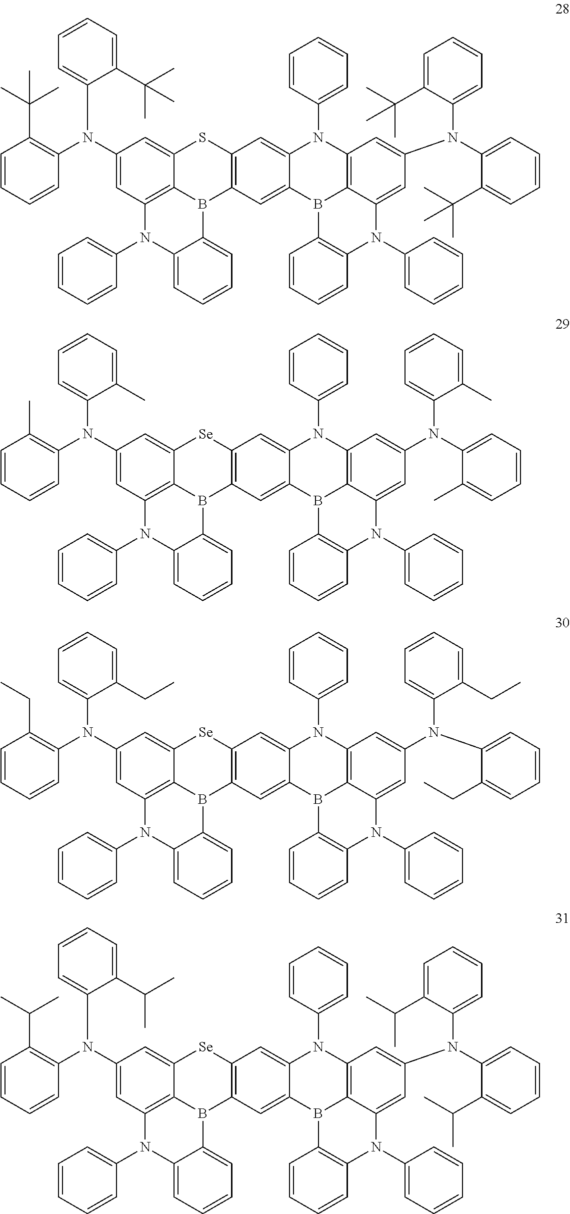

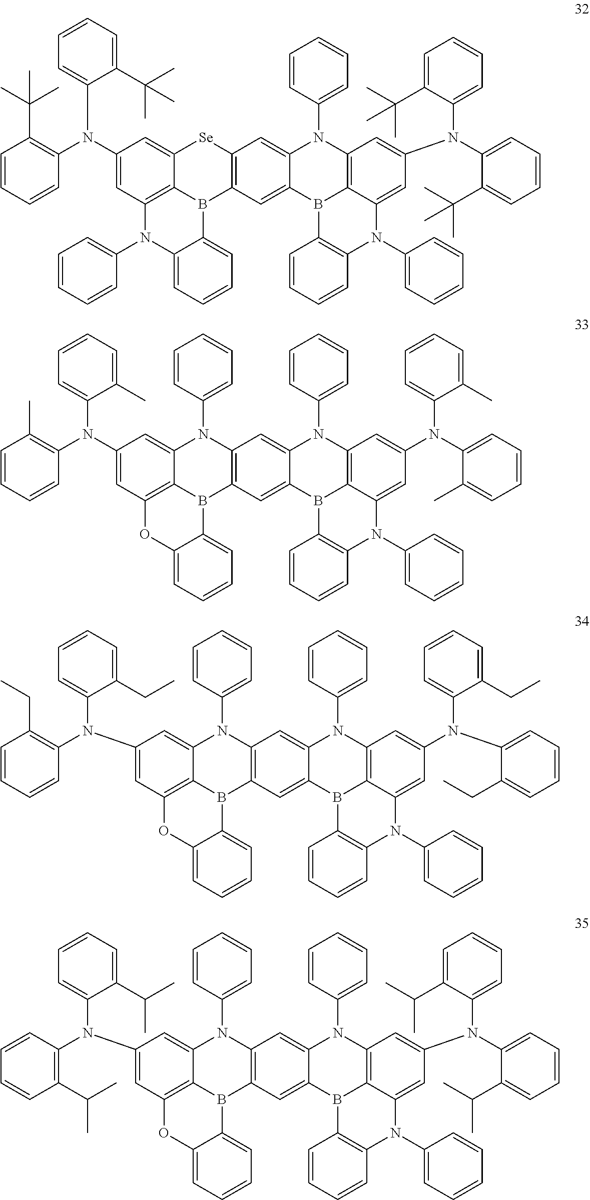

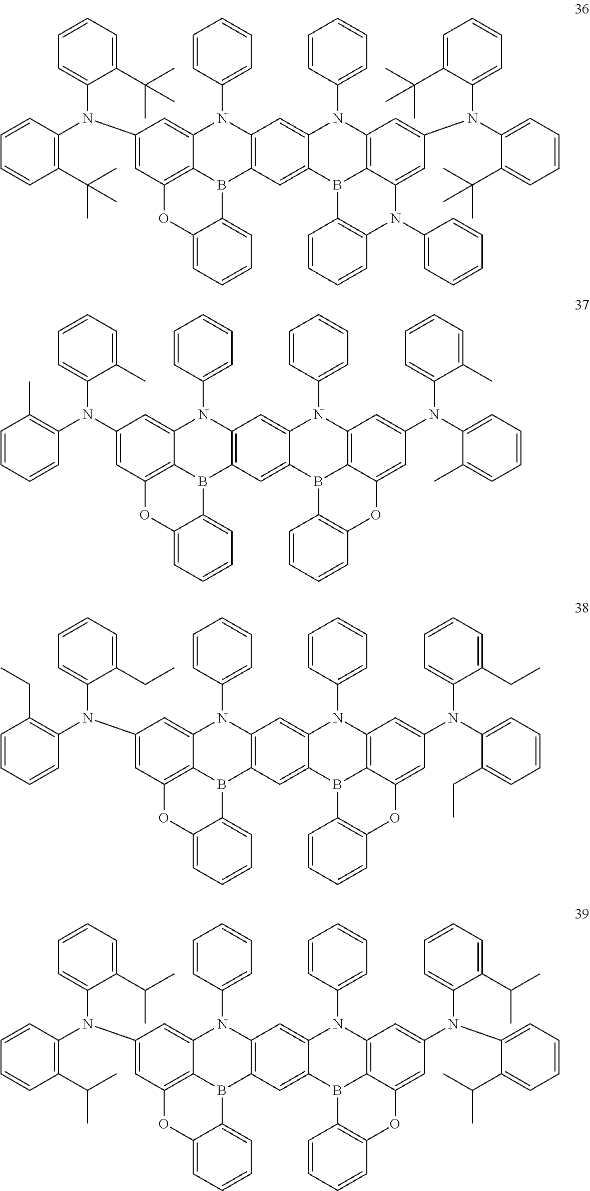

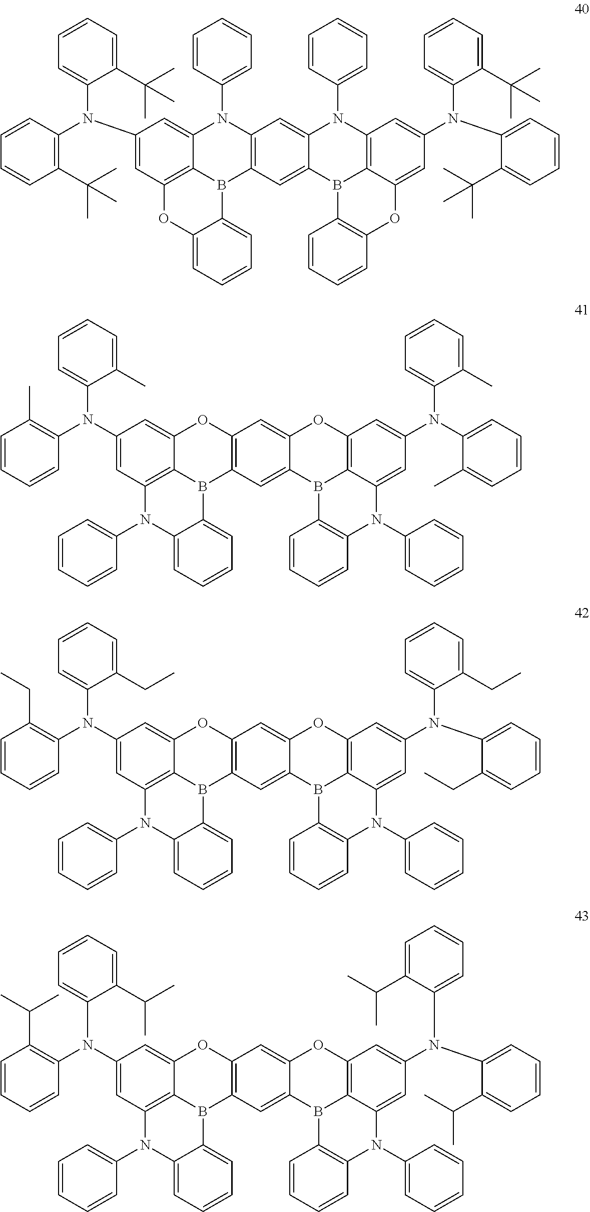

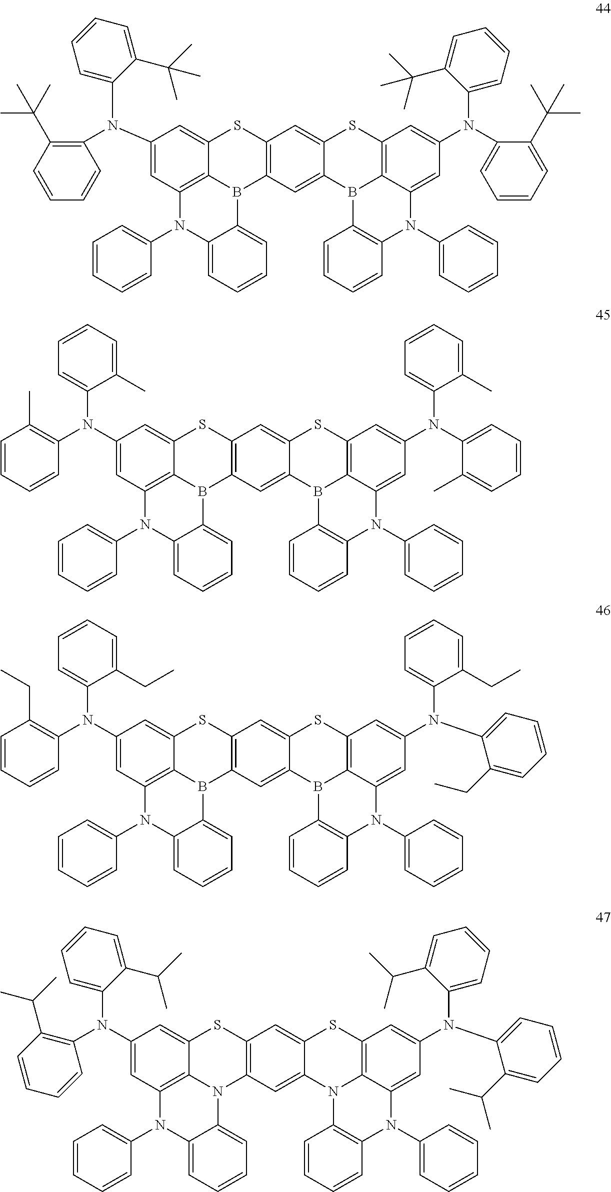

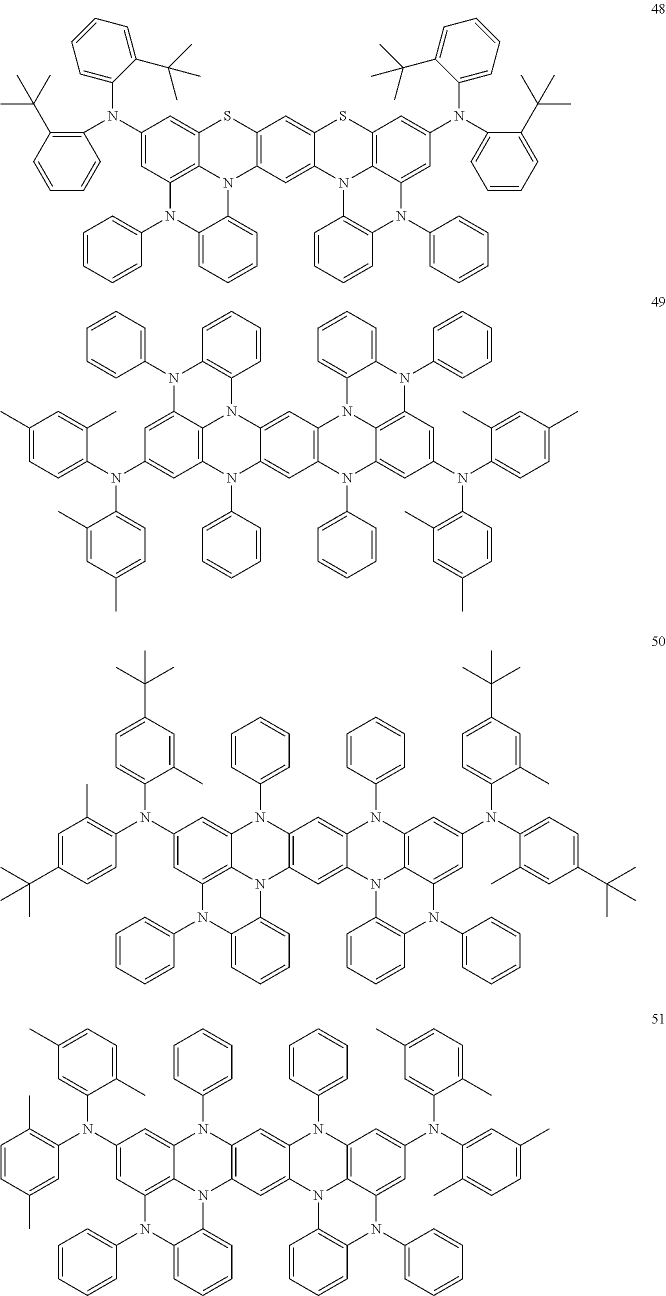

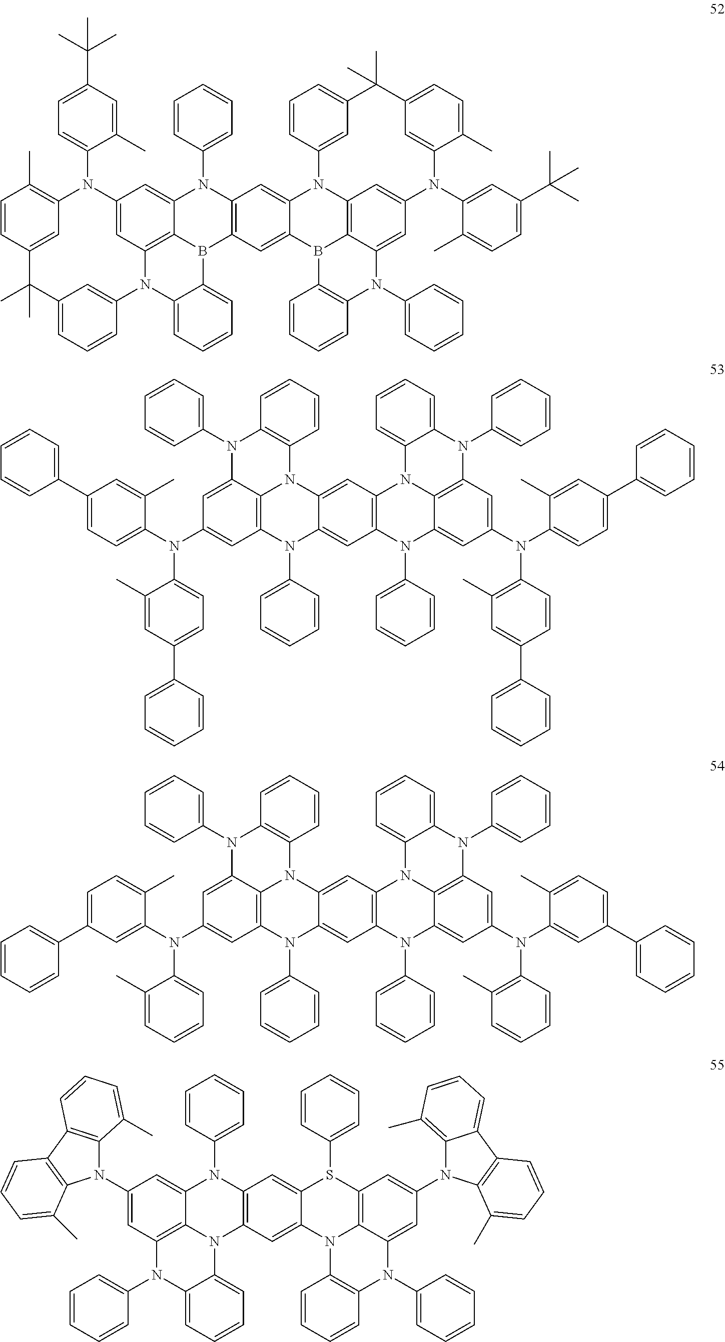

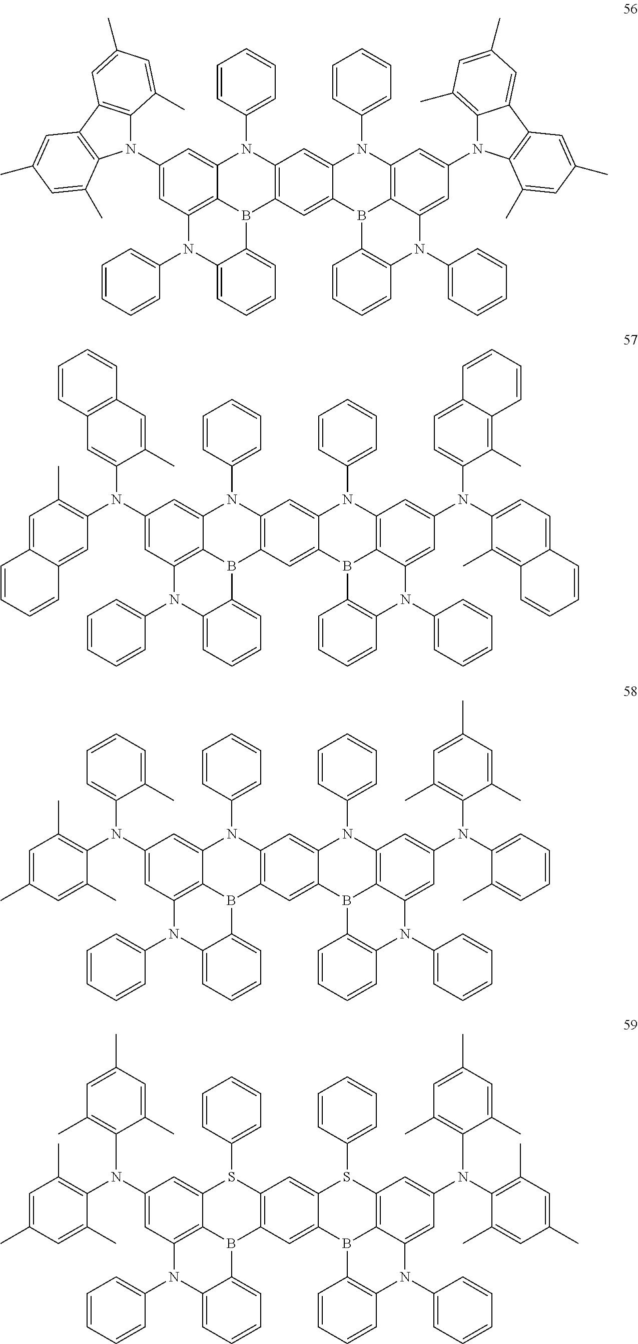

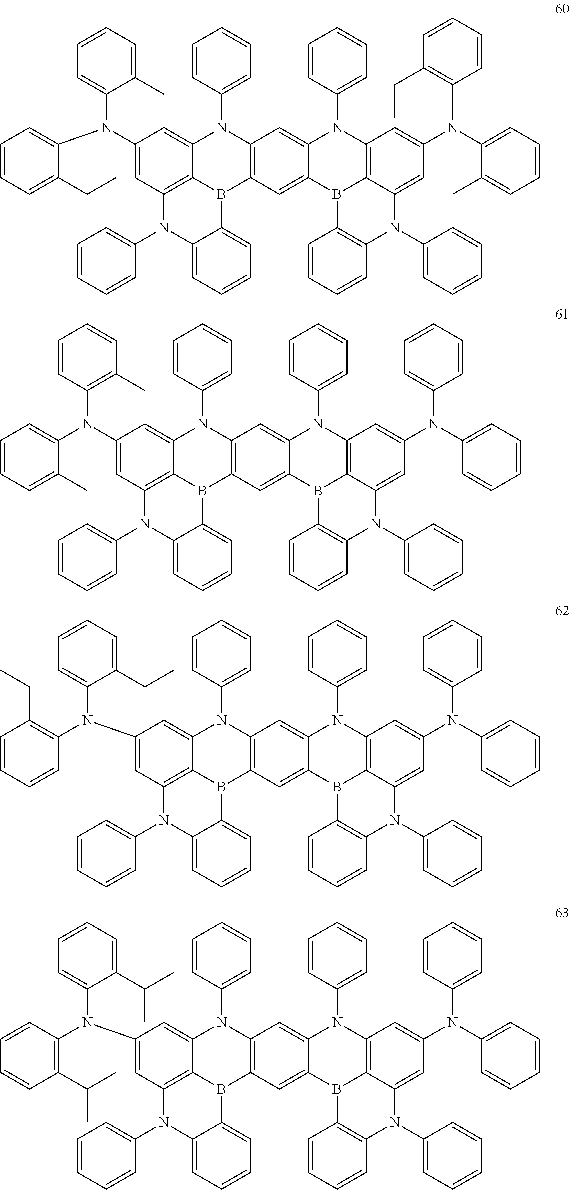

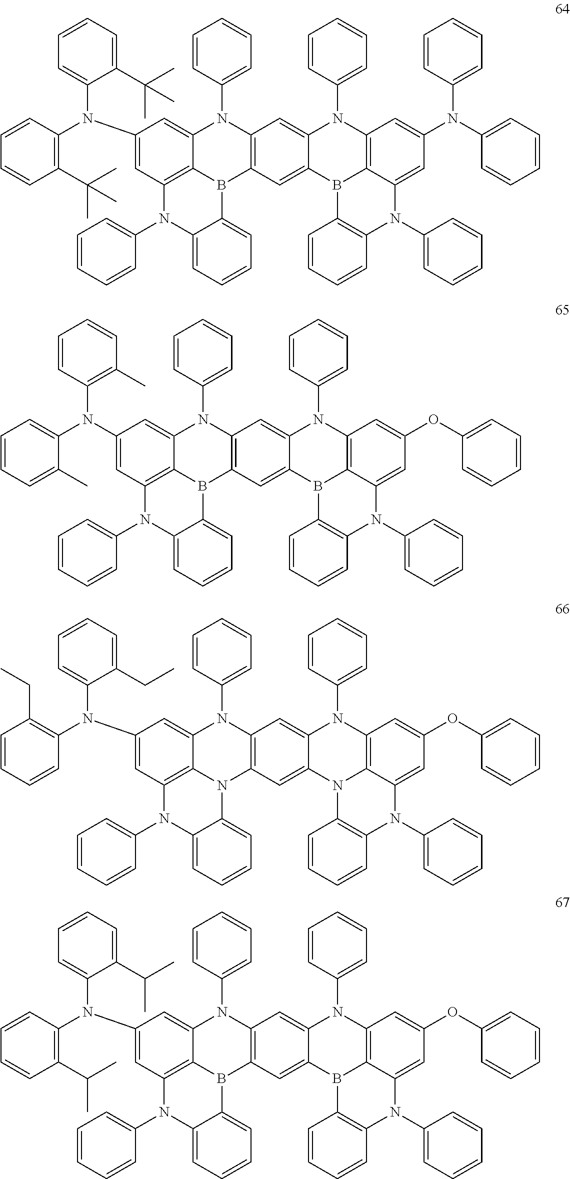

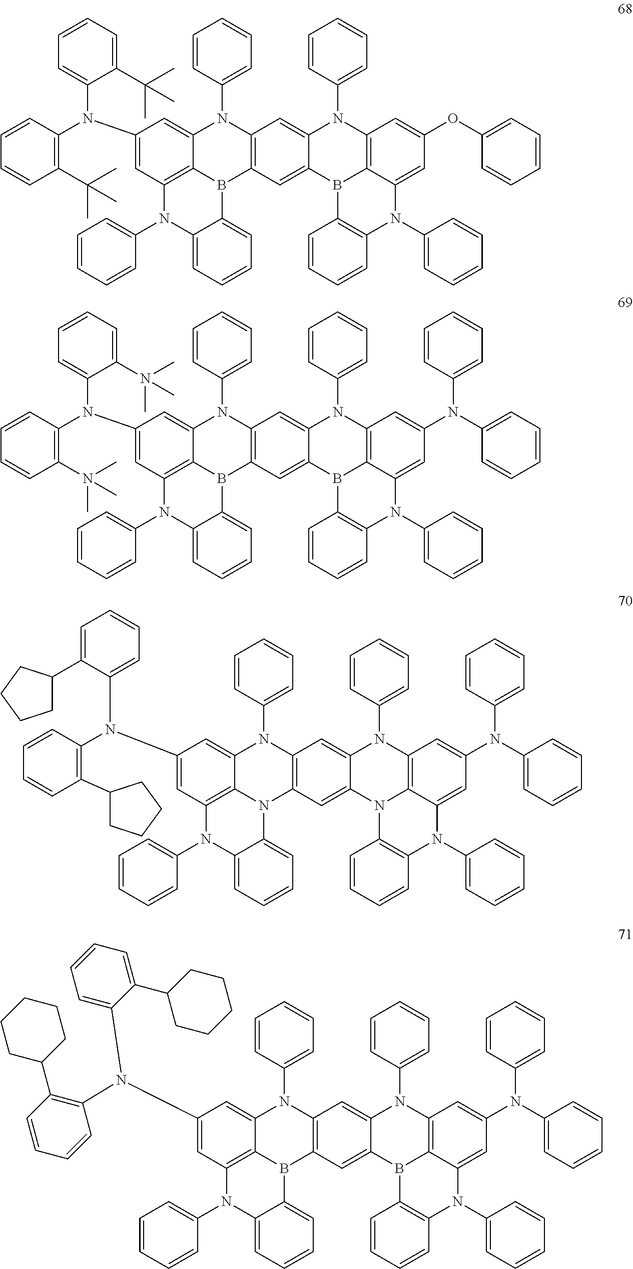

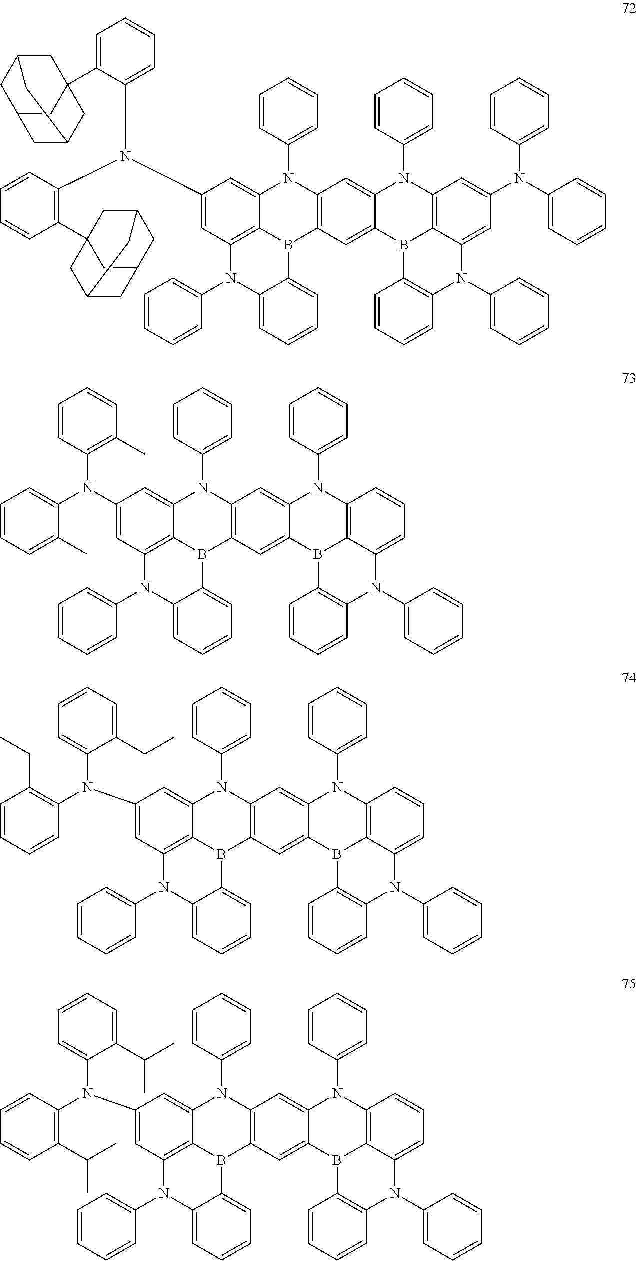

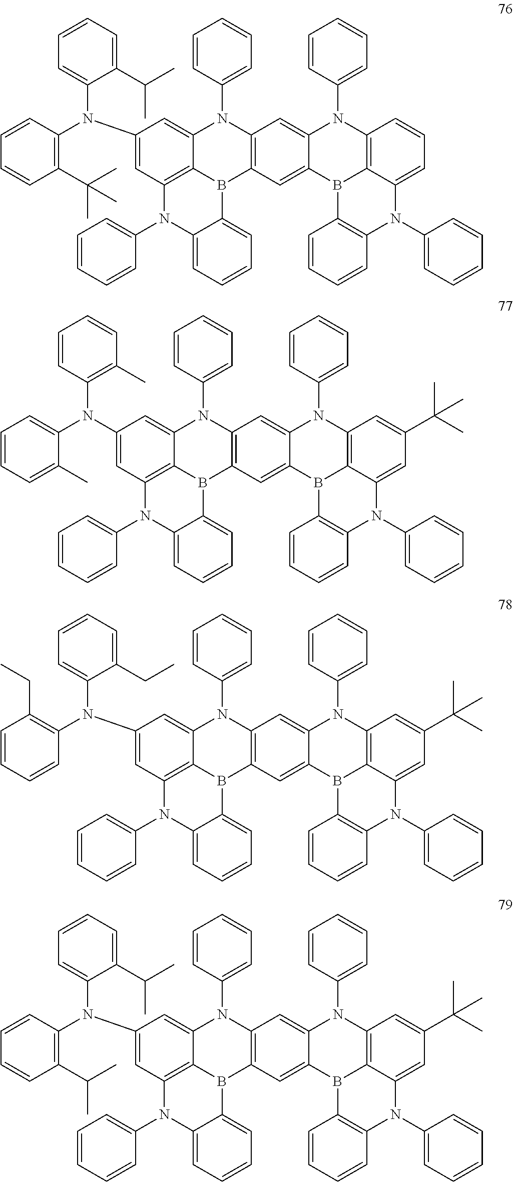

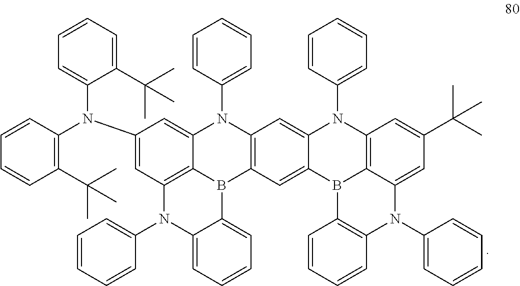 [SMILES: CC(C)(C)c1cc2c3c(c1)N(c1ccccc1)c1cc4c(cc1B3c1ccccc1N2c1ccccc1)B1c2ccccc2N(c2ccccc2)c2cc(N(c3ccccc3C(C)(C)C)c3ccccc3C(C)(C)C)cc(c21)N4c1ccccc1]

13. A polycyclic compound represented by the following Formula 1: 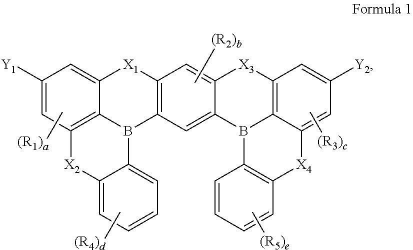
wherein in Formula 1,
X₁ to X₄ are each independently CR₆R₇, NR₈, O, S, or Se,
R₁ to R₇ are each independently a hydrogen atom, a deuterium atom, a halogen atom, a nitro group, a cyano group, a hydroxyl group, a substituted or unsubstituted amine group, a substituted or unsubstituted thiol group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring,
R₈ is a hydrogen atom, a deuterium atom, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring,
Y₁ and Y₂ are each independently a hydrogen atom, a deuterium atom, a halogen atom, a substituted or unsubstituted silyl group, a substituted or unsubstituted oxy group, a substituted or unsubstituted amine group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring,
a to c are each independently an integer of 0 to 2, and
d and e are each independently an integer of 0 to 4,
where at least one selected from among Y₁ and Y₂ is represented by the following Formula 2-1 or Formula 2-2: 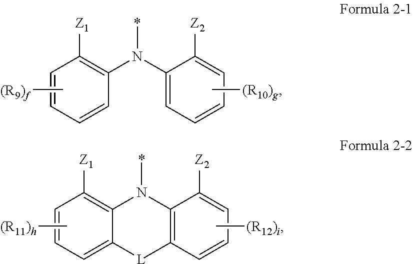
and
wherein in Formula 2-1 and Formula 2-2,
L is a direct linkage, CR₁₃R₁₄, O, or S,
R₉ to R₁₂ are each independently a hydrogen atom, a deuterium atom, a halogen atom, a cyano group, a nitro group, a hydroxyl group, a substituted or unsubstituted silyl group, a substituted or unsubstituted oxy group, a substituted or unsubstituted thiol group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring,
R₁₃ and R₁₄ are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
Z₁ and Z₂ are each independently a substituted or unsubstituted silyl group, a substituted or unsubstituted alkyl group of 1 to 20 carbon atoms, a substituted or unsubstituted cycloalkyl group of 3 to 20 carbon atoms, a substituted or unsubstituted bicycloalkyl group of 5 to 30 carbon atoms, or a substituted or unsubstituted tricycloalkyl group of 8 to 30 carbon atoms,
f and g are each independently an integer of 0 to 4, and
h and i are each independently an integer of 0 to 3.

14. The polycyclic compound of claim 13, wherein Formula 2-2 is represented by the following Formula 3: 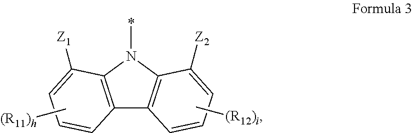
and
wherein in Formula 3,
Z₁, Z₂, R₁₁, R₁₂, h, and i are the same as defined in Formula 2-2.

15. The polycyclic compound of claim 13, wherein Formula 1 is represented by any one selected from among the following Formula 4-1 to Formula 4-4: 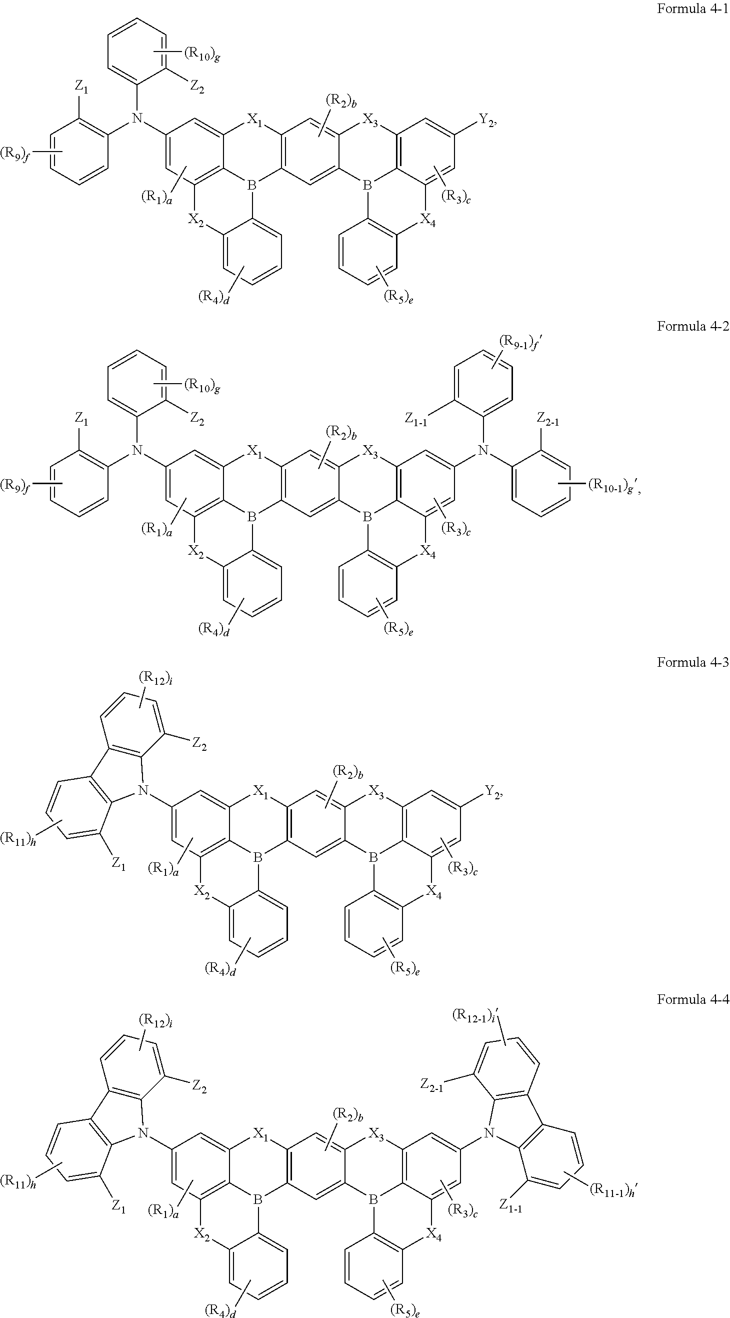
and
wherein in Formula 4-1 to Formula 4-4,
Z₁₋₁ and Z₂₋₁ are each independently a substituted or unsubstituted silyl group, a substituted or unsubstituted alkyl group of 1 to 20 carbon atoms, a substituted or unsubstituted cycloalkyl group of 3 to 20 carbon atoms, a substituted or unsubstituted bicycloalkyl group of 5 to 30 carbon atoms, or a substituted or unsubstituted tricycloalkyl group of 8 to 30 carbon atoms,
R₉₋₁, R₁₀₋₁, R₁₁₋₁, and R₁₂₋₁ are each independently a hydrogen atom, a deuterium atom, a halogen atom, a cyano group, a nitro group, a hydroxyl group, a substituted or unsubstituted silyl group, a substituted or unsubstituted oxy group, a substituted or unsubstituted thiol group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring,
f′ and g′ are each independently an integer of 0 to 4,
h′ and l′ are each independently an integer of 0 to 3, and
X₁ to X₄, R₁ to R₅, a to e, Y₂, Z₁, Z₂, R₉ to R₁₂, and f to i are the same as defined in Formula 1 and Formula 2.

16. The polycyclic compound of claim 13, wherein Z₁ and Z₂ are each independently a silyl group substituted with a substituted or unsubstituted alkyl group of 1 to 10 carbon atoms, a substituted or unsubstituted alkyl group of 1 to 10 carbon atoms, a substituted or unsubstituted cycloalkyl group of 3 to 10 ring-forming carbon atoms, a substituted or unsubstituted bicycloalkyl group of 5 to 10 ring-forming carbon atoms, or a substituted or unsubstituted tricycloalkyl group of 8 to 12 ring-forming carbon atoms.

17. The polycyclic compound of claim 13, wherein at least one selected from among X₁ to X₄ is NAr₁, and
Ar₁ is a substituted or unsubstituted aryl group of 6 to 30 ring-forming carbon atoms, or a substituted or unsubstituted heteroaryl group of 2 to 30 ring-forming carbon atoms.

18. The polycyclic compound of claim 13, wherein Formula 1 is represented by any one selected from among the following Formula 5-1 to Formula 5-5: 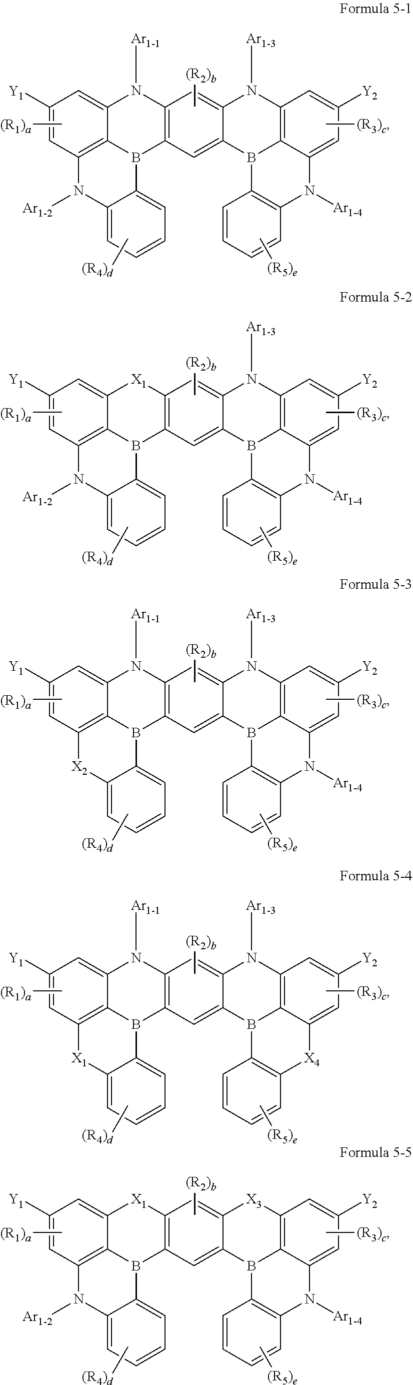
and
wherein in Formula 5-1 to Formula 5-5,
X₁ to X₄ are each independently O, S, or Se,
Ar₁₋₁ to Ar₁₋₄ are each independently a substituted or unsubstituted aryl group of 6 to 30 ring-forming carbon atoms, or a substituted or unsubstituted heteroaryl group of 2 to 30 ring-forming carbon atoms, and
Y₁, Y₂, R₁ to R₅, and a toe are the same as defined in Formula 1.

19. The polycyclic compound of claim 18, wherein Ar₁₋₁ to Ar₁₋₄ are each independently represented by any one selected from among the following Formula 6-1 to Formula 6-3: 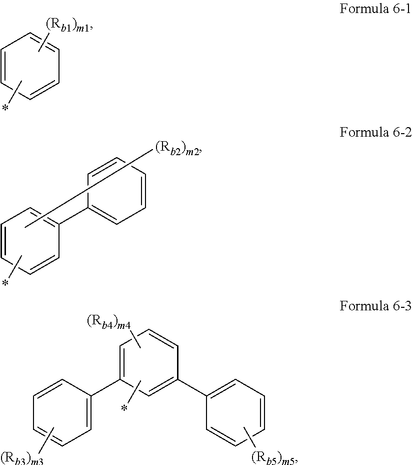
and
wherein in Formula 6-1 to Formula 6-3,
R_{b1} to R_{b5} are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, and/or combined with an adjacent group to form a ring,
m1, m3, and m5 are each independently an integer of 0 to 5,
m2 is an integer of 0 to 9, and
m4 is an integer of 0 to 3.

20. The polycyclic compound of claim 13, wherein the polycyclic compound represented by Formula 1 is any one selected from among compounds represented in the following Compound Group 1: 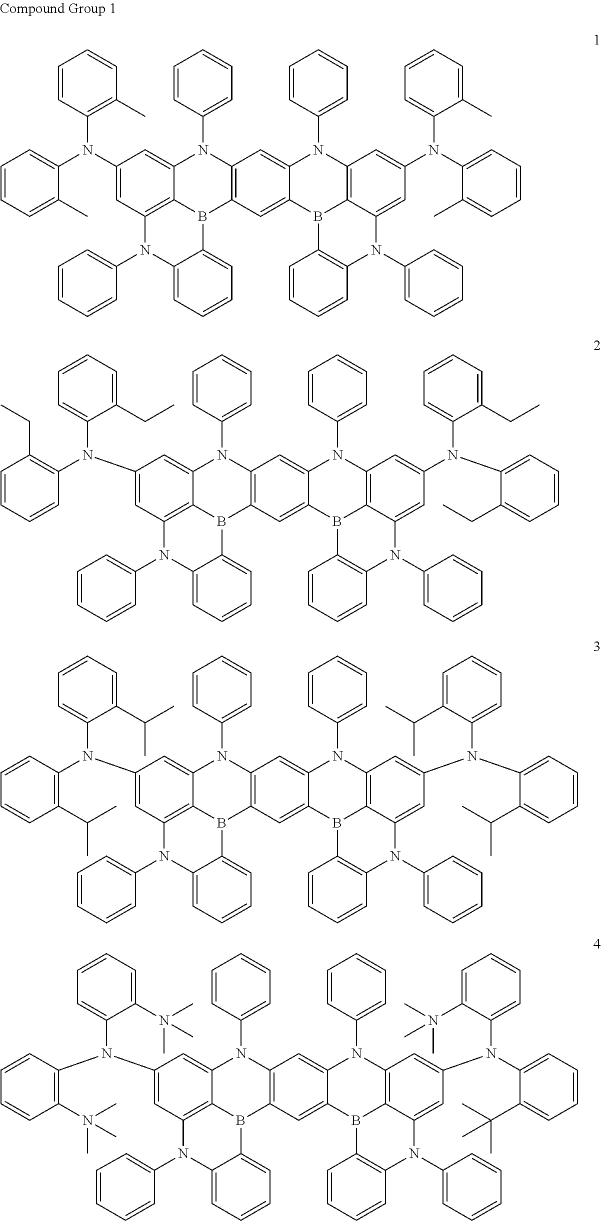 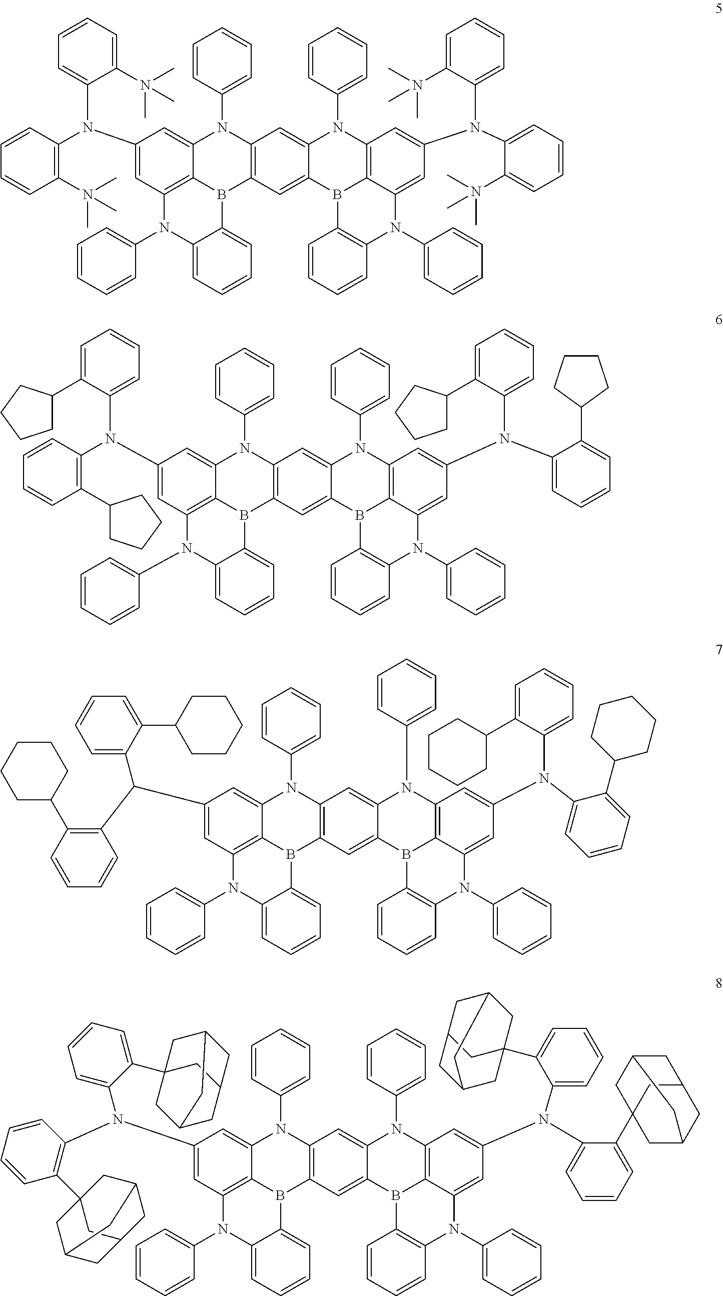 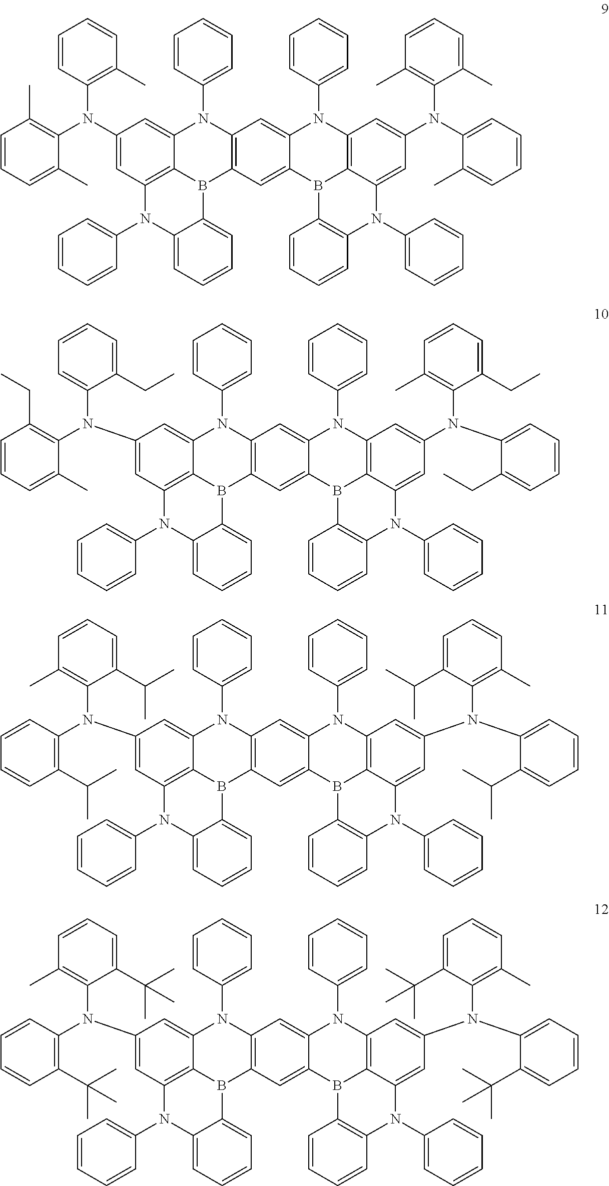 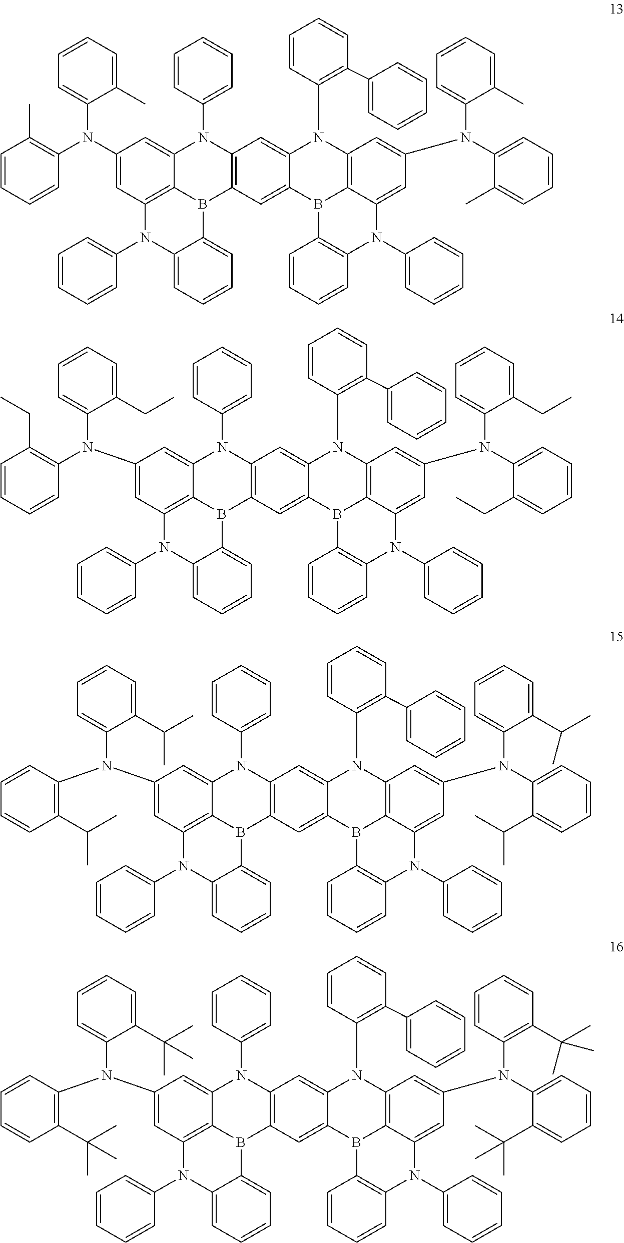 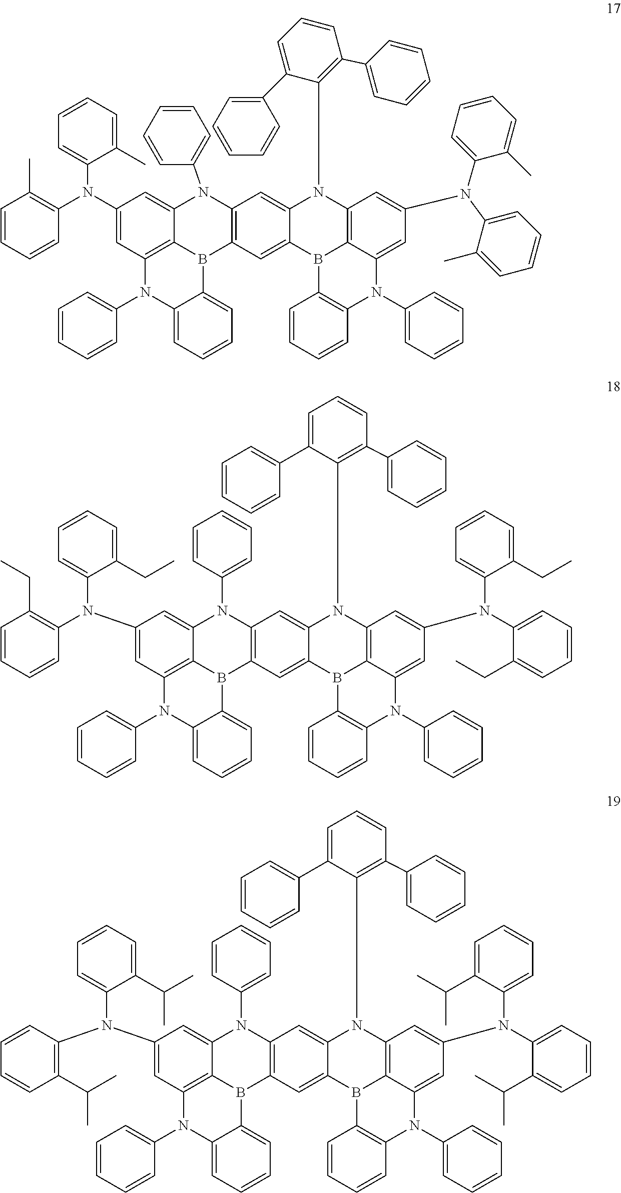 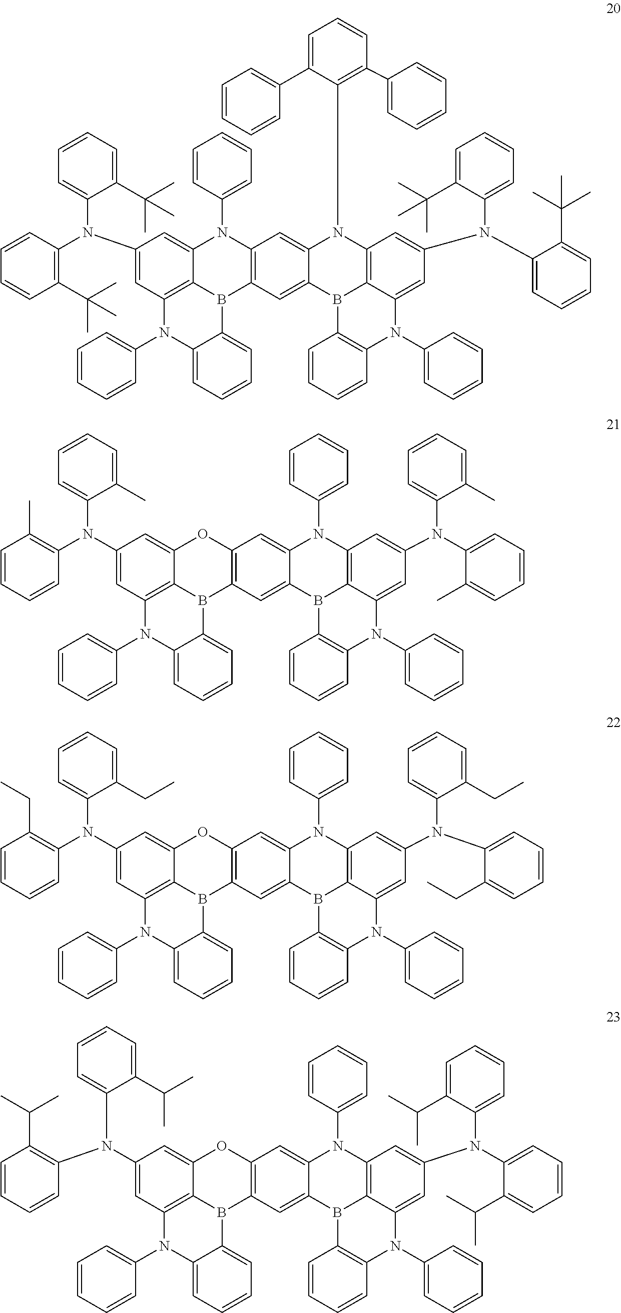 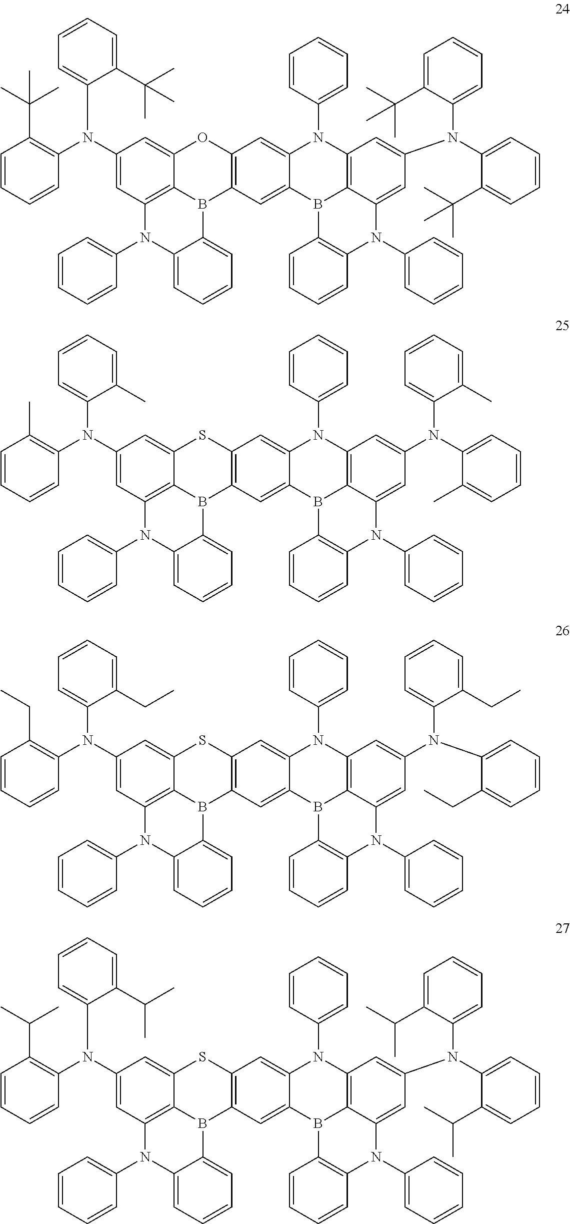 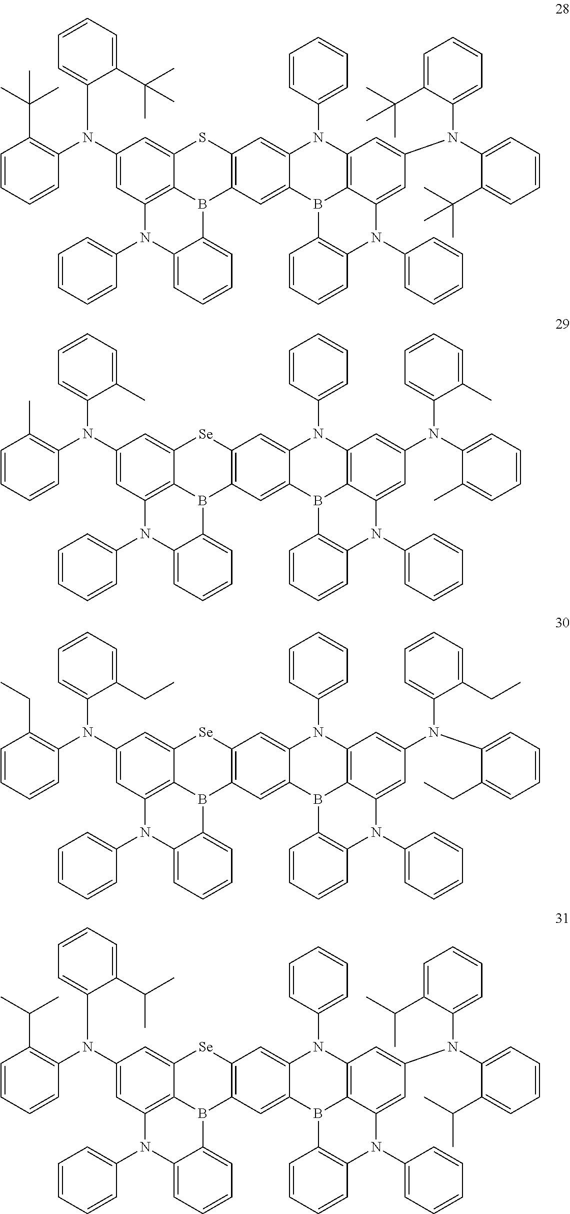 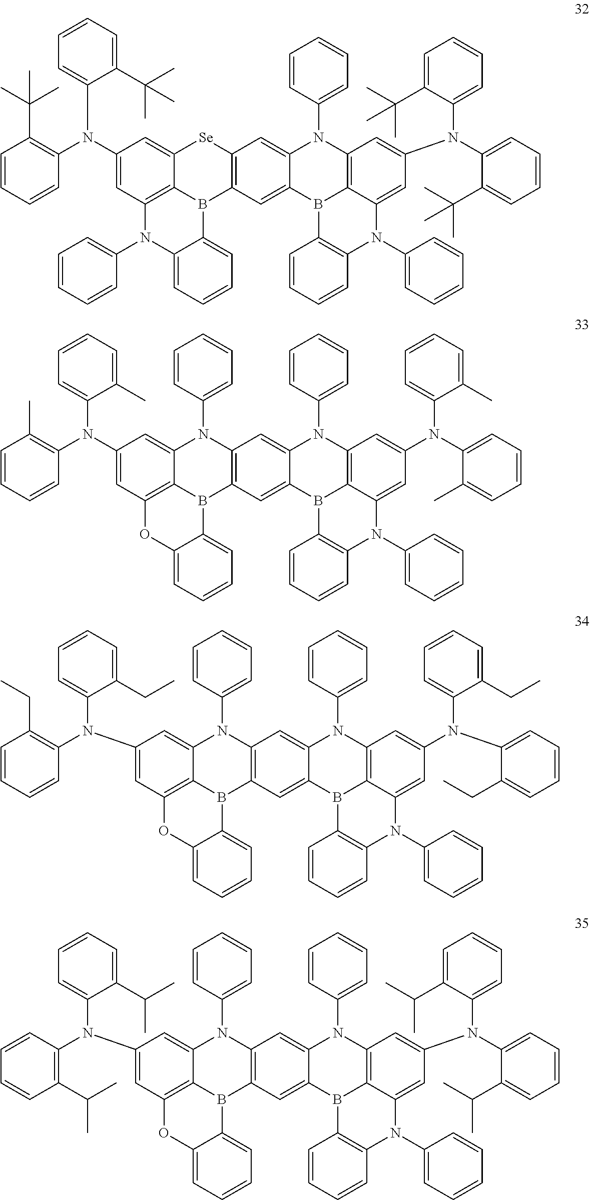 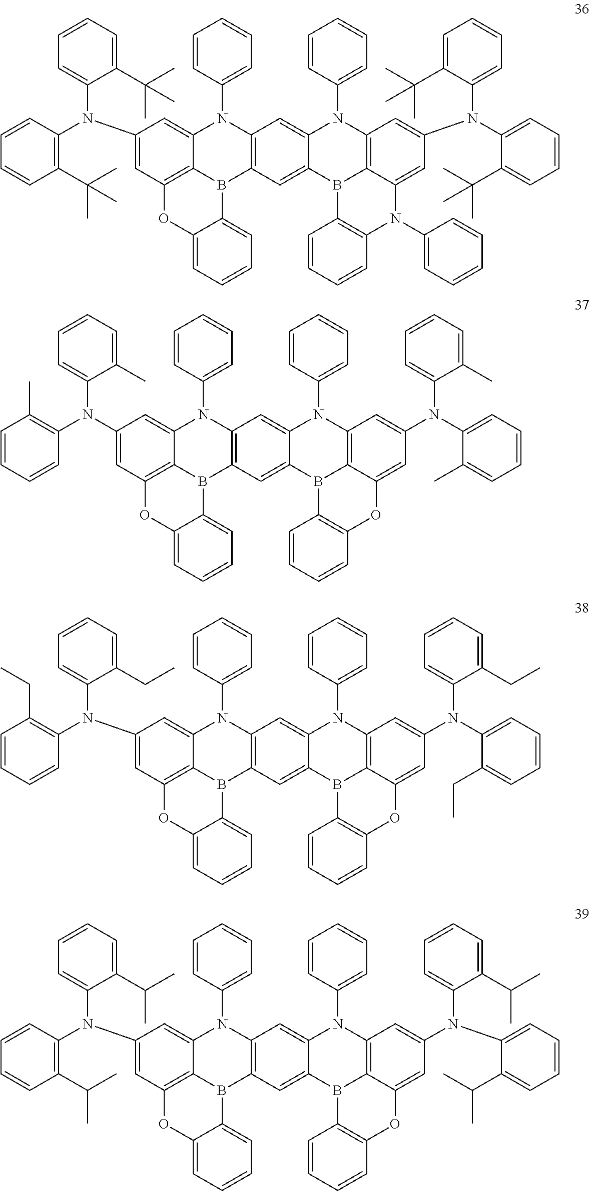 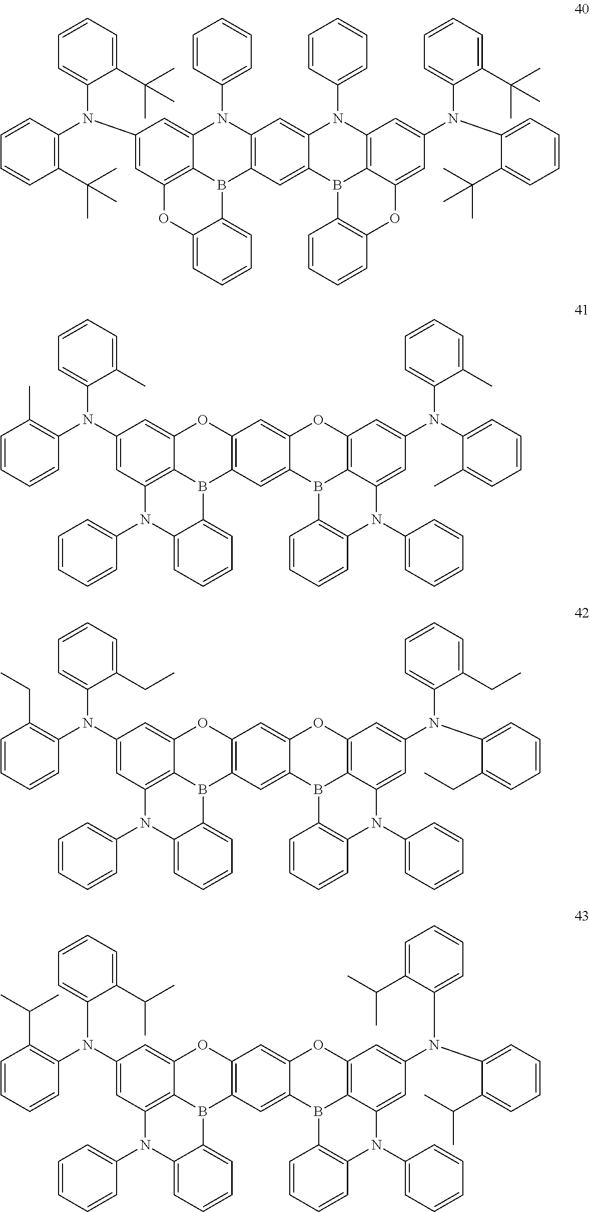 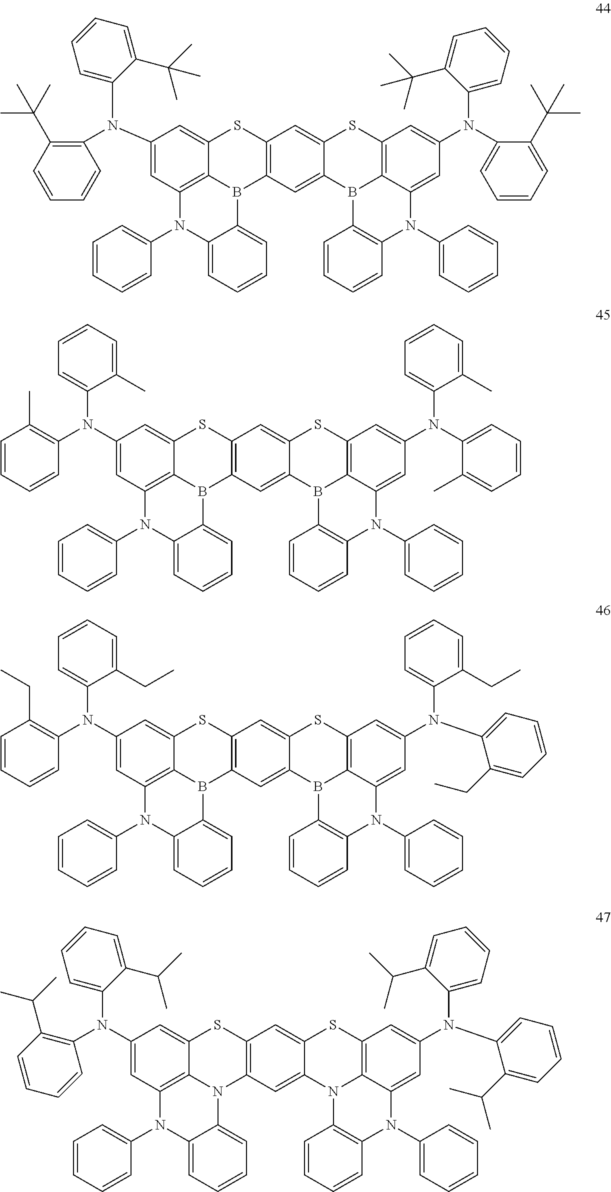 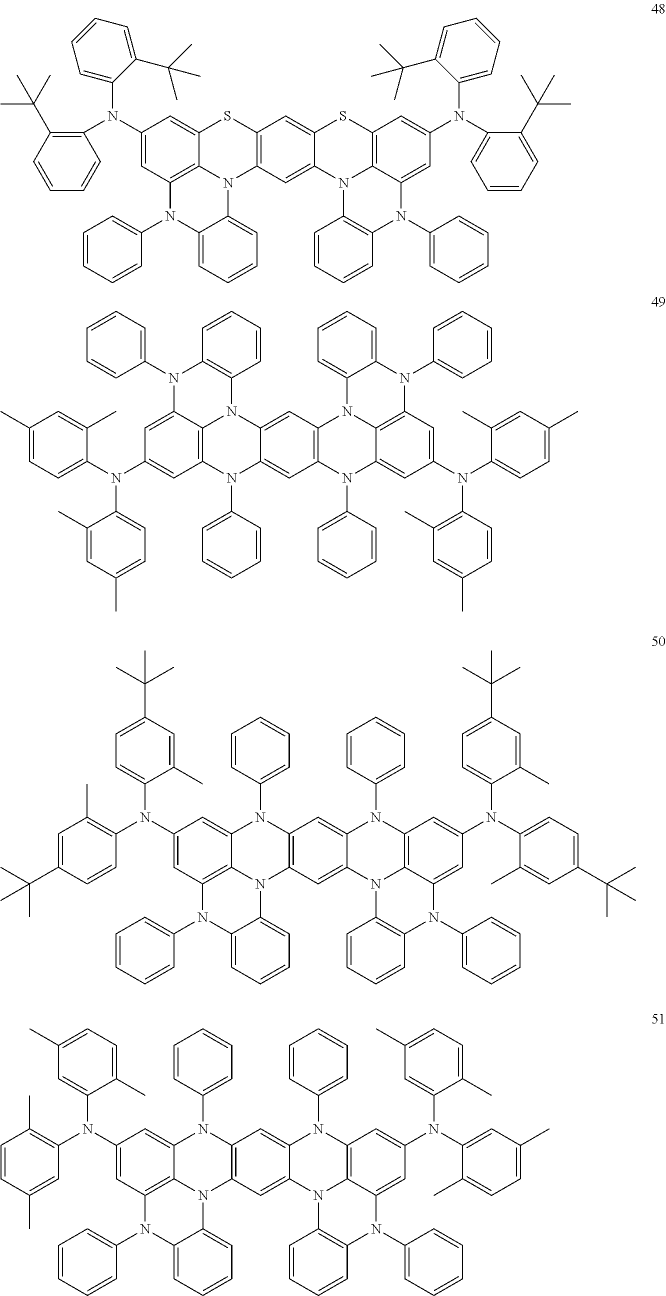 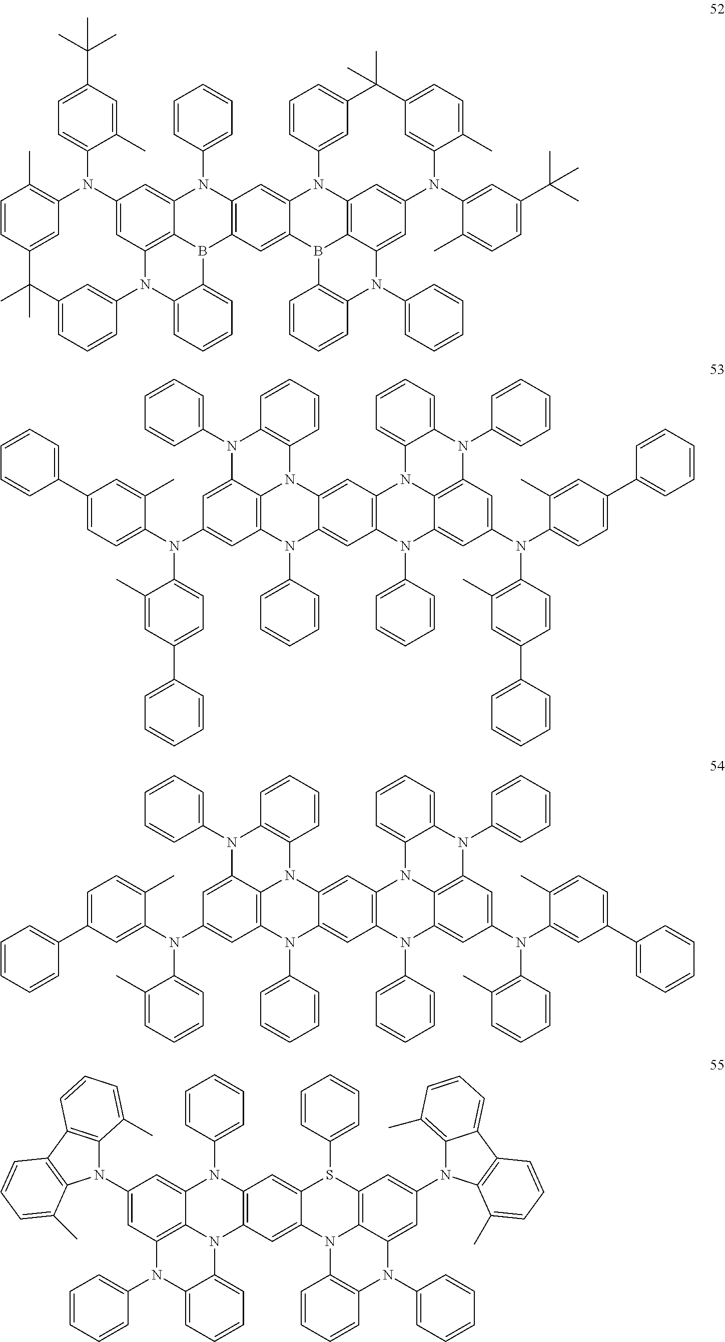 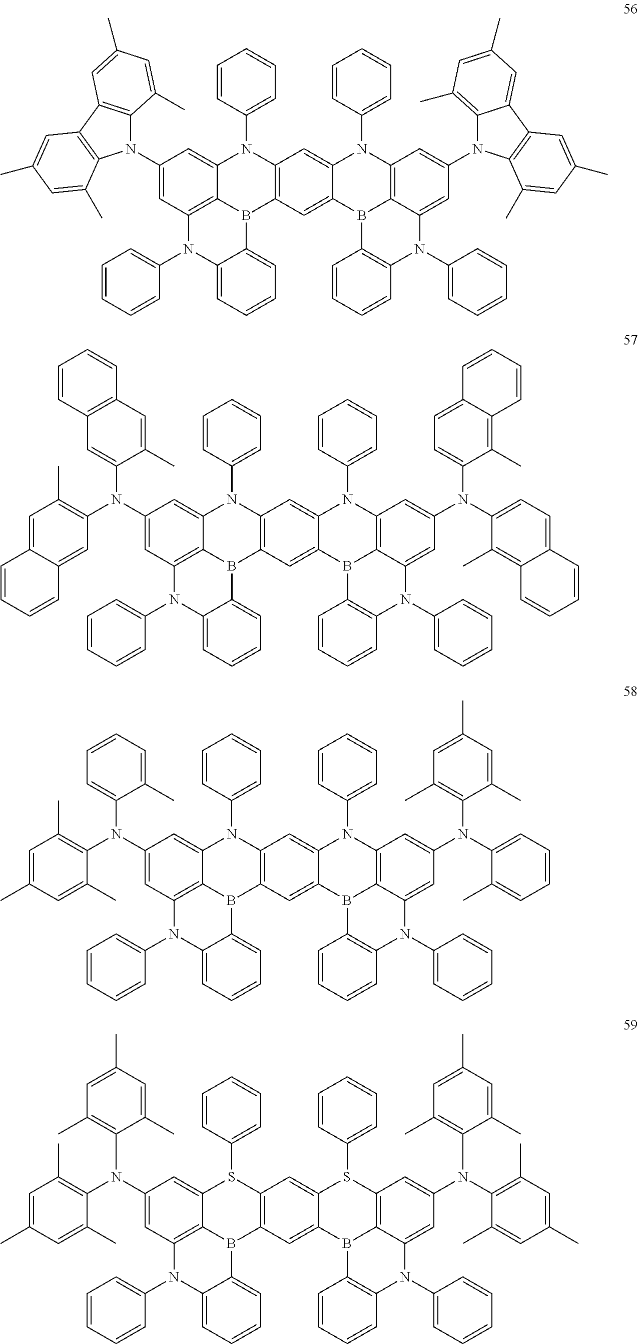 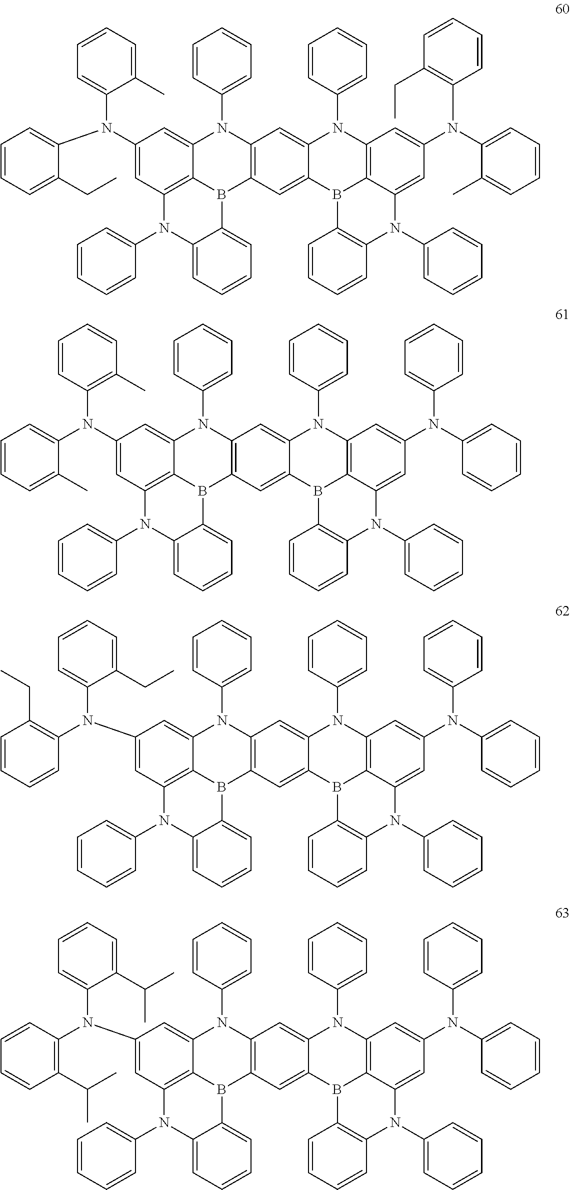 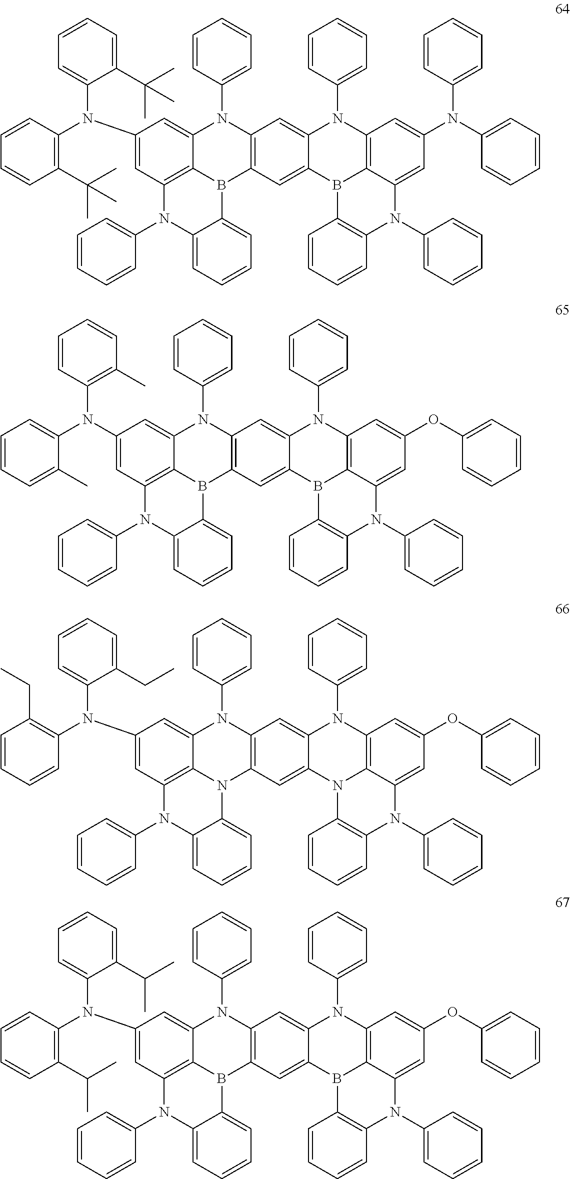 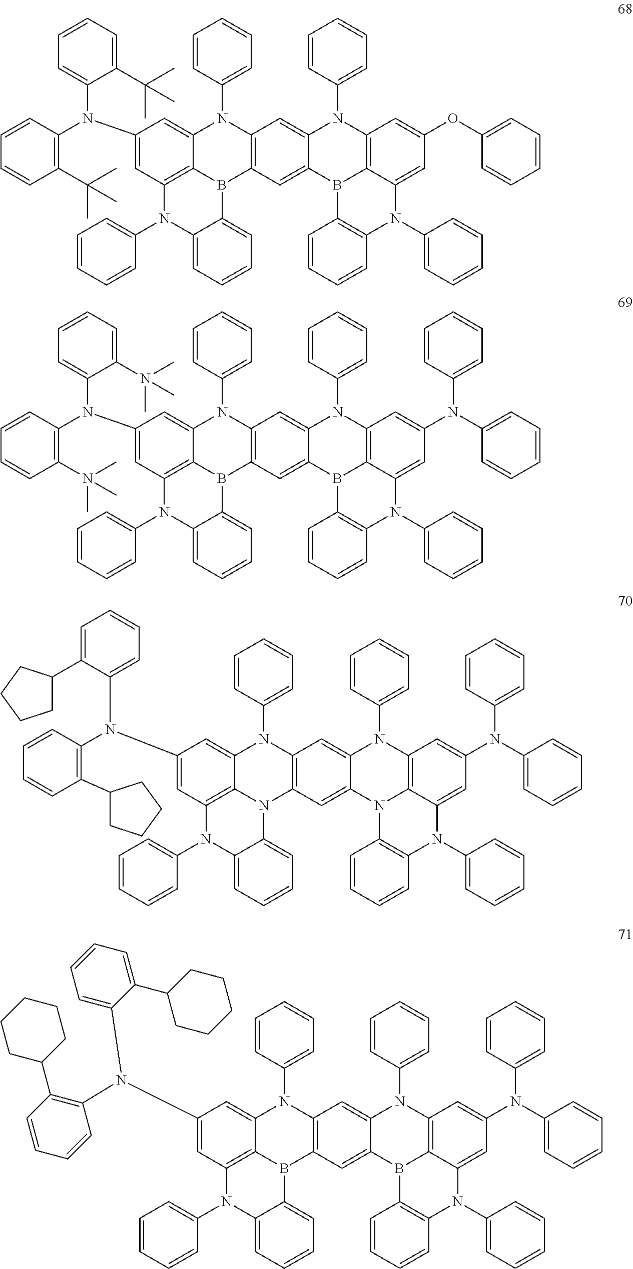 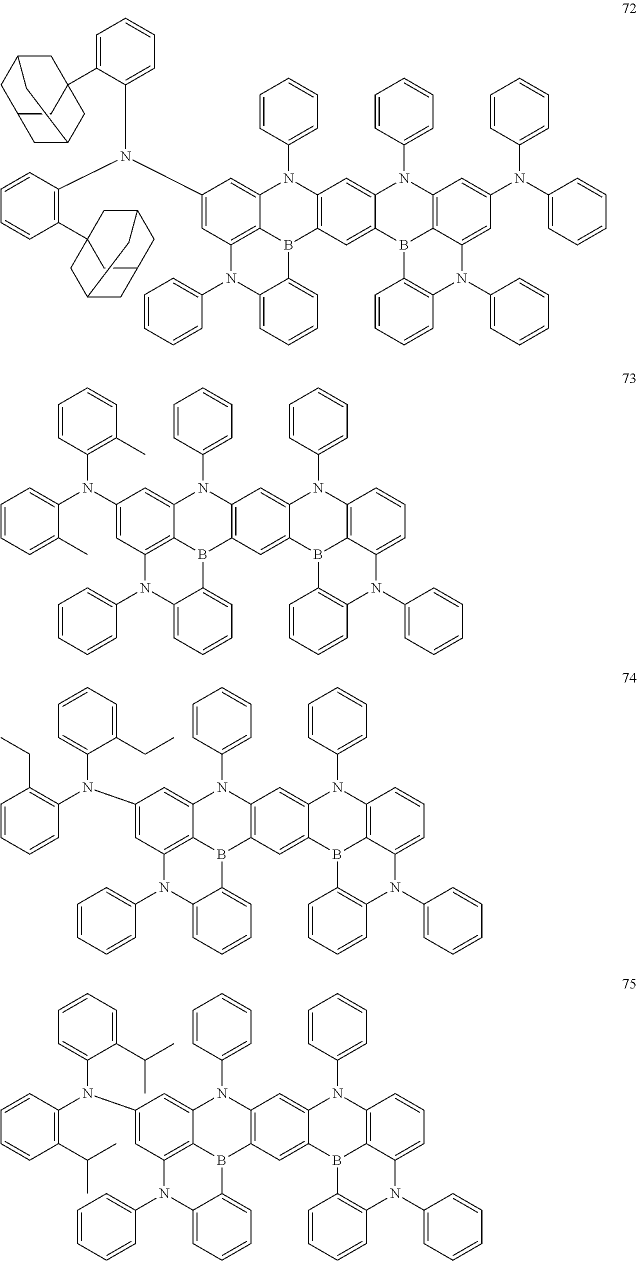 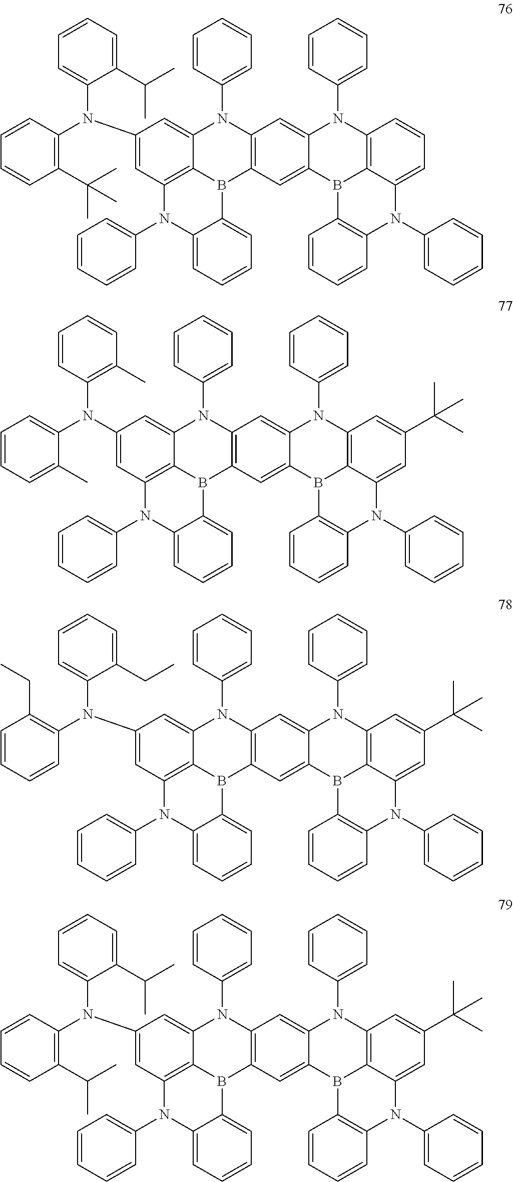 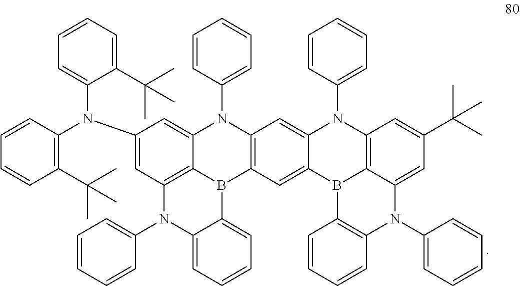 [SMILES: CC(C)(C)c1cc2c3c(c1)N(c1ccccc1)c1cc4c(cc1B3c1ccccc1N2c1ccccc1)B1c2ccccc2N(c2ccccc2)c2cc(N(c3ccccc3C(C)(C)C)c3ccccc3C(C)(C)C)cc(c21)N4c1ccccc1]
